(19) United States
(12) Patent Application Publication
(10) Pub. No.: US 2024/0190908 A1
(43) Pub. Date: Jun. 13, 2024

(54) BLUE PHOSPHORESCENT EMITTERS EMPLOYING FUNCTIONALIZED IMIDAZOPHENTHRIDINE AND ANALOGUES

(71) Applicant: Arizona Board of Regents on behalf of Arizona State University, Scottsdale, AZ (US)

(72) Inventors: Jian Li, Tempe, AZ (US); Linyu Cao, Tempe, AZ (US)

(21) Appl. No.: 18/535,055

(22) Filed: Dec. 11, 2023

Related U.S. Application Data
(63) Continuation of application No. 16/751,586, filed on Jan. 24, 2020, now Pat. No. 11,878,988.
(60) Provisional application No. 62/796,275, filed on Jan. 24, 2019.

(51) Int. Cl. C07F 15/00; H10K 85/30

(52) U.S. Cl. CPC C07F 15/0086; C07F 15/006; H10K 85/346

(57) ABSTRACT

A series of functionalized imidazophenthridine analogue-based blue phosphorescent emitters have been designed, where bulky substituents (e.g., tetrabutyl, phenyl, mesityl, triisopropylbenzene, etc.) are introduced on an imidazophenthridine fragment of the emitters. Bulky substituents may suppress potential excimer formation, as well as improve the solubility of the complexes. This class of emitters may be utilized in luminescent labels, emitters for organic light emitting devices, and lighting applications.

### CROSS-REFERENCE TO RELATED APPLICATIONS

The present application claims priority to U.S. Provisional Application No. 62/796,275, filed Jan. 24, 2019, which is incorporated by reference herein in its entirety.

### BACKGROUND OF THE INVENTION

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

In recent decades, phosphorescent organic light emitting devices (OLEDs) using palladium (Pd) and platinum (Pt) complexes have attracted great attention due to their 100% of electron to photon conversion efficiency. However, efficient blue phosphorescent OLEDs with excellent operational stability remains a significant challenge. Hence, it is in great demand to develop efficient and stable blue phosphorescent emitters.

### SUMMARY OF THE INVENTION

According to one embodiment, a compound is provided having General formula I, General formula II, General formula I, or General formula IV;

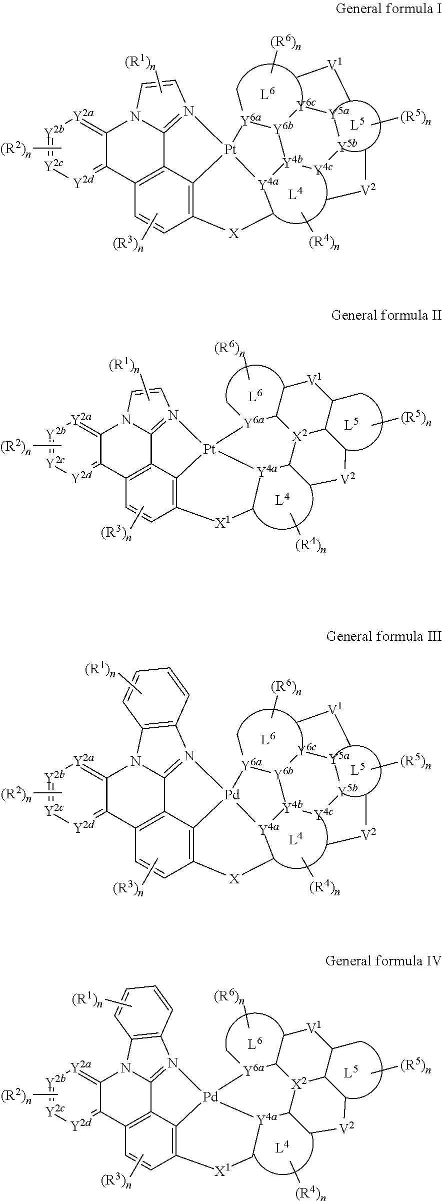

wherein, in General formula I to IV,
Y^{2a}, Y^{2b}, Y^{2c}, Y^{2d}, Y^{4a}, Y^{4b}, Y^{4c}, Y^{5a}, Y^{5b}, Y^{6a}, Y^{6b}, Y^{6c}, and X² each independently represent C or N;
X, X¹, V¹ and V² each independently represent no bond, O, S, Se NR⁷, PR⁷, AsR⁷, SbR⁷, BiR⁷, R⁷P═O, R⁷As═O, R⁷Bi═O, BR⁷, AlR⁷, CR⁷R⁸, SiR⁷R⁸, GeR⁷R⁸, C═O, SO₂, or SeO₂;
each occurrence of R² independently represents substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
each of R¹, R³, R⁴, R⁵, R⁶, R⁷ and R⁸ is independently absent or present as a single substituent or multiple substituents, valency permitting, and each of R, R¹, R³, R⁴, R⁵, R⁶, R⁷, and R⁸ independently represents deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
each n is independently an integer, valency permitting; and
L⁴, L⁵, and L⁶ each independently represents a 5- to 10-membered aryl, heteroaryl, fused aryl, or fused heteroaryl.

According to another embodiment, an organic light emitting device (OLED) is provided. The OLED can include an anode; a cathode; and an organic layer disposed between the anode and the cathode. The organic layer can include a compound of General formula 1, General formula II, General formula III, or General Formula IV. The OLED can be incorporated into a consumer product.

According to another embodiment, a formulation is provided. The formulation can include a compound of General formula I, General formula II, General formula III, or General Formula IV.

### BRIEF DESCRIPTION OF THE DRAWINGS

The following detailed description of preferred embodiments will be better understood when read in conjunction with the appended drawings. For the purpose of illustration, there are shown in the drawings embodiments which are presently preferred. It should be understood, however, that the disclosure is not limited to the precise arrangements and instrumentalities of the embodiments shown in the drawings.

FIG. 1 is a schematic diagram of an organic light emitting device.

FIG. 2 is a plot of the emission spectrum of PtON2-PP4 in methylene chloride at room temperature.

FIG. 3 is a plot of the emission spectrum of Pt2O2-PPy5-tb3 in methylene chloride at room temperature.

FIG. 4 is a plot of the emission spectrum of Pt2O2-P2-M3 at room temperature and at 77 K.

FIG. 5 depicts the results of DFT modeling of Pt2O2-P2 and Pt2O-P2-M3.

### DETAILED DESCRIPTION

The present disclosure relates in part to the unexpected discovery that phosphorescent emitters with imidazophenthridines having bulky substituents have lower propensity to form excimers and also have improved solubility.

### Definitions

It is to be understood that the figures and descriptions herein have been simplified to illustrate elements that are relevant for a clear understanding of the present disclosure, while eliminating, for the purpose of clarity, many other elements found in the art related to phosphorescent organic light emitting devices and the like. Those of ordinary skill in the art may recognize that other elements and/or steps are desirable and/or required in implementing the devices disclosed herein. However, because such elements and steps are well known in the art, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this disclosure pertains. Although any methods, materials and components similar or equivalent to those described herein can be used in the practice or testing of the disclosed devices and compositions, the preferred methods, and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, 5%, ±1%, or +0.1% from the specified value, as such variations are appropriate.

Throughout this disclosure, various aspects can be presented in a range format. It should be understood that the description in range format is merely for convenience and brevity and should not be construed as an inflexible limitation. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, 6 and any whole and partial increments therebetween. This applies regardless of the breadth of the range.

Disclosed are the components to be used to prepare the compositions of the disclosure as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-F, B-F, C-D, C-F, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions disclosed herein. Thus, if there are a variety of additional steps that can be performed it is understood that each of these additional steps can be performed with any specific embodiment or combination of embodiments of the methods disclosed herein.

As referred to herein, a linking atom or a linking group can connect two groups such as, for example, an N and C group. The linking atom can optionally, if valency permits, have other chemical moieties attached. For example, in one aspect, an oxygen would not have any other chemical groups attached as the valency is satisfied once it is bonded to two groups (e.g., N and/or C groups). In another aspect, when carbon is the linking atom, two additional chemical moieties can be attached to the carbon. Suitable chemical moieties include, but are not limited to, hydrogen, hydroxyl, alkyl, alkoxy, ═O, halogen, nitro, amine, amide, thiol, aryl, heteroaryl, cycloalkyl, and heterocyclyl.

The term “cyclic structure” or the like terms used herein refer to any cyclic chemical structure which includes, but is not limited to, aryl, heteroaryl, cycloalkyl, cycloalkenyl, and heterocyclyl.

As used herein, the term “substituted” is contemplated to include all permissible substituents of organic compounds. In a broad aspect, the permissible substituents include acyclic and cyclic, branched and unbranched, carbocyclic and heterocyclic, and aromatic and nonaromatic substituents of organic compounds. Illustrative substituents include, for example, those described below. The permissible substituents can be one or more and the same or different for appropriate organic compounds. For purposes of this disclosure, the heteroatoms, such as nitrogen, can have hydrogen substituents and/or any permissible substituents of organic compounds described herein which satisfy the valences of the heteroatoms. This disclosure is not intended to be limited in any manner by the permissible substituents of organic compounds. Also, the terms “substitution” or “substituted with” include the implicit proviso that such substitution is in accordance with permitted valence of the substituted atom and the substituent, and that the substitution results in a stable compound, e.g., a compound that does not spontaneously undergo transformation such as by rearrangement, cyclization, elimination, etc. It is also contemplated that, in certain aspects, unless expressly indicated to the contrary, individual substituents can be further optionally substituted (i.e., further substituted or unsubstituted).

The term “alkyl” as used herein is a branched or unbranched saturated hydrocarbon group of 1 to 24 carbon atoms, such as methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic or acyclic. The alkyl group can be branched or unbranched. The alkyl group can also be substituted or unsubstituted. For example, the alkyl group can be substituted with one or more groups including, but not limited to, alkyl, cycloalkyl, alkoxy, amino, ether, halide, hydroxy, nitro, silyl, sulfo-oxo, or thiol, as described herein. A “lower alkyl” group is an alkyl group containing from one to six (e.g., from one to four) carbon atoms.

Throughout the specification “alkyl” is generally used to refer to both unsubstituted alkyl groups and substituted alkyl groups; however, substituted alkyl groups are also specifically referred to herein by identifying the specific substituent(s) on the alkyl group. For example, the term “halogenated alkyl” or “haloalkyl” specifically refers to an alkyl group that is substituted with one or more halide, e.g., fluorine, chlorine, bromine, or iodine. The term “alkoxyalkyl” specifically refers to an alkyl group that is substituted with one or more alkoxy groups, as described below. The term “alkylamino” specifically refers to an alkyl group that is substituted with one or more amino groups, as described below, and the like. When “alkyl” is used in one instance and a specific term such as “alkylalcohol” is used in another, it is not meant to imply that the term “alkyl” does not also refer to specific terms such as “alkylalcohol” and the like.

This practice is also used for other groups described herein. That is, while a term such as “cycloalkyl” refers to both unsubstituted and substituted cycloalkyl moieties, the substituted moieties can, in addition, be specifically identified herein; for example, a particular substituted cycloalkyl can be referred to as, e.g., an “alkylcycloalkyl.” Similarly, a substituted alkoxy can be specifically referred to as, e.g., a “halogenated alkoxy,” a particular substituted alkenyl can be, e.g., an “alkenylalcohol,” and the like. Again, the practice of using a general term, such as “cycloalkyl,” and a specific term, such as “alkylcycloalkyl,” is not meant to imply that the general term does not also include the specific term.

The term “cycloalkyl” as used herein is a non-aromatic carbon-based ring composed of at least three carbon atoms. Examples of cycloalkyl groups include, but are not limited to, cyclopropyl, cyclobutyl, cyclopentyl, cyclohexyl, norbornyl, and the like. The term “heterocycloalkyl” is a type of cycloalkyl group as defined above, and is included within the meaning of the term “cycloalkyl,” where at least one of the carbon atoms of the ring is replaced with a heteroatom such as, but not limited to, nitrogen, oxygen, sulfur, or phosphorus. The cycloalkyl group and heterocycloalkyl group can be substituted or unsubstituted. The cycloalkyl group and heterocycloalkyl group can be substituted with one or more groups including, but not limited to, alkyl, cycloalkyl, alkoxy, amino, ether, halide, hydroxy, nitro, silyl, sulfo-oxo, or thiol as described herein.

The term “polyalkylene group” as used herein is a group having two or more CH₂ groups linked to one another. The polyalkylene group can be represented by the formula (CH₂)ₐ—, where “a” is an integer of from 2 to 500.

The terms “alkoxy” and “alkoxyl” as used herein to refer to an alkyl or cycloalkyl group bonded through an ether linkage; that is, an “alkoxy” group can be defined as —OA¹ where A¹ is alkyl or cycloalkyl as defined above. “Alkoxy” also includes polymers of alkoxy groups as just described; that is, an alkoxy can be a polyether such as —OA¹-OA² or —OA¹-(OA²)-OA³, where “a” is an integer of from 1 to 200 and A¹, A², and A³ are alkyl and/or cycloalkyl groups.

The term “alkenyl” as used herein is a hydrocarbon group of from 2 to 24 carbon atoms with a structural formula containing at least one carbon-carbon double bond. Asymmetric structures such as (A¹A²)C═C(A³A⁴) are intended to include both the E and Z isomers. This can be presumed in structural formulae herein wherein an asymmetric alkene is present, or it can be explicitly indicated by the bond symbol C═C. The alkenyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol, as described herein.

The term “cycloalkenyl” as used herein is a non-aromatic carbon-based ring composed of at least three carbon atoms and containing at least one carbon-carbon double bond, i.e., C═C. Examples of cycloalkenyl groups include, but are not limited to, cyclopropenyl, cyclobutenyl, cyclopentenyl, cyclopentadienyl, cyclohexenyl, cyclohexadienyl, norbornenyl, and the like. The term “heterocycloalkenyl” is a type of cycloalkenyl group as defined above, and is included within the meaning of the term “cycloalkenyl,” where at least one of the carbon atoms of the ring is replaced with a heteroatom such as, but not limited to, nitrogen, oxygen, sulfur, or phosphorus. The cycloalkenyl group and heterocycloalkenyl group can be substituted or unsubstituted. The cycloalkenyl group and heterocycloalkenyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein.

The term “alkynyl” as used herein is a hydrocarbon group of 2 to 24 carbon atoms with a structural formula containing at least one carbon-carbon triple bond. The alkynyl group can be unsubstituted or substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol, as described herein.

The term “cycloalkynyl” as used herein is a non-aromatic carbon-based ring composed of at least seven carbon atoms and containing at least one carbon-carbon triple bound. Examples of cycloalkynyl groups include, but are not limited to, cycloheptynyl, cyclooctynyl, cyclononynyl, and the like. The term “heterocycloalkynyl” is a type of cycloalkenyl group as defined above, and is included within the meaning of the term “cycloalkynyl,” where at least one of the carbon atoms of the ring is replaced with a heteroatom such as, but not limited to, nitrogen, oxygen, sulfur, or phosphorus. The cycloalkynyl group and heterocycloalkynyl group can be substituted or unsubstituted. The cycloalkynyl group and heterocycloalkynyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein.

The term “aryl” as used herein is a group that contains any carbon-based aromatic group including, but not limited to, benzene, naphthalene, phenyl, biphenyl, phenoxybenzene, and the like. The term “aryl” also includes “heteroaryl,” which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term “non-heteroaryl,” which is also included in the term “aryl,” defines a group that contains an aromatic group that does not contain a heteroatom. The aryl group can be substituted or unsubstituted. The aryl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein. The term “biaryl” is a specific type of aryl group and is included in the definition of “aryl.” Biaryl refers to two aryl groups that are bound together via a fused ring structure, as in naphthalene, or are attached via one or more carbon-carbon bonds, as in biphenyl.

The term “aldehyde” as used herein is represented by the formula —C(O)H. Throughout this specification “C(O)” is a short hand notation for a carbonyl group, i e., C═O.

The terms “amine” or “amino” as used herein are represented by the formula —NA¹A², where A¹ and A² can be, independently, hydrogen or alkyl, cycloalkyl, alkenyl, cycloalkenyl, alkynyl, cycloalkynyl, aryl, or heteroaryl group as described herein.

The term “alkylamino” as used herein is represented by the formula —NH(-alkyl) where alkyl is a described herein. Representative examples include, but are not limited to, methylamino group, ethylamino group, propylamino group, isopropylamino group, butylamino group, isobutylamino group, (sec-butyl)amino group, (tert-butyl)amino group, pentylamino group, isopentylamino group, (tert-pentyl)amino group, hexylamino group, and the like.

The term “dialkylamino” as used herein is represented by the formula —N(-alkyl)₂ where alkyl is a described herein. Representative examples include, but are not limited to, dimethylamino group, diethylamino group, dipropylamino group, diisopropylamino group, dibutylamino group, diisobutylamino group, di(sec-butyl)amino group, di(tert-butyl)amino group, dipentylamino group, diisopentylamino group, di(tert-pentyl)amino group, dihexylamino group, N-ethyl N-methylamino group, N-methyl-N-propylamino group, N-ethyl-N-propylamino group and the like.

The term “carboxylic acid” as used herein is represented by the formula C(O)OH.

The term “ester” as used herein is represented by the formula OC(O)A¹ or C(O)OA¹, where A¹ can be alkyl, cycloalkyl, alkenyl, cycloalkenyl, alkynyl, cycloalkynyl, aryl, or heteroaryl group as described herein. The term “polyester” as used herein is represented by the formula -(A¹O(O)C-A²-C(O)O), or -(A¹O(O)C-A²-OC(O))ₐ, where A¹ and A² can be, independently, an alkyl, cycloalkyl, alkenyl, cycloalkenyl, alkynyl, cycloalkynyl, aryl, or heteroaryl group described herein and “a” is an integer from 1 to 500. “Polyester” is as the term used to describe a group that is produced by the reaction between a compound having at least two carboxylic acid groups with a compound having at least two hydroxyl groups.

The term “ether” as used herein is represented by the formula A¹OA², where A¹ and A² can be, independently, an alkyl, cycloalkyl, alkenyl, cycloalkenyl, alkynyl, cycloalkynyl, aryl, or heteroaryl group described herein. The term “polyether” as used herein is represented by the formula -(A¹O-A²O)ₐ—, where A¹ and A² can be, independently, an alkyl, cycloalkyl, alkenyl, cycloalkenyl, alkynyl, cycloalkynyl, aryl, or heteroaryl group described herein and “a” is an integer of from 1 to 500. Examples of polyether groups include polyethylene oxide, polypropylene oxide, and polybutylene oxide.

The term “halide” as used herein refers to the halogens fluorine, chlorine, bromine, and iodine.

The term “heterocyclyl,” as used herein refers to single and multi-cyclic non-aromatic ring systems and “heteroaryl” as used herein refers to single and multi-cyclic aromatic ring systems: in which at least one of the ring members is other than carbon. The term “heterocyclyl” includes azetidine, dioxane, furan, imidazole, isothiazole, isoxazole, morpholine, oxazole, oxazole, including, 1,2,3-oxadiazole, 1,2,5-oxadiazole and 1,3,4-oxadiazole, piperazine, piperidine, pyrazine, pyrazole, pyridazine, pyridine, pyrimidine, pyrrole, pyrrolidine, tetrahydrofuran, tetrahydropyran, tetrazine, including 1,2,4,5-tetrazine, tetrazole, including 1,2,3,4-tetrazole and 1,2,4,5-tetrazole, thiadiazole, including, 1,2,3-thiadiazole, 1,2,5-thiadiazole, and 1,3,4-thiadiazole, thiazole, thiophene, triazine, including 1,3,5-triazine and 1,2,4-triazine, triazole, including, 1,2,3-triazole, 1,3,4-triazole, and the like.

The term “hydroxyl” as used herein is represented by the formula —OH.

The term “ketone” as used herein is represented by the formula A¹C(O)A², where A¹ and A² can be, independently, an alkyl, cycloalkyl, alkenyl, cycloalkenyl, alkynyl, cycloalkynyl, aryl, or heteroaryl group as described herein.

The term “azide” as used herein is represented by the formula —N₃.

The term “nitro” as used herein is represented by the formula —NO₂.

The term “nitrile” as used herein is represented by the formula —CN.

The term “ureido” as used herein refers to a urea group of the formula —NHC(O)NH₂ or —NHC(O)NH—.

The term “phosphoramide” as used herein refers to a group of the formula —P(O)(NA¹A²)₂, where A¹ and A² can be, independently, hydrogen or an alkyl, cycloalkyl, alkoxy, alkenyl, cycloalkenyl, alkynyl, cycloalkynyl, aryl, or heteroaryl group as described herein.

The term “carbamoyl” as used herein refers to an amide group of the formula —CONA¹A², where A¹ and A² can be, independently, hydrogen or an alkyl, cycloalkyl, alkoxy, alkenyl, cycloalkenyl, alkynyl, cycloalkynyl, aryl, or heteroaryl group as described herein.

The term “sulfamoyl” as used herein refers to a group of the formula S(O)₂NA¹A², where A¹ and A² can be, independently, hydrogen or an alkyl, cycloalkyl, alkoxy, alkenyl, cycloalkenyl, alkynyl, cycloalkynyl, aryl, or heteroaryl group as described herein.

The term “silyl” as used herein is represented by the formula —SiA1A²A³, where A¹, A², and A³ can be, independently, hydrogen or an alkyl, cycloalkyl, alkoxy, alkenyl, cycloalkenyl, alkynyl, cycloalkynyl, aryl, or heteroaryl group as described herein.

The term “sulfo-oxo” as used herein is represented by the formulas —S(O)A¹, S(O)₂A¹, —OS(O)₂A¹, or —OS(O)₂OA¹, where A¹ is hydrogen or an alkyl, cycloalkyl, alkenyl, cycloalkenyl, alkynyl, cycloalkynyl, aryl, or heteroaryl group as described herein. Throughout this specification “S(O)” is a short hand notation for S═O The term “sulfonyl” is used herein to refer to the sulfo-oxo group represented by the formula —S(O)₂A¹, where A¹ is hydrogen or an alkyl, cycloalkyl, alkenyl, cycloalkenyl, alkynyl, cycloalkynyl, aryl, or heteroaryl group as described herein. The term “sulfone” as used herein is represented by the formula A¹S(O)₂A², where A¹ and A² can be, independently, an alkyl, cycloalkyl, alkenyl, cycloalkenyl, alkynyl, cycloalkynyl, aryl, or heteroaryl group as described herein. The term “sulfoxide” as used herein is represented by the formula A¹S(O)A², where A¹ and A² can be, independently, an alkyl, cycloalkyl, alkenyl, cycloalkenyl, alkynyl, cycloalkynyl, aryl, or heteroaryl group as described herein.

The term “thiol” as used herein is represented by the formula SH.

“R,” “R¹,” “R²,” “R³,” “Rⁿ,” where n is an integer, as used herein can, independently, include hydrogen or one or more of the groups listed above. For example, if R¹ is a straight chain alkyl group, one of the hydrogen atoms of the alkyl group can optionally be substituted with a hydroxyl group, an alkoxy group, an alkyl group, a halide, and the like. Depending upon the groups that are selected, a first group can be incorporated within a second group or, alternatively, the first group can be pendant (i.e., attached) to the second group. For example, with the phrase “an alkyl group comprising an amino group,” the amino group can be incorporated within the backbone of the alkyl group. Alternatively, the amino group can be attached to the backbone of the alkyl group. The nature of the group(s) that is (are) selected will determine if the first group is embedded or attached to the second group.

As described herein, compounds of the disclosure may contain “optionally substituted” moieties. In general, the term “substituted,” whether preceded by the term “optionally” or not, means that one or more hydrogens of the designated moiety are replaced with a suitable substituent. Unless otherwise indicated, an “optionally substituted” group may have a suitable substituent at each substitutable position of the group, and when more than one position in any given structure may be substituted with more than one substituent selected from a specified group, the substituent may be either the same or different at every position. Combinations of substituents envisioned by this disclosure are preferably those that result in the formation of stable or chemically feasible compounds. It is also contemplated that, in certain aspects, unless expressly indicated to the contrary, individual substituents can be further optionally substituted (i.e., further substituted or unsubstituted).

In some aspects, a structure of a compound can be represented by a formula:

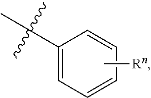

which is understood to be equivalent to a formula:

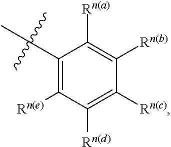

wherein n is typically an integer. That is, Rⁿ is understood to represent five independent substituents, R^{n(a)}, R^{n(b)}, R^{n(c)}, R^{n(d)}, R^{n(e)}. By “independent substituents,” it is meant that each R substituent can be independently defined. For example, if in one instance R^{n(a)} is halogen, then R^{n(b)} is not necessarily halogen in that instance.

Several references to R, R¹, R², R³, R⁴, R⁵, R⁶, etc. are made in chemical structures and moieties disclosed and described herein. Any description of R, R¹, R², R³, R⁴, R⁵, R⁶, etc in the specification is applicable to any structure or moiety reciting R, R¹, R², R³, R⁴, R⁵, R⁶, etc. respectively.

### Compounds

Owing to the potential of phosphorescent tetradentate platinum complexes for harvesting both electro-generated singlet and triplet excitions to achieve 100% internal quantum efficiency, these complexes are good candidate for the emitting materials of OLEDs. In some cases, there is an “emitting portion” and an “ancillary portion” in a ligand of platinum complex (e.g., a tetradentate platinum complex). If stabilizing substitution(s), such as conjugated group(s), aryl or heteroaroniatic substitution(s) and so on, were introduced into the emitting portion, the “Highest Occupied Molecular Orbital” (HOMO) energy level, the “Lowest Unoccupied Molecular Orbital” (LUMO) energy level, or both may be changed. So the energy gap between the HOMO and LUMO can be tuned. Thus, the emission spectra of phosphorescent tetradentate platinum complexes can be modified to lesser or greater extents, such that the emission spectra can become narrower or broader, such that the emission spectra can exhibit a blue shift or a red shift, or a combination thereof.

The emission of such disclosed complexes can be tuned, for example, from the ultraviolet to near-infrared, by, for example, modifying the ligand structure. In another aspect, the disclosed complexes can provide emission over a majority of the visible spectrum. In a specific example, the disclosed complexes can emit light over a range of from about 400 nm to about 700 nm. In another aspect, the disclosed complexes have improved stability and efficiency over traditional emission complexes. In yet another aspect, the disclosed complexes can be useful as luminescent labels in, for example, bio-applications, anti-cancer agents, emitters in organic light emitting devices (OLED), or a combination thereof. In another aspect, the disclosed complexes can be useful in light emitting devices, such as, for example, compact fluorescent lamps (CFL), light emitting diodes (LED), incandescent lamps, and combinations thereof.

A series of functionalized imidazophenthridine and analogues based blue phosphorescent emitters have been designed, where bulky substituents (R²)ₙ (e.g. tetrabutyl, phenyl, mesityl, triisopropylbenzene, etc.) are chosen to introduce on imidazophenthridine fragment of the emitters. While not wishing to be bound by any particular scientific theory, there are two main purposes for introducing bulky substituents: first, the bulky substituents can suppress the planarity of the complexes to eliminate the potential excimer formation; second, the substituents can as well as improve the solubility of the complexes. This class of emitters could be utilized in, for example, full color displays and lighting applications.

The compounds can also have other known emission mechanisms which are useful in devices.

Disclosed herein are compounds or compound complexes comprising platinum and/or palladium. The terms compound, complex, or combinations thereof, are used interchangeably herein. In one aspect, the compounds disclosed herein have a neutral charge.

The compounds disclosed herein can exhibit desirable properties and have emission spectra, absorption spectra, or both that can be tuned via the selection of appropriate ligands. In another aspect, the present disclosure can exclude any one or more of the compounds, structures, or portions thereof, specifically recited herein.

The compounds disclosed herein are suited for use in a wide variety of optical and electro-optical devices, including, but not limited to, photo-absorbing devices such as solar- and photo-sensitive devices, organic light emitting devices (OLEDs), photo-emitting devices, or devices capable of both photo-absorption and emission and as markers for bio-applications.

As briefly described above, the disclosed compounds are platinum and/or palladium complexes. In one aspect, the compounds disclosed herein can be used as host materials for OLED applications, such as full color displays.

The compounds disclosed herein are useful in a variety of applications. As light emitting materials, the compounds can be useful in organic light emitting devices (OLEDs), luminescent devices and displays, and other light emitting devices.

In another aspect, the compounds can provide improved efficiency, improved operational lifetimes, or both in lighting devices, such as, for example, organic light emitting devices, as compared to conventional materials.

The compounds of the disclosure can be made using a variety of methods, including, but not limited to those recited in the examples provided herein,

### Compounds

In one aspect, the present disclosure relates to compounds of General formula 1, General formula II, General formula III, or General formula IV:

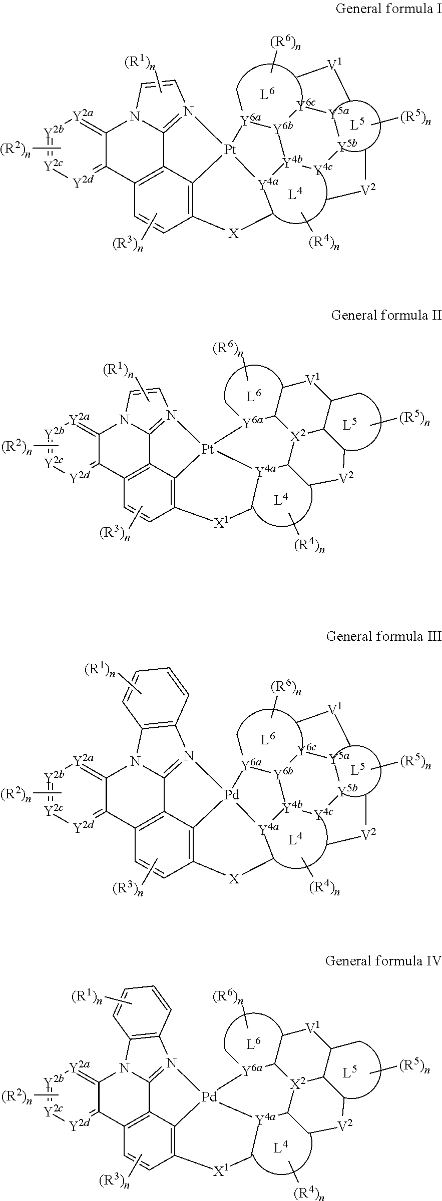

wherein, in General formula I to IV,
Y^{2a}, Y^{2b}, Y^{2c}, Y^{2d}, Y^{4a}, Y^{4b}, Y^{4c}, Y^{5a}, Y^{5b}, Y^{6a}, Y^{6b}, Y^{6c}, and X² each independently represent C or N;
X, X¹, V¹, and V² each independently represent no bond, O, S, Se NR⁷, PR⁷, AsR⁷, SbR⁷, BiR⁷, R⁷P═O, R⁷As═O, R⁷Bi═O, BR⁷, AlR⁷, CR⁷R⁸, SiR⁷R⁸, GeR⁷R⁸, C═O, SO₂, or SeO₂; each occurrence of R² independently represents substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
each of R, R¹, R³, R⁴, R⁵, R⁶, R⁷ and R⁸ is independently absent or present as a single substituent or multiple substituents, valency permitting, and each of R, R¹, R³, R⁴, R⁵, R⁶, R⁷, and R⁸ independently represents deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
each n is independently an integer, valency permitting; and
L⁴, L⁵, and L⁶ each independently represents a 5- to 10-membered aryl, heteroaryl, fused aryl, or fused heteroaryl.

In one embodiment, the compound of General formula I, General formula II, General formula III, or General formula IV, is a compound of General formula V, General formula VI, General formula VII, or General formula VIII:

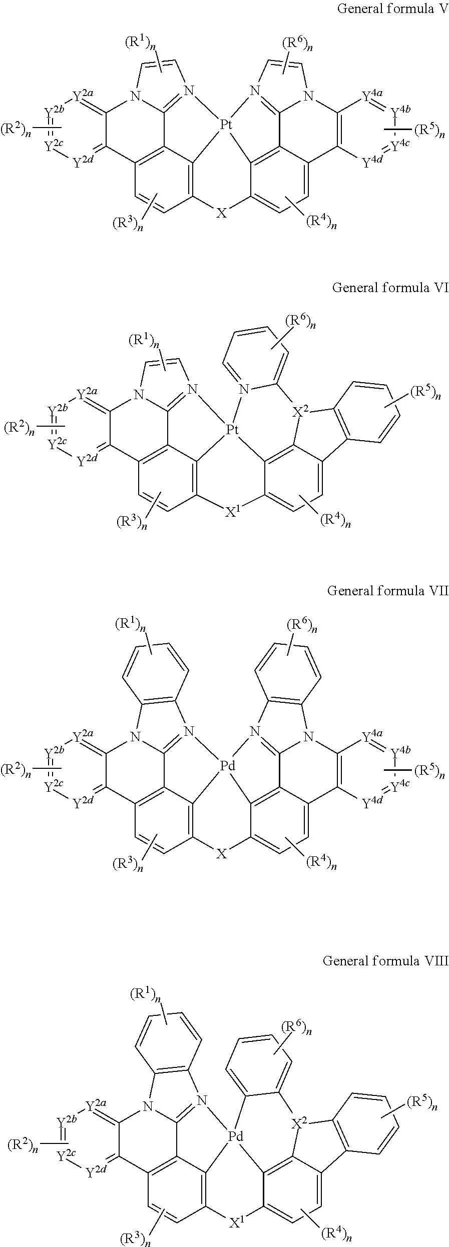

wherein, in General formula V to VIII;
Y^{2a}, Y^{2b}, Y^{2c}, Y^{2d}, Y^{4a}, Y^{4b}, Y^{4c}, Y^{4d} and X² each independently represents C or N,
each of X and X¹ independently represents no bond, O, S, Se, NR⁷, PR⁷, AsR⁷, SbR⁷, BiR⁷, R⁷P═O, R⁷As═O, R⁷Bi═O, BR⁷, AlR⁷, CR⁷R⁸, SiR⁷R⁸, GeR⁷R⁸, C═O, SO₂, or SeO₂;
each of R, R¹, R³, R⁴, R⁵, R⁶, R⁷ and R⁸ is independently absent or present as a single substituent or multiple substituents, valency permitting, and each of R, R¹, R³, R⁴, R⁵, R⁶, R⁷ and R⁸ independently represents deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, nonoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof; and
each n is independently an integer, valency permitting.

In one embodiment, the compound has a neutral charge.

In one embodiment, X and X¹ are present or not present. In one embodiment, when X or X¹ is not present, then that variable represents no bond. In one embodiment, X and X are both present. In one embodiment, neither of X¹ and X² represent no bond. In one embodiment, X and Xⁱ each independently represent O, NR⁷, CR⁷R⁸, or SiR⁷R⁸. In one embodiment, X² represents N. In one embodiment, at least one of Y^{2a}, Y^{2b}, Y^{2c}, Y^{2d}, Y^{4a}, Y^{4b}, Y^{4c} and Y^{4d} represents N. In one embodiment, only one of Y^{2a}, Y^{2b}, Y^{2c}, Y^{2d}, Y^{4a}, Y^{4b}, Y^{4c}, and Y^{4d} represents N and the remaining of Y^{2a}, Y^{2b}, Y^{2c}, Y^{2d}, Y^{4a}, Y^{4b}, Y^{4c}, and Y^{4d} represent C.

In one embodiment, L⁶ is 5- to 10-membered heteroaryl or fused heteroaryl. In one embodiment, L⁶ is imidazole, benzimidazole, or pyridine.

In one embodiment, V¹ and V² are present or not present. In one embodiment, when V¹ or V² is not present, then that variable represents no bond. In one embodiment, at least one of V¹ and V² represents no bond. In one embodiment, at least one of V¹ and V² is not present.

In one embodiment, each occurrence of R² is independently selected from the group consisting of substituted or unsubstituted alkyl, substituted or unsubstituted aryl, or combinations thereof. In one embodiment, at least one occurrence of R⁵ is selected from the group consisting of substituted or unsubstituted alkyl, substituted or unsubstituted aryl, or combinations thereof.

In one embodiment, each occurrence of R² is independently selected from the group consisting of the following:

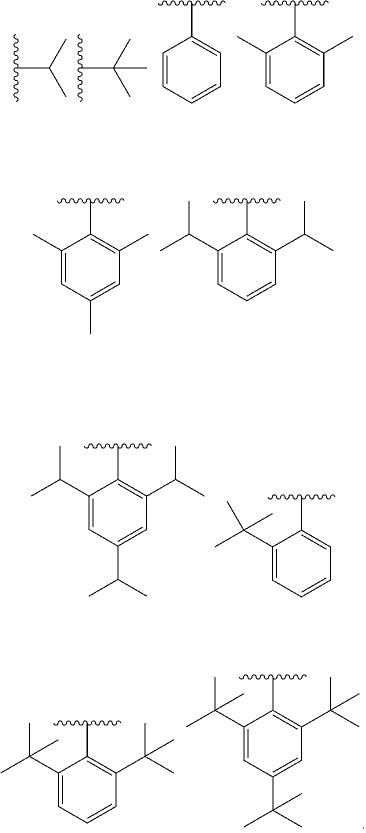

Exemplary substituents R¹ and R³ to R⁸ include, but are not limited to, the following:

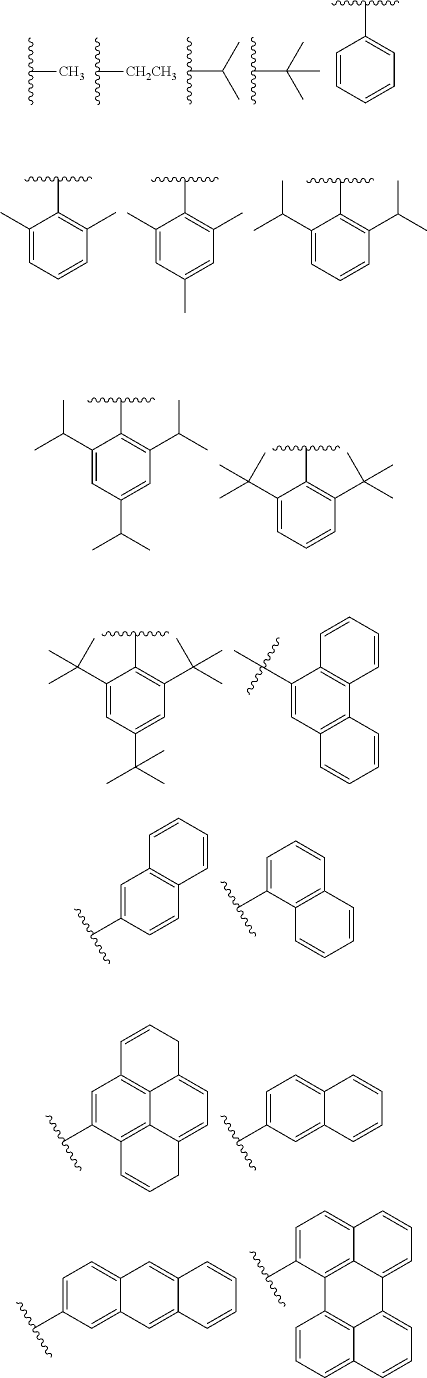

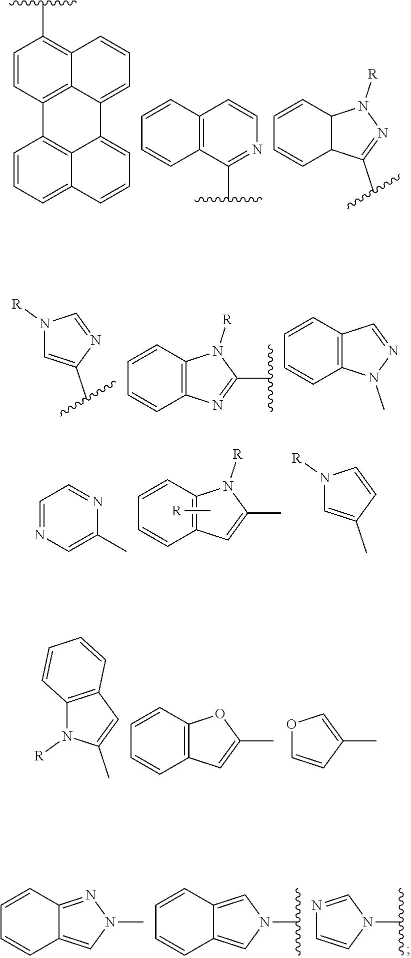

wherein each of R independently represents hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoaryl amino, diarylamino, alkoxy, aryloxy, haloalkyl, aralkyl, ester, alkoxy carbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

Exemplary complexes of General formula I to VIII include, but are not limited to, the following complexes:

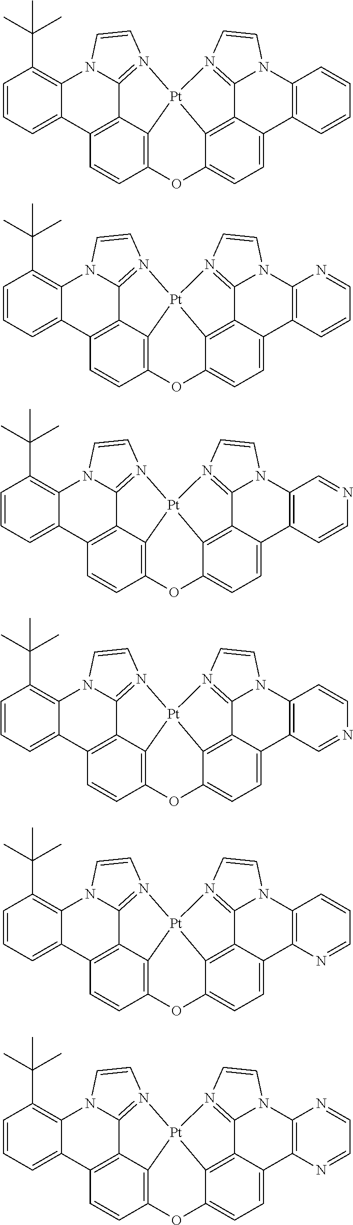

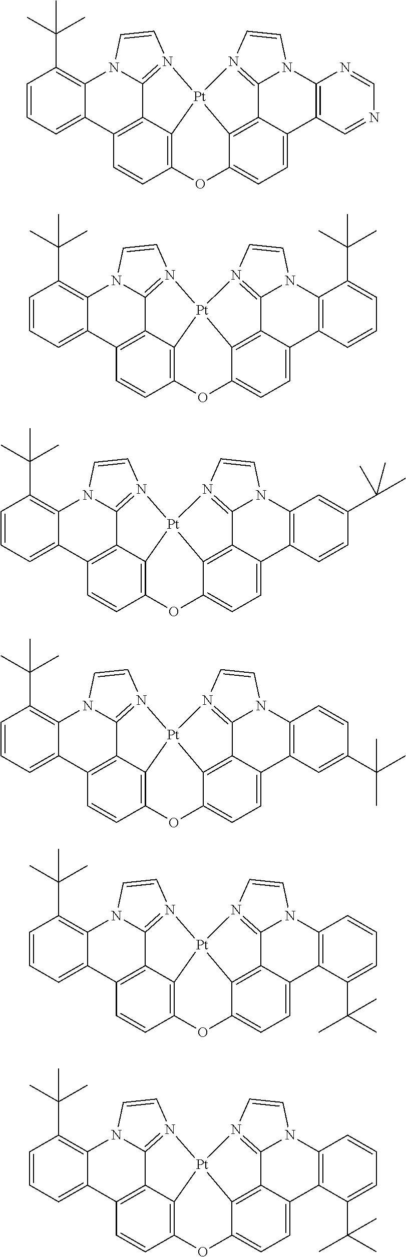

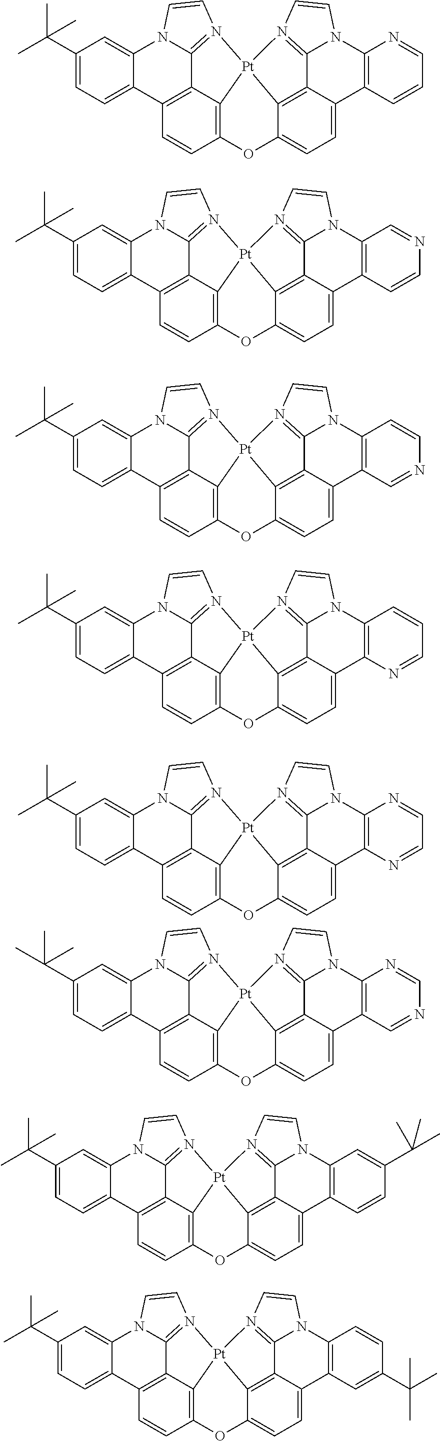

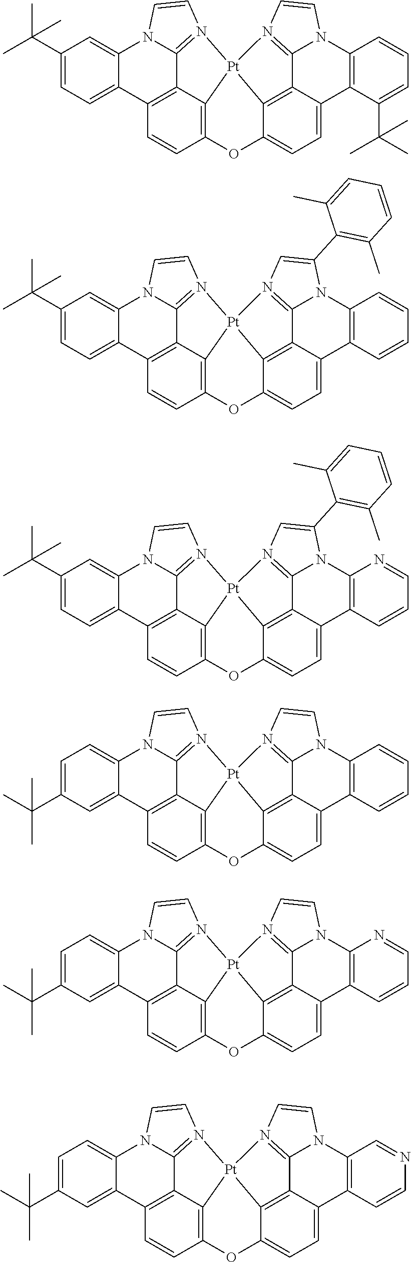

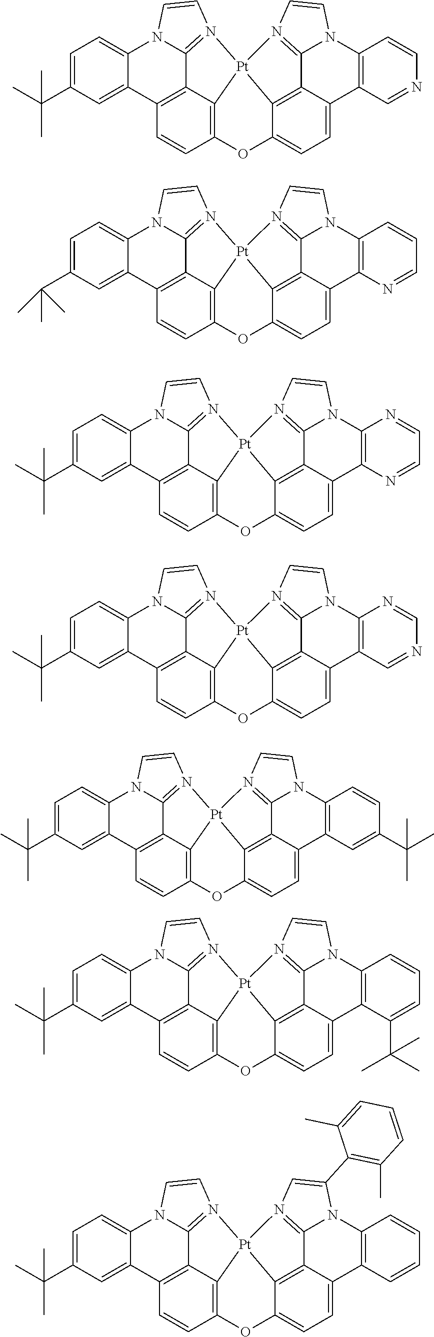

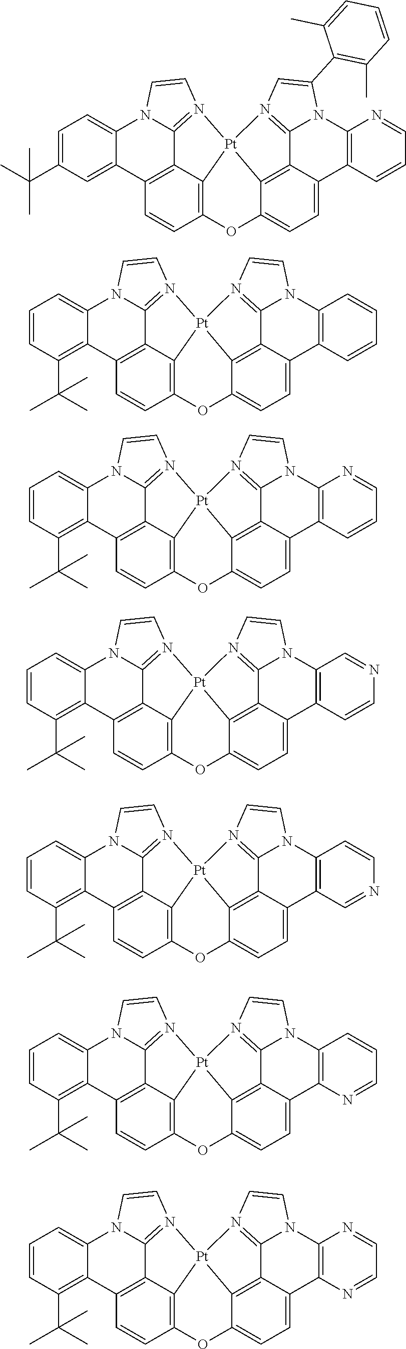

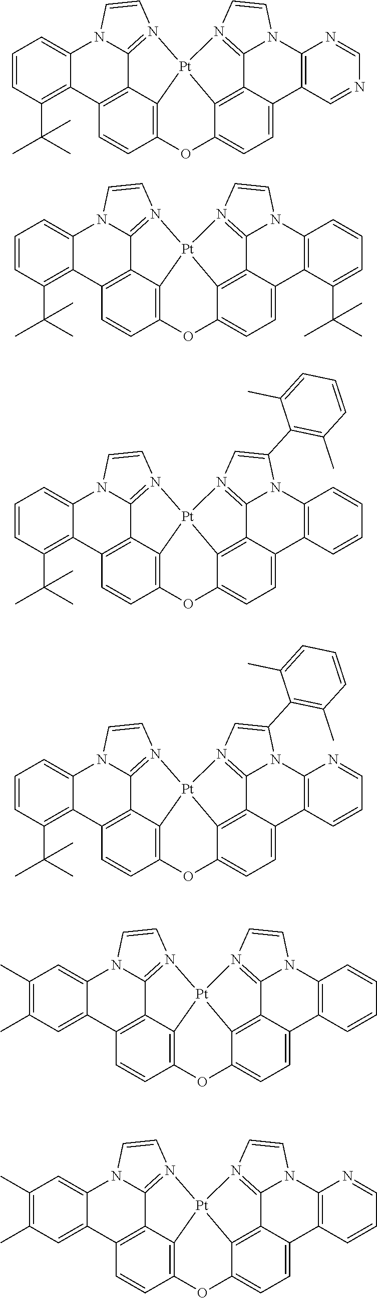

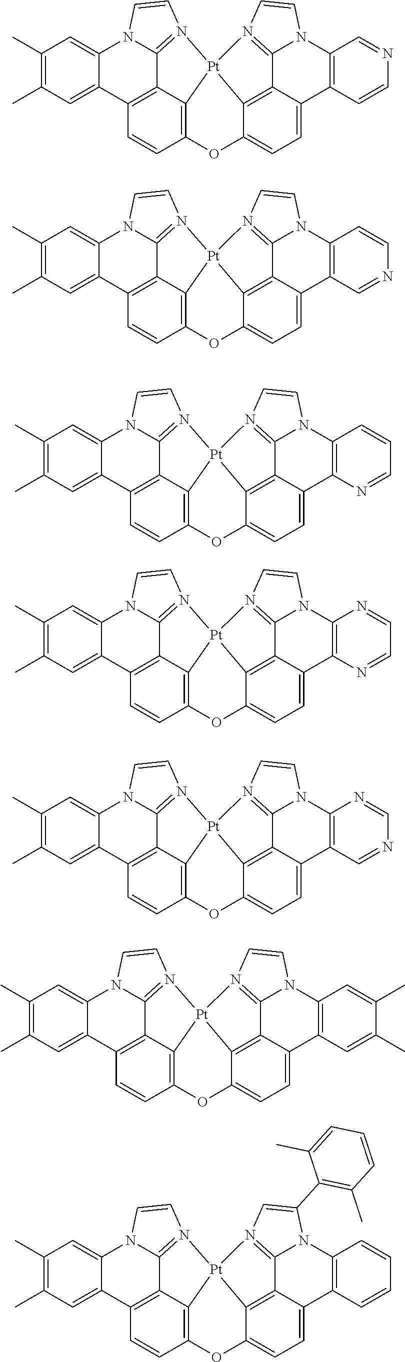

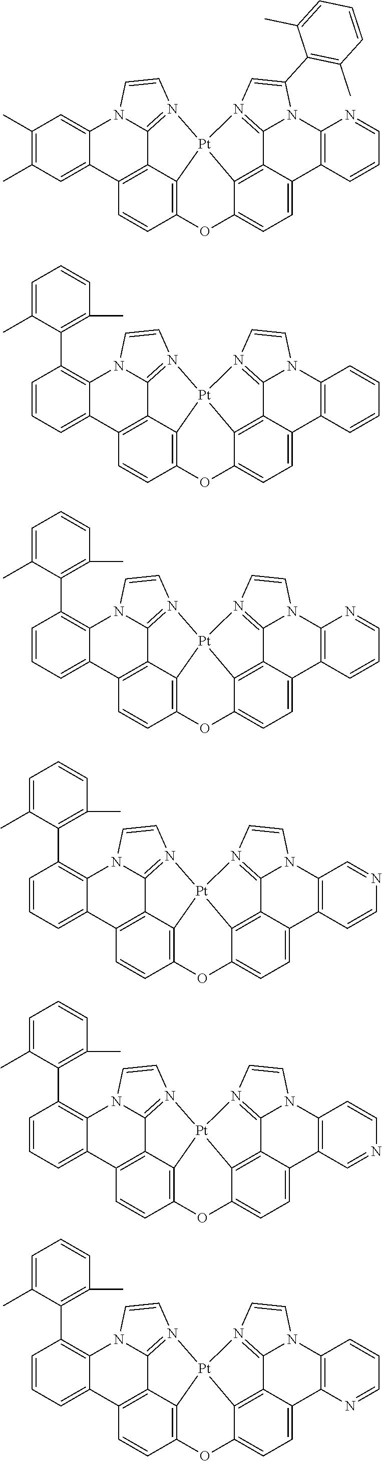

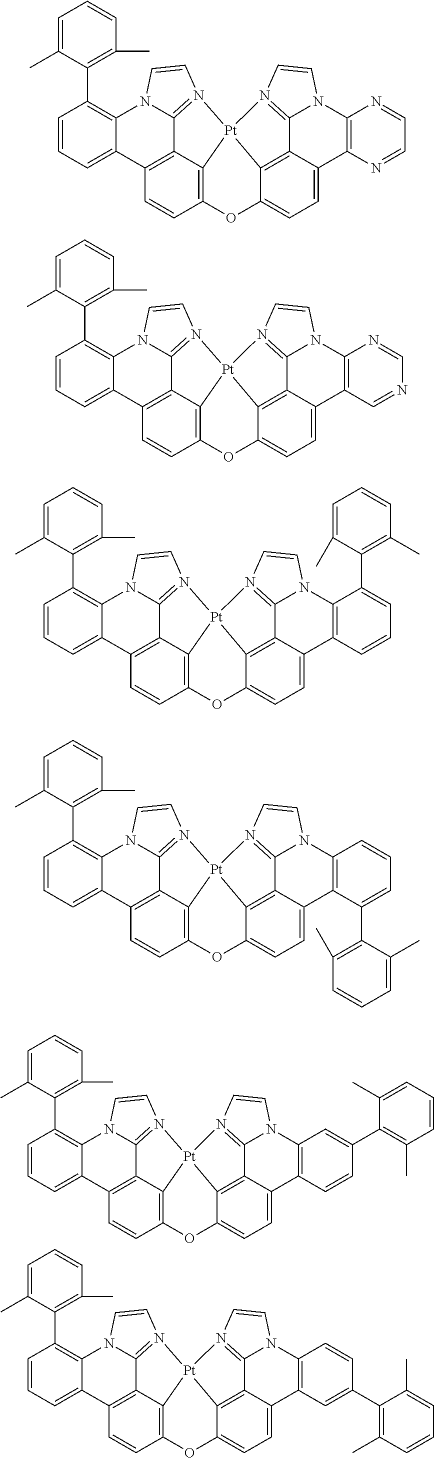

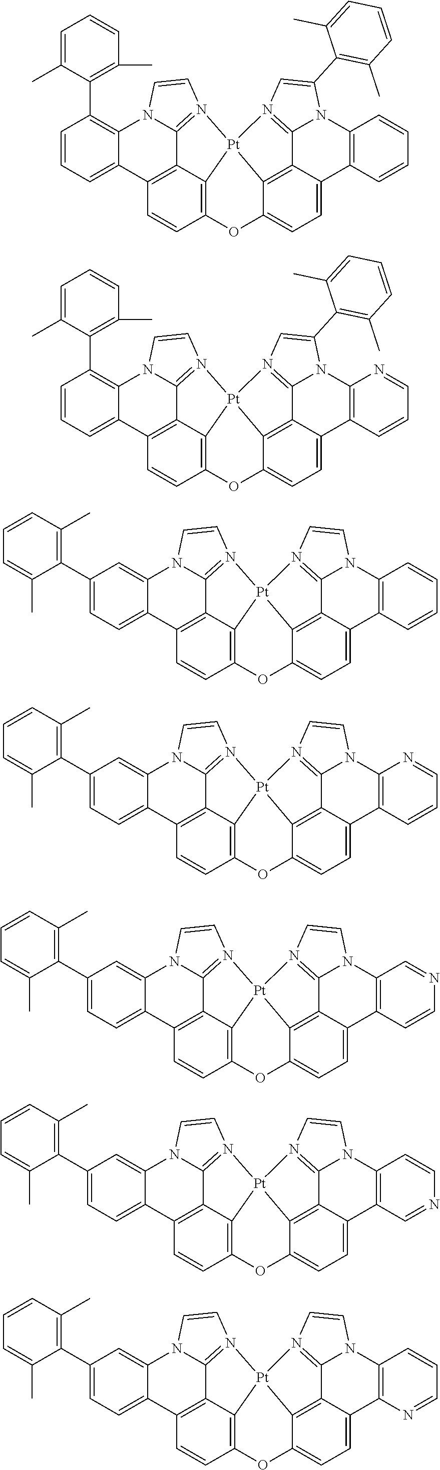

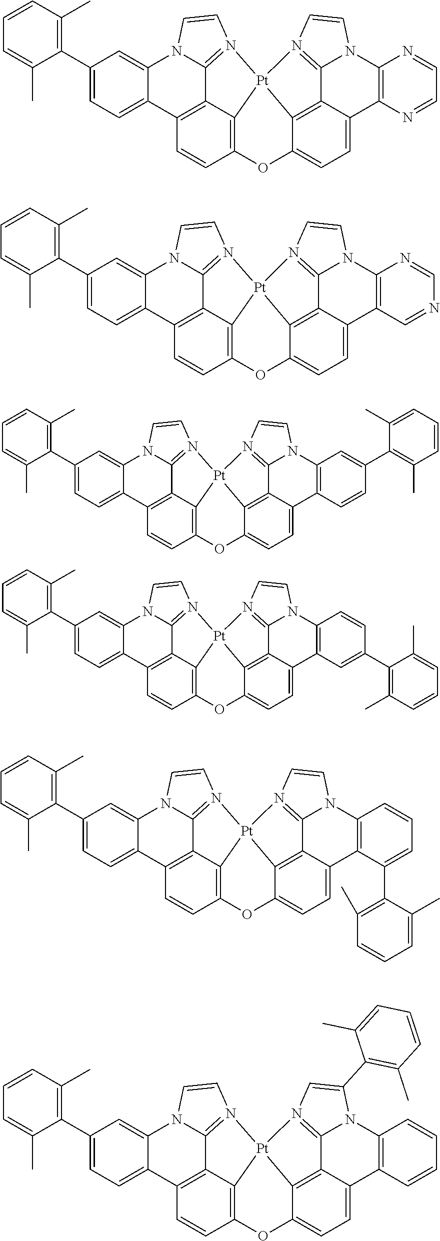

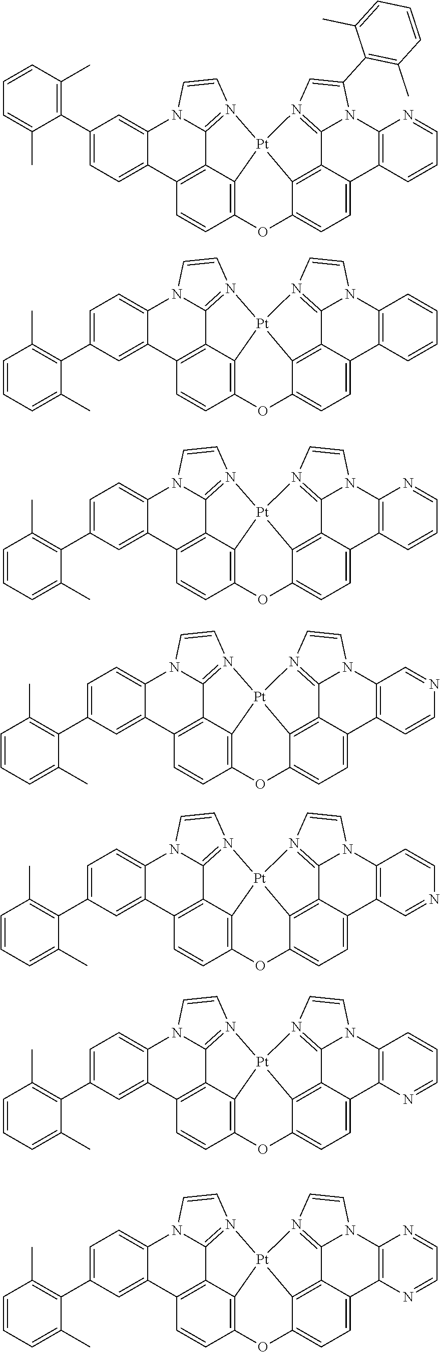

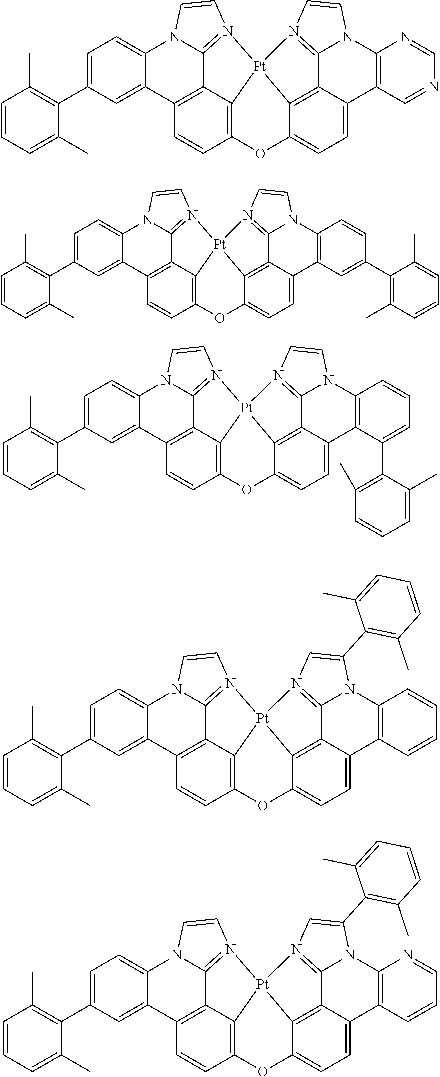

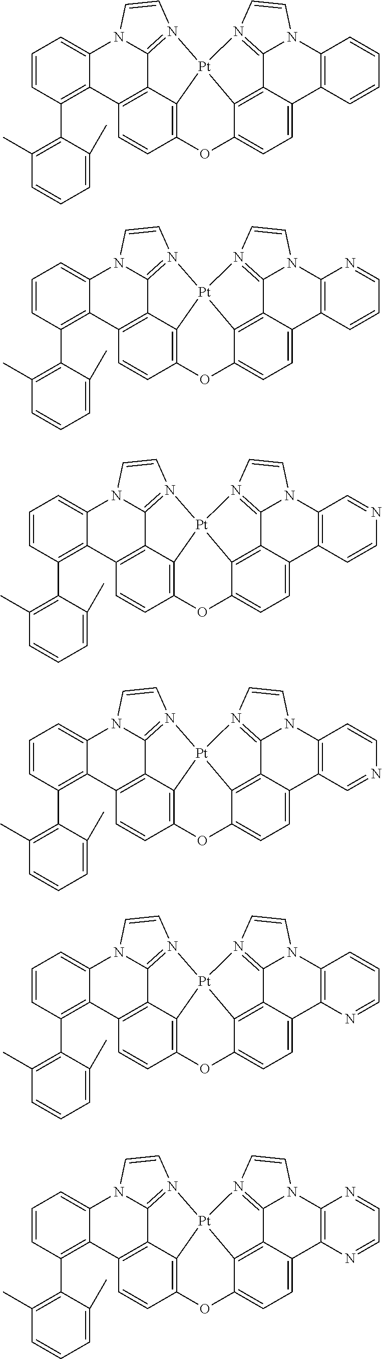

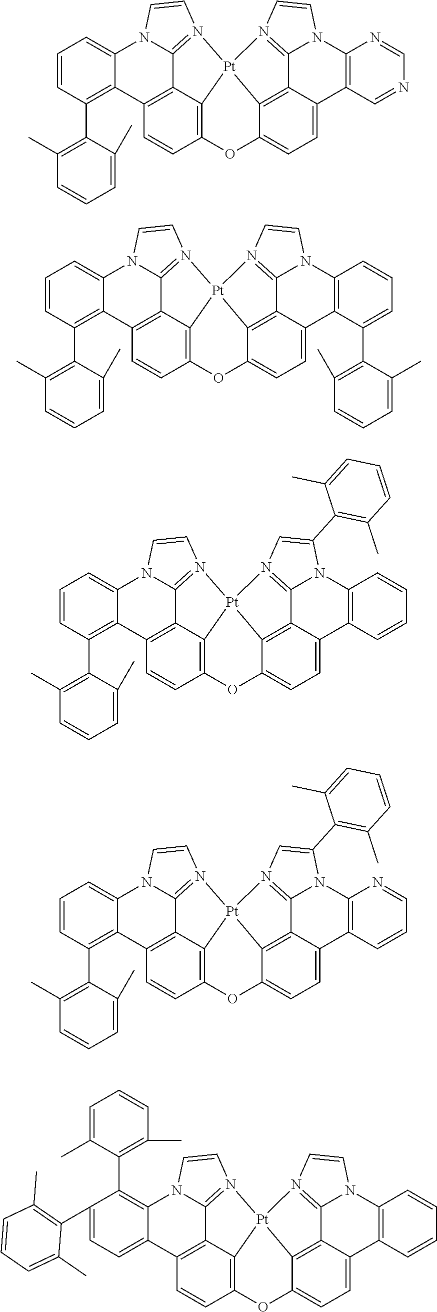

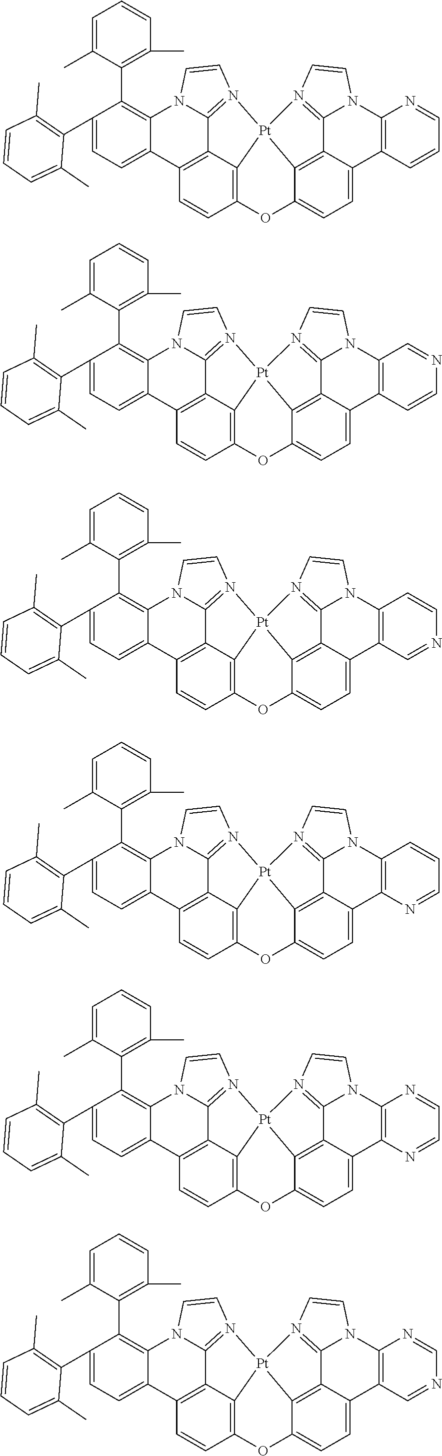

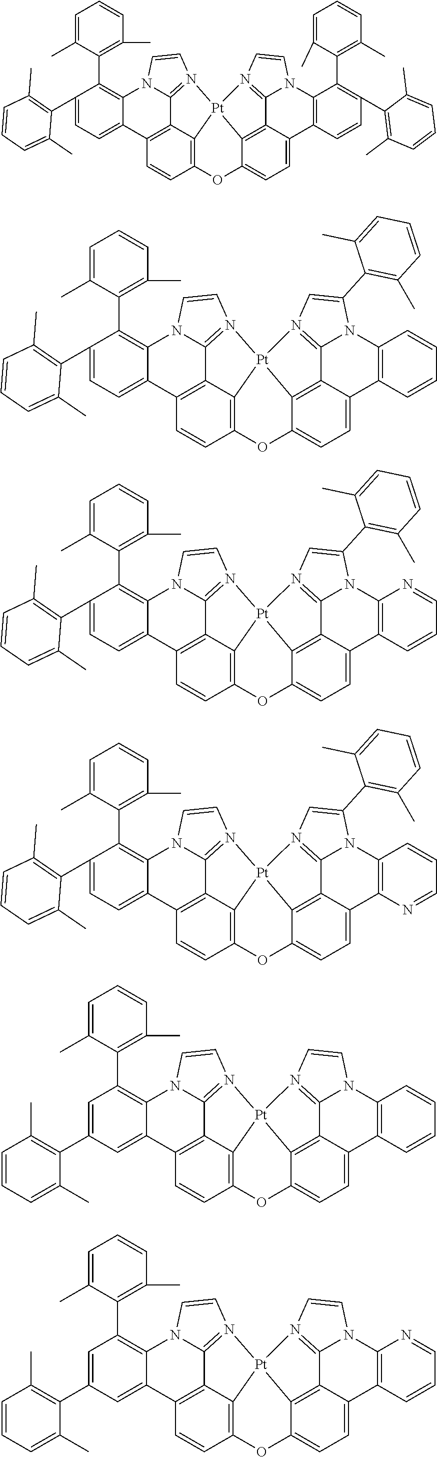

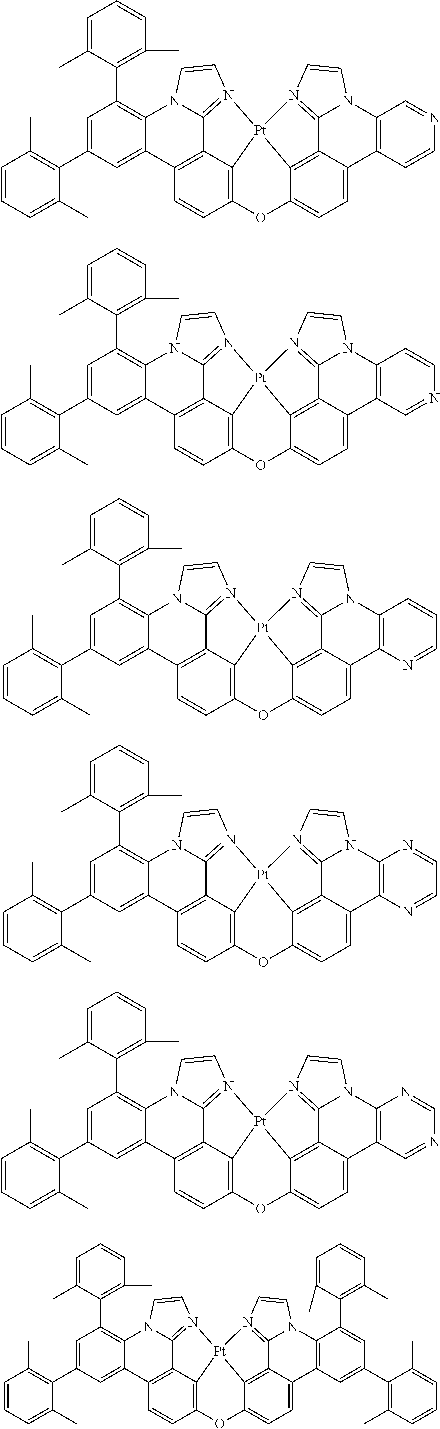

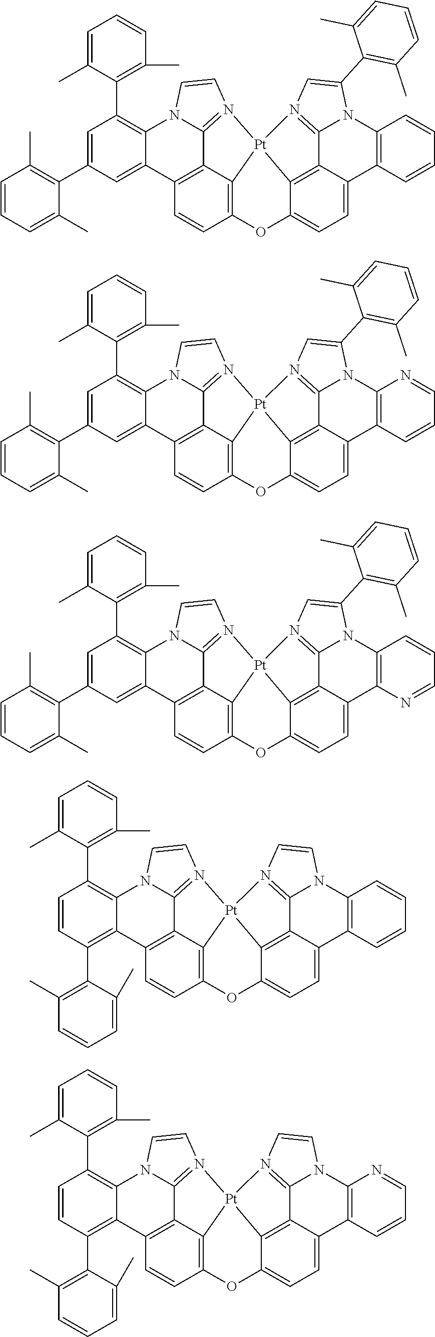

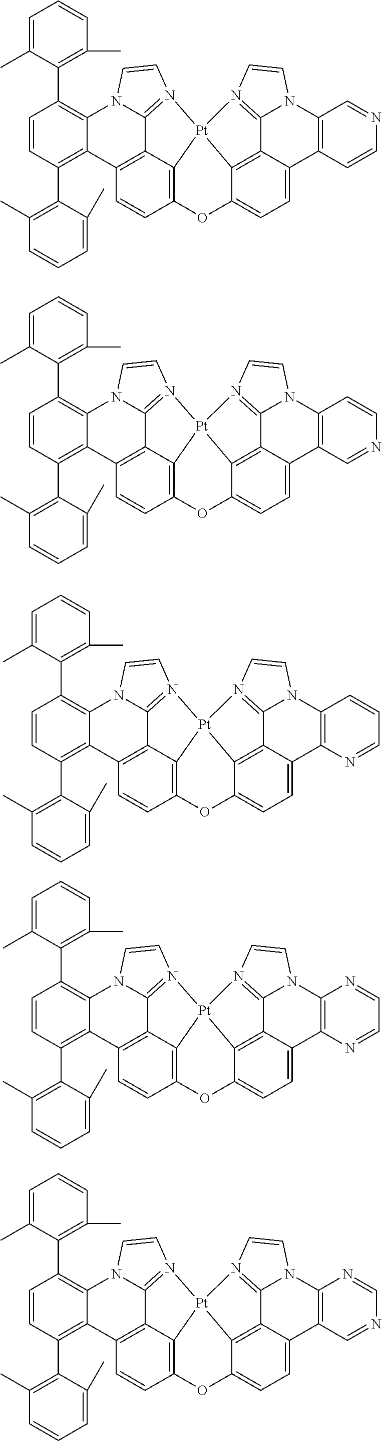

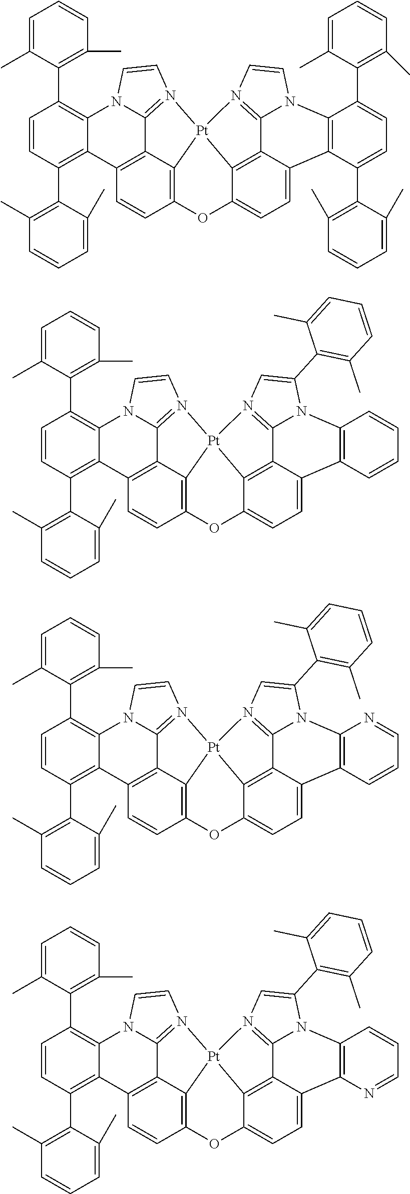

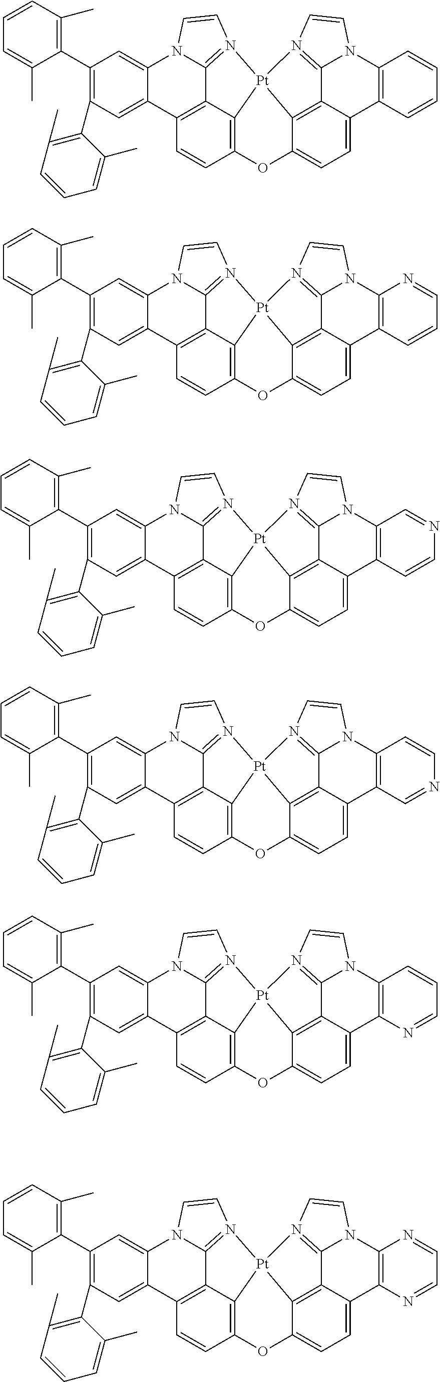

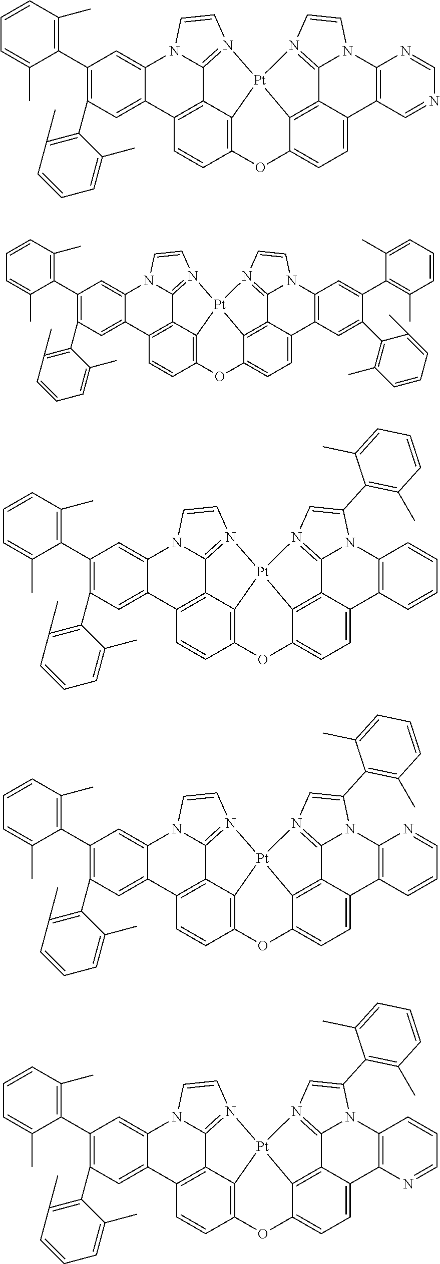

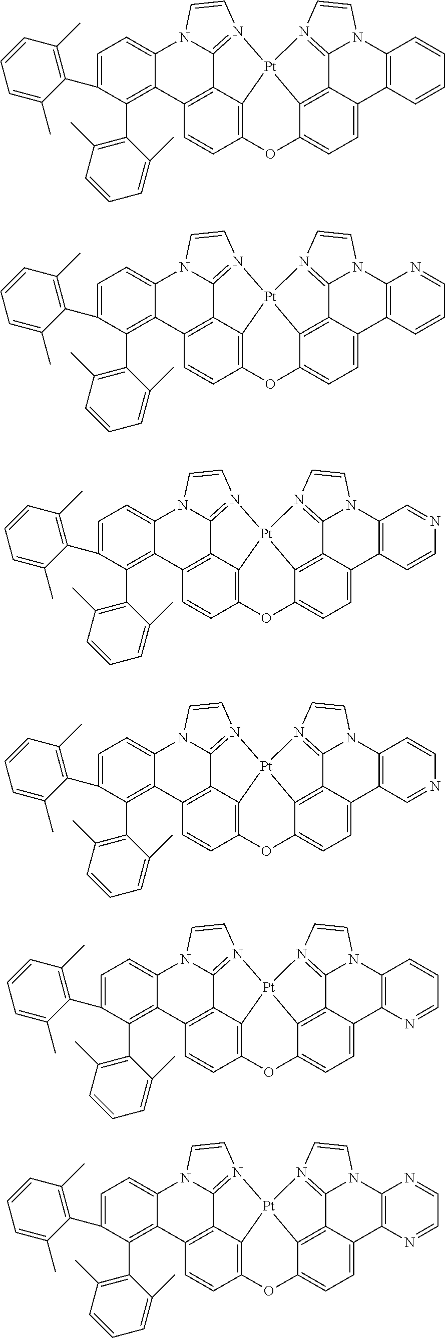

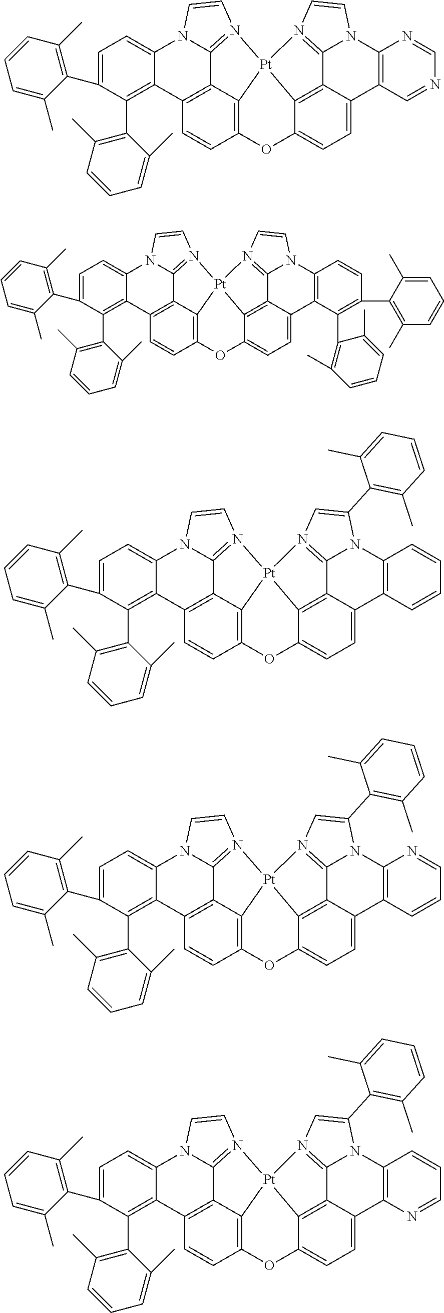

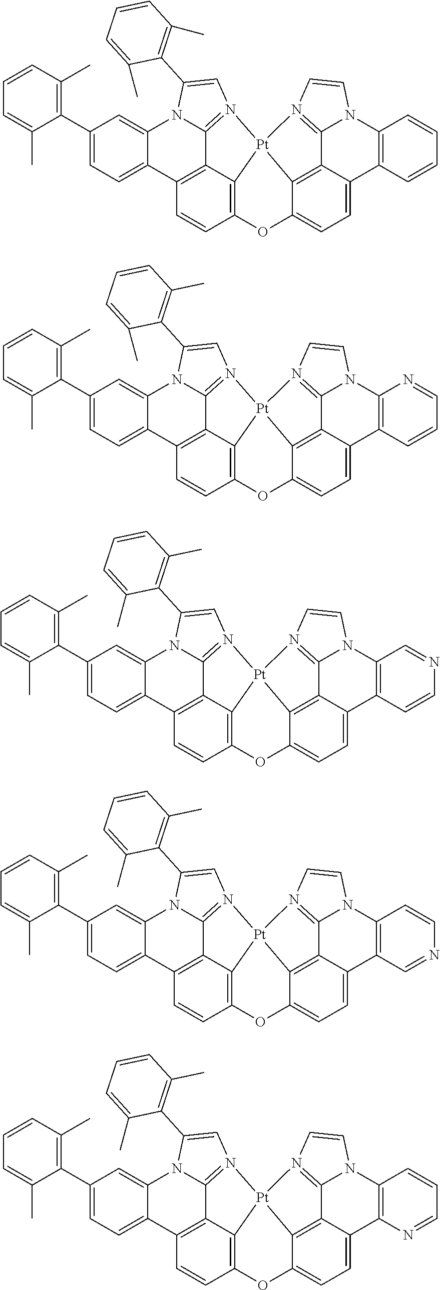

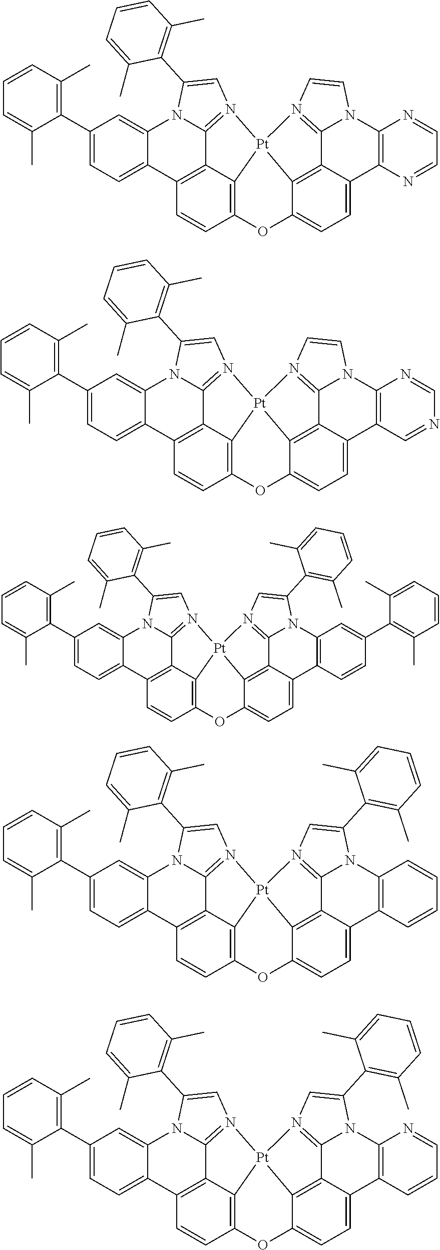

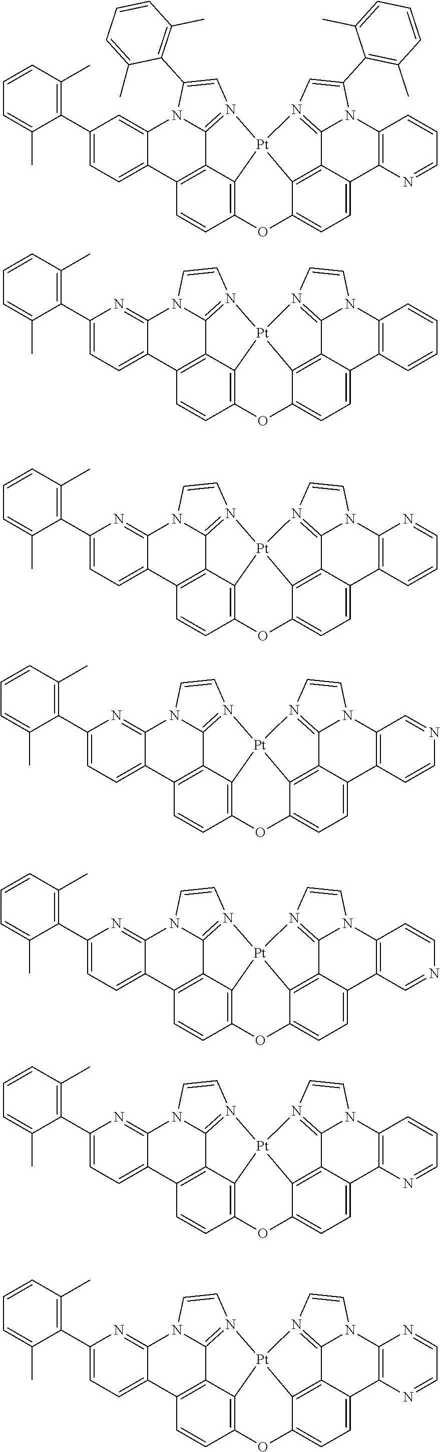

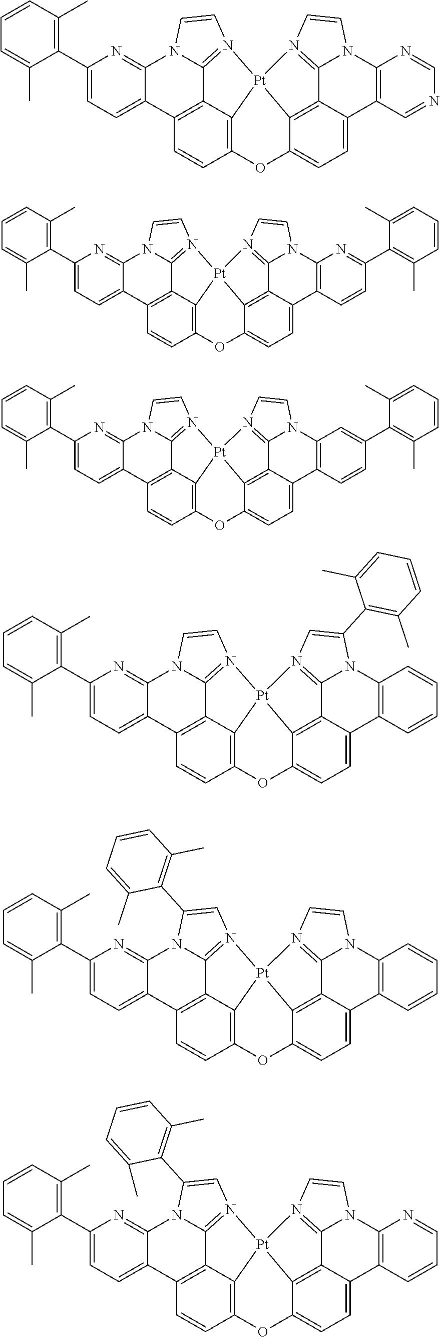

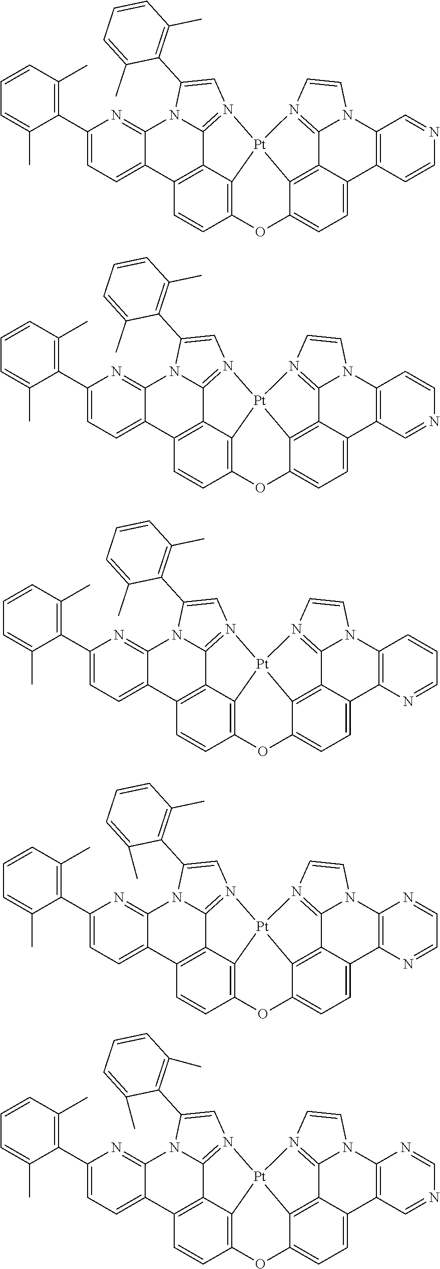

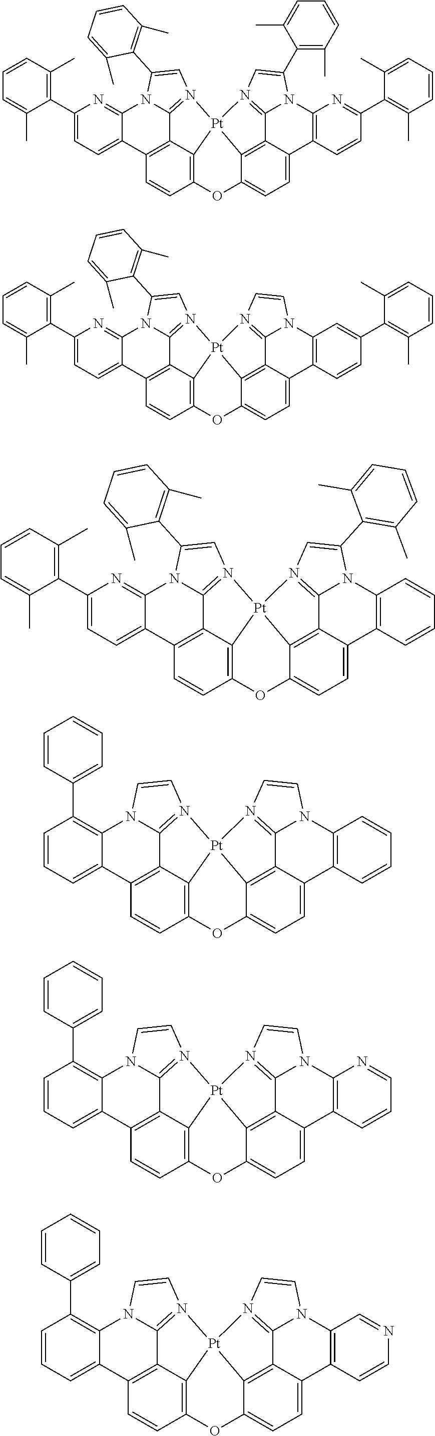

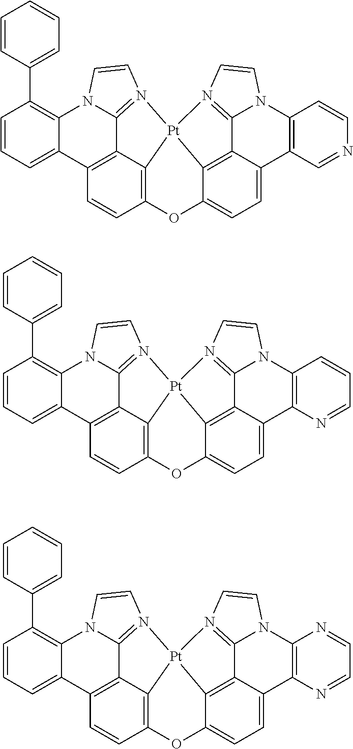

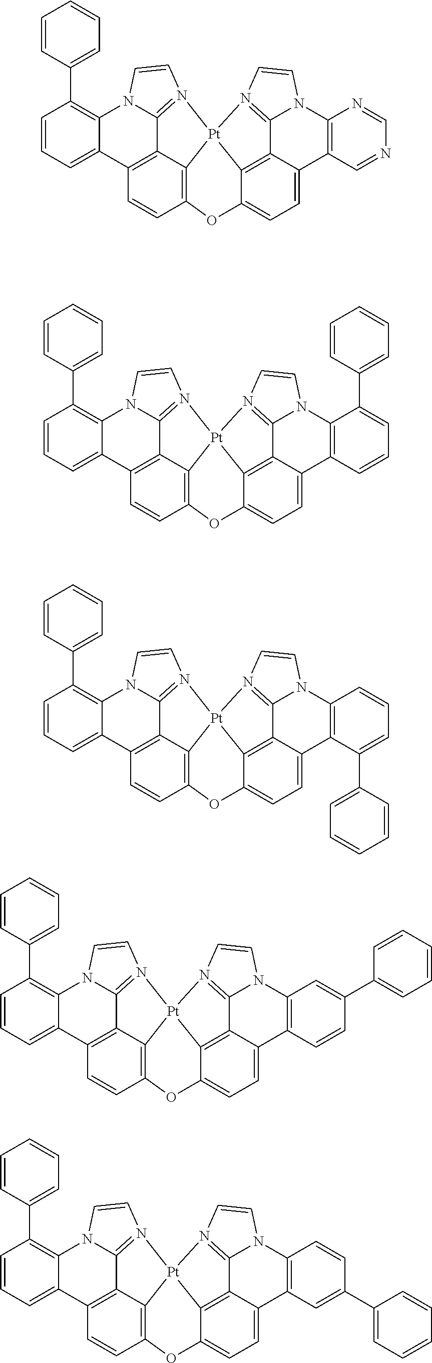

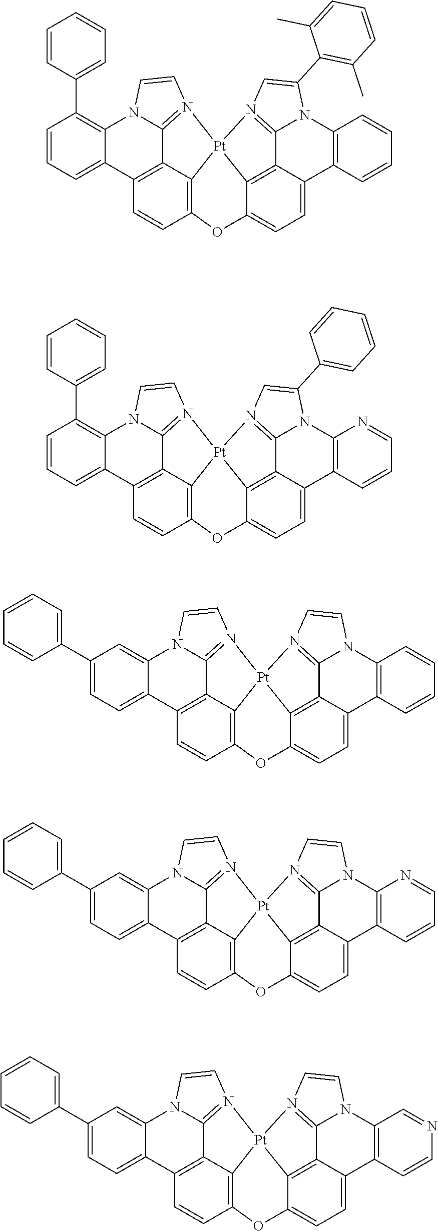

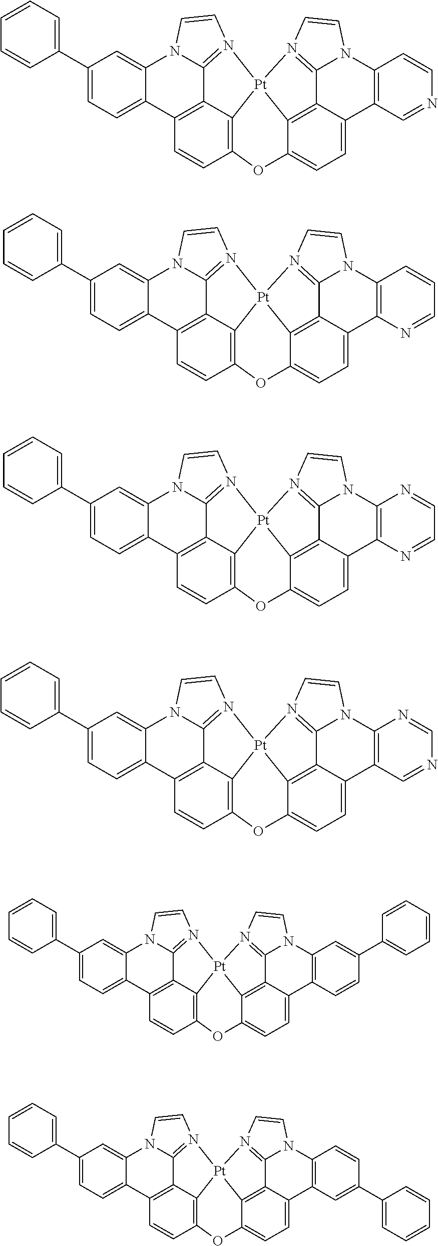

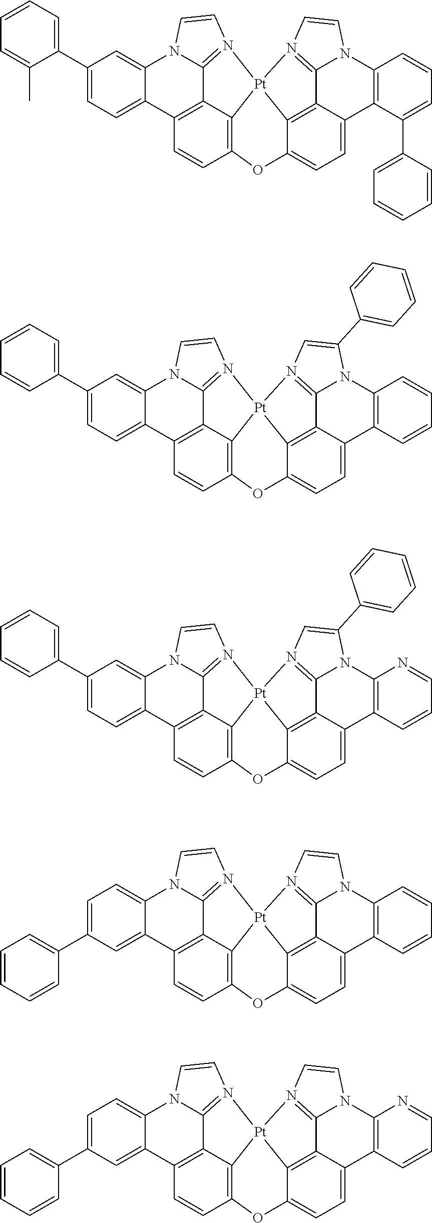

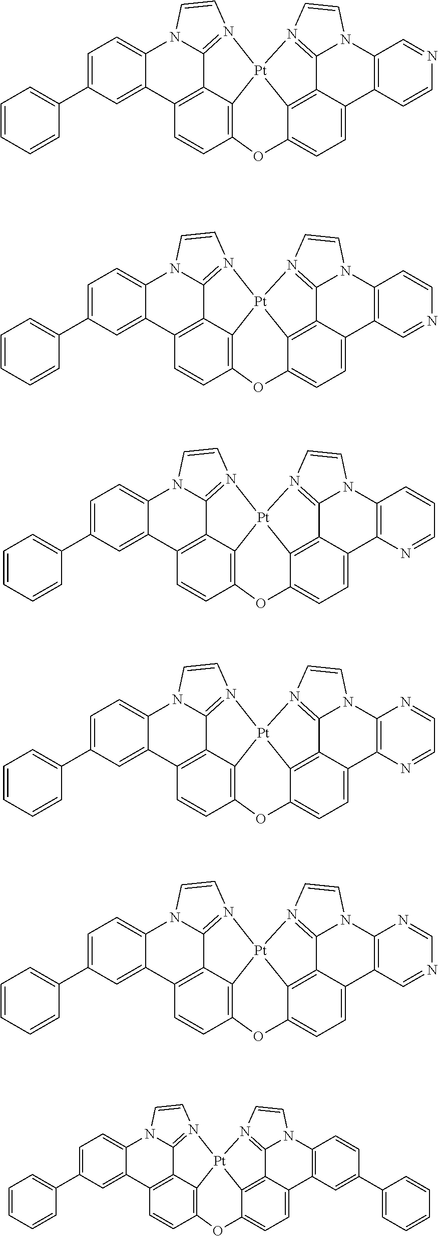

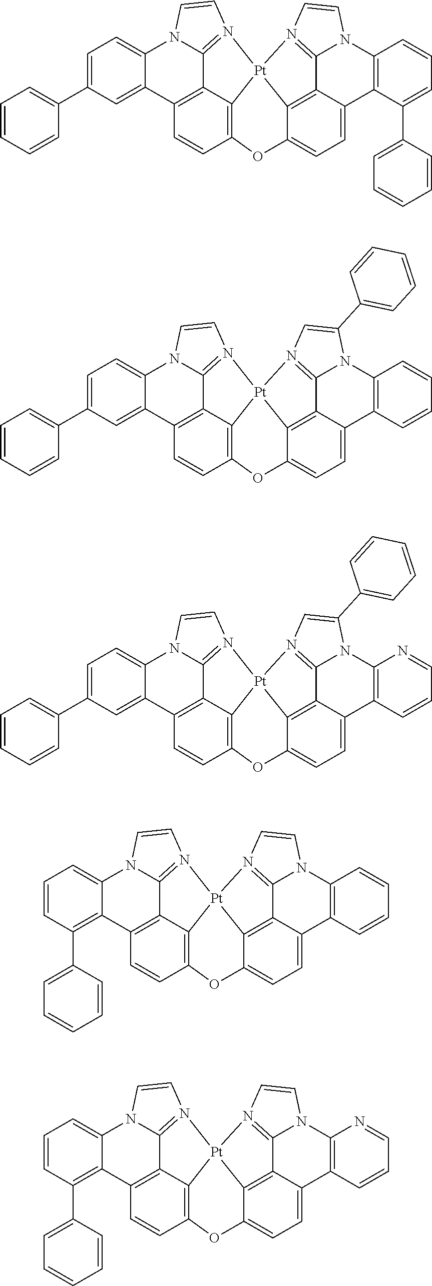

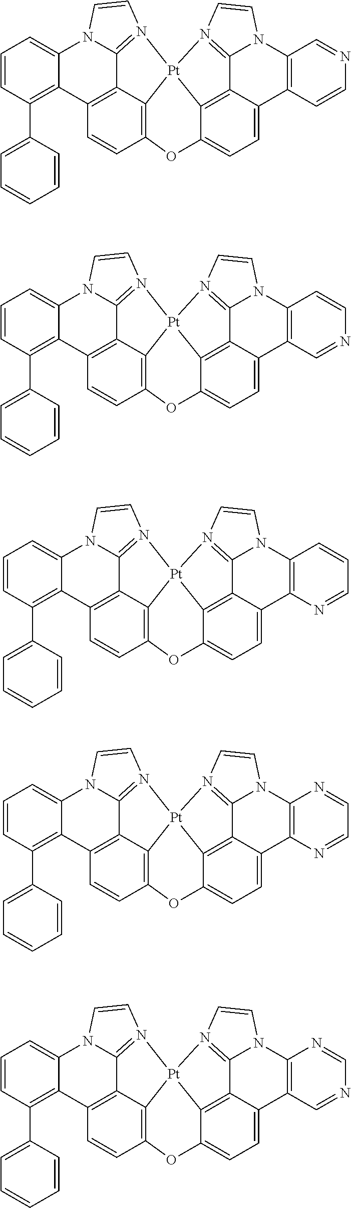

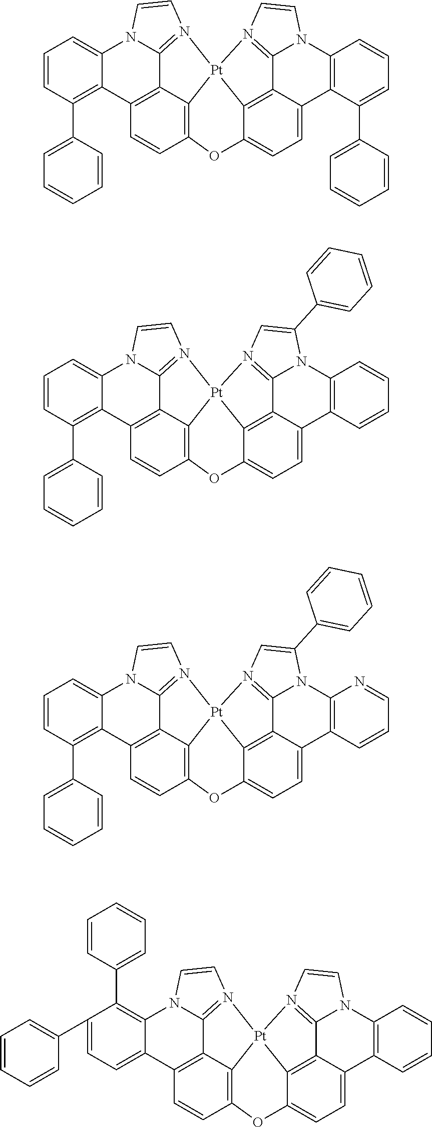

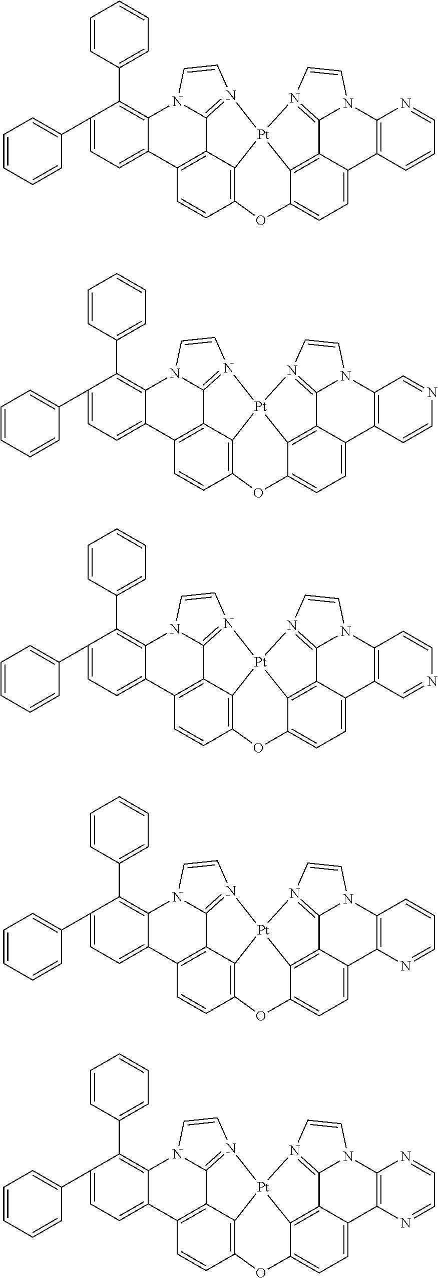

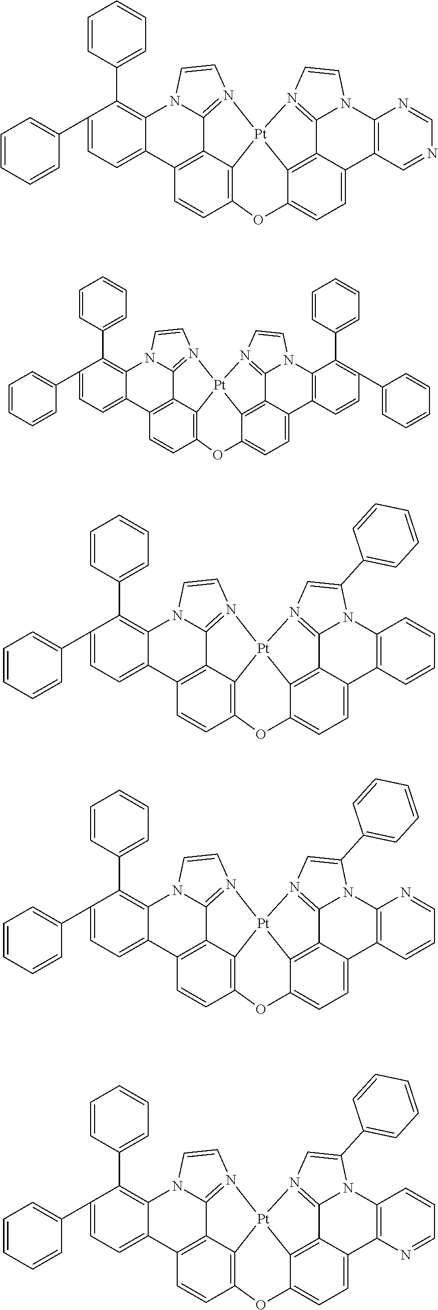

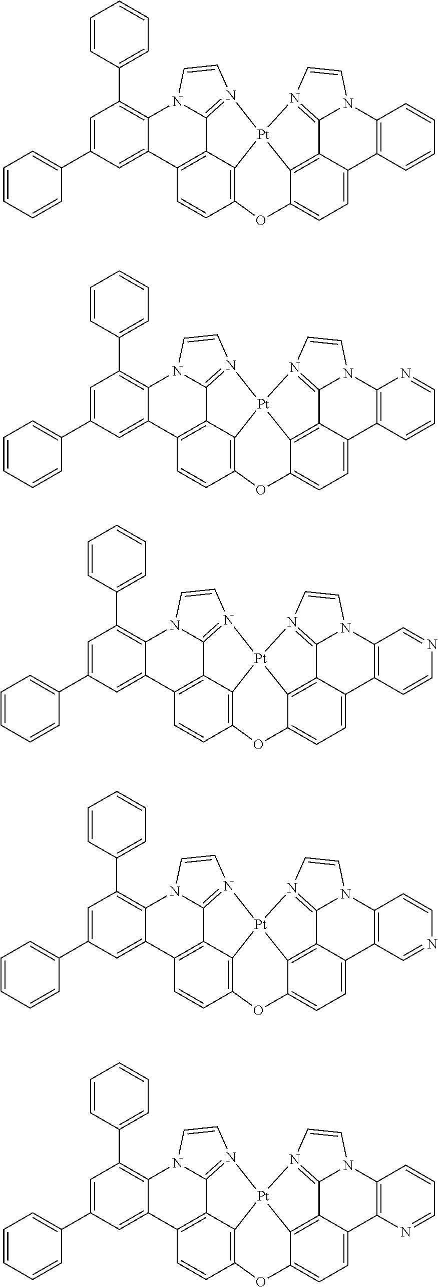

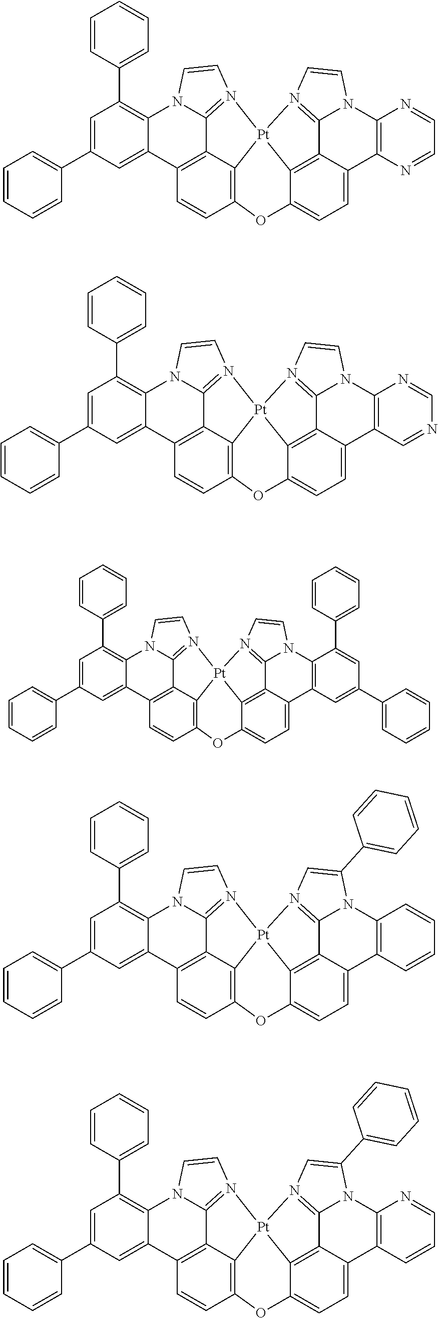

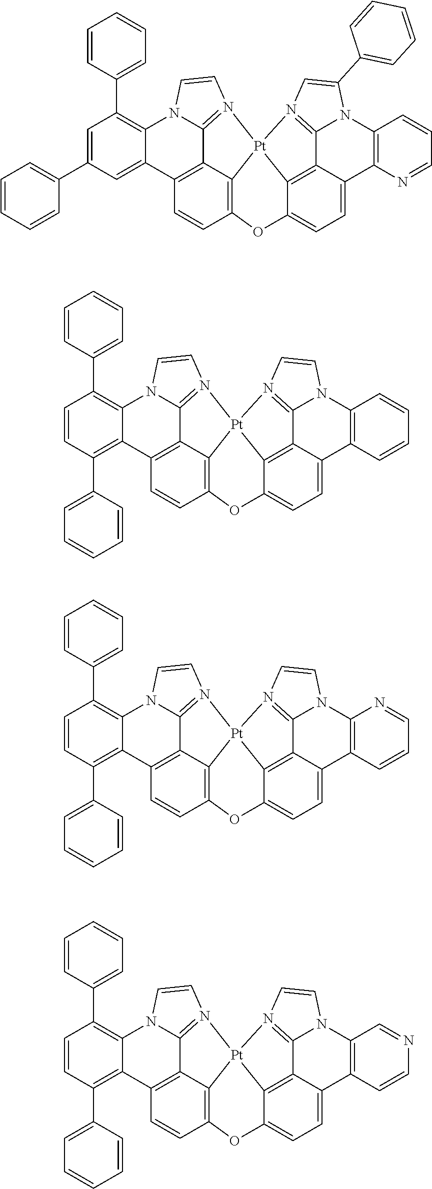

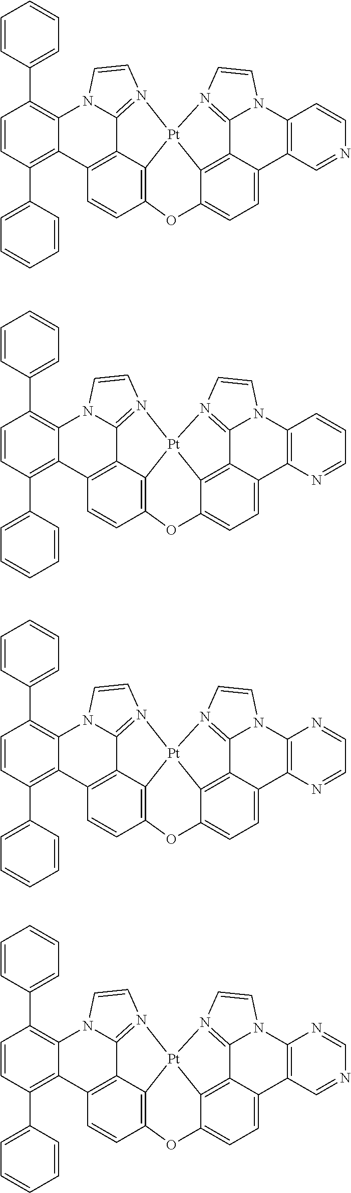

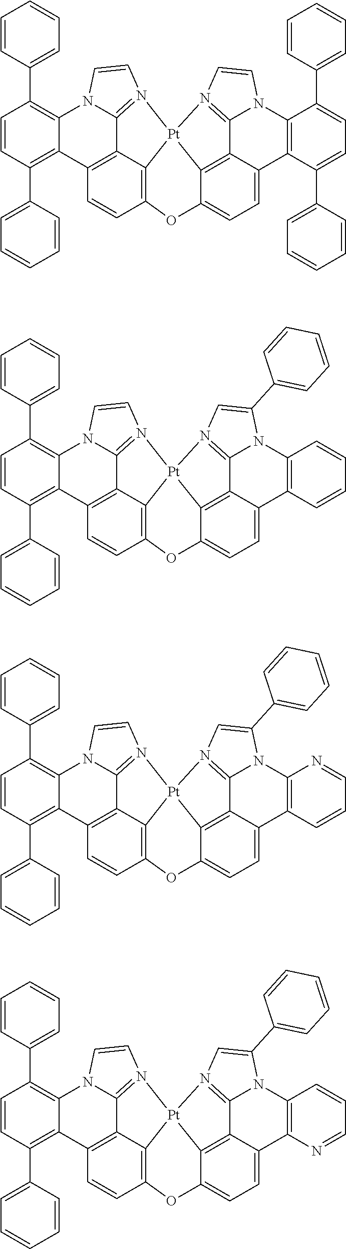

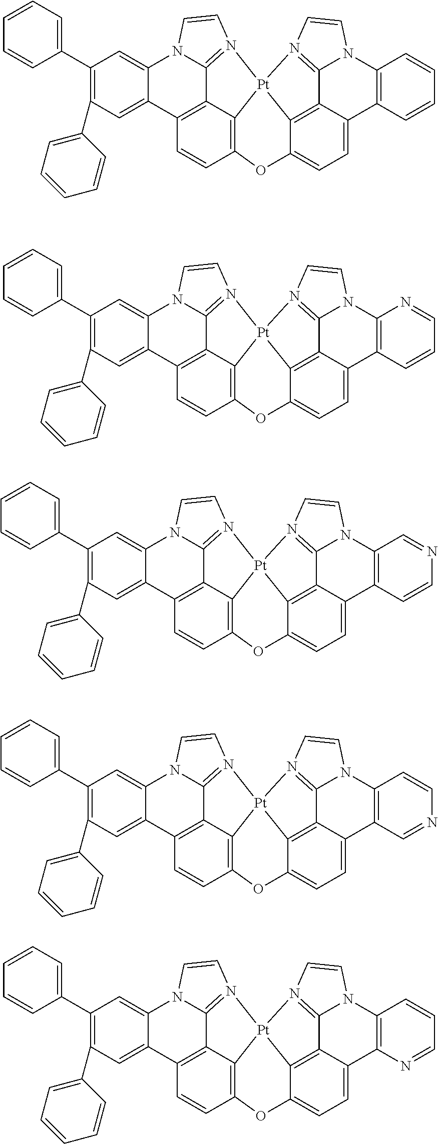

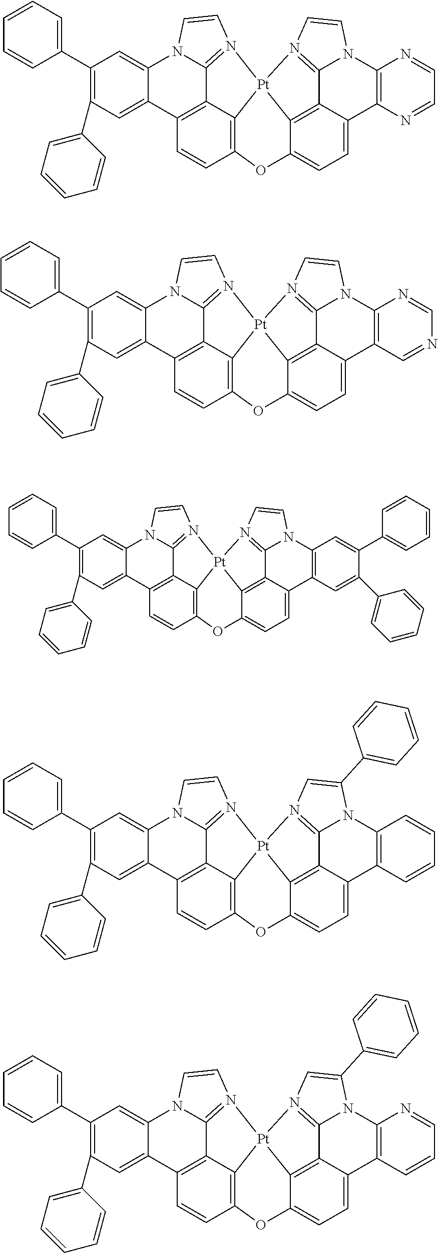

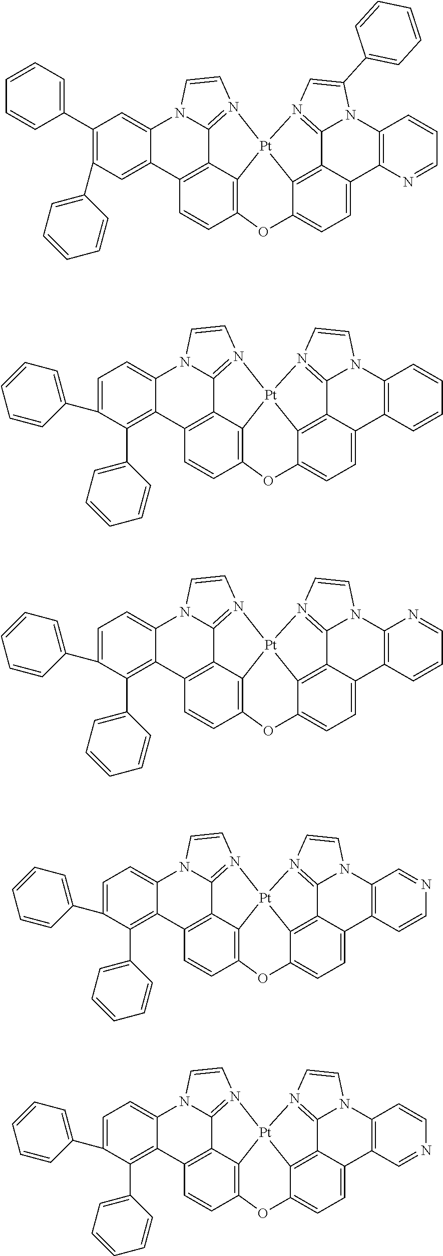

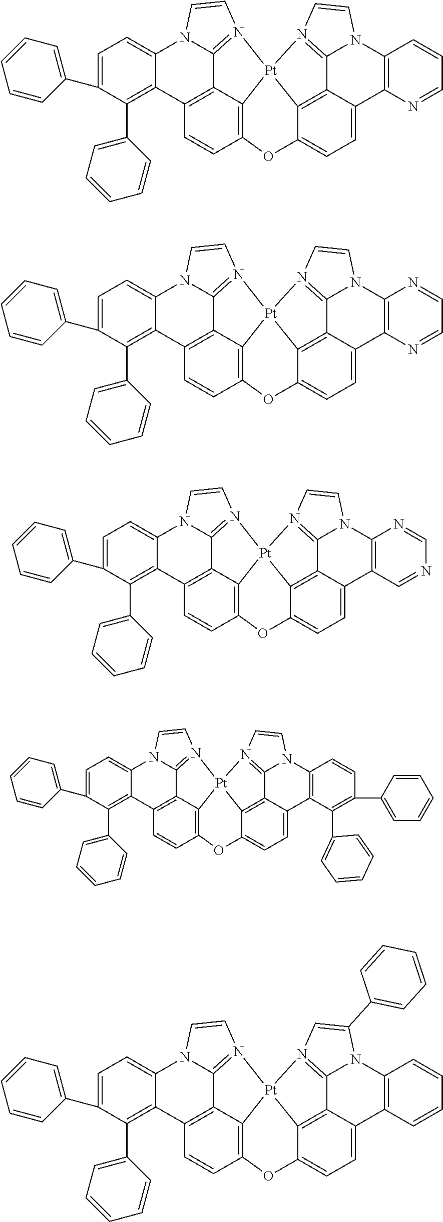

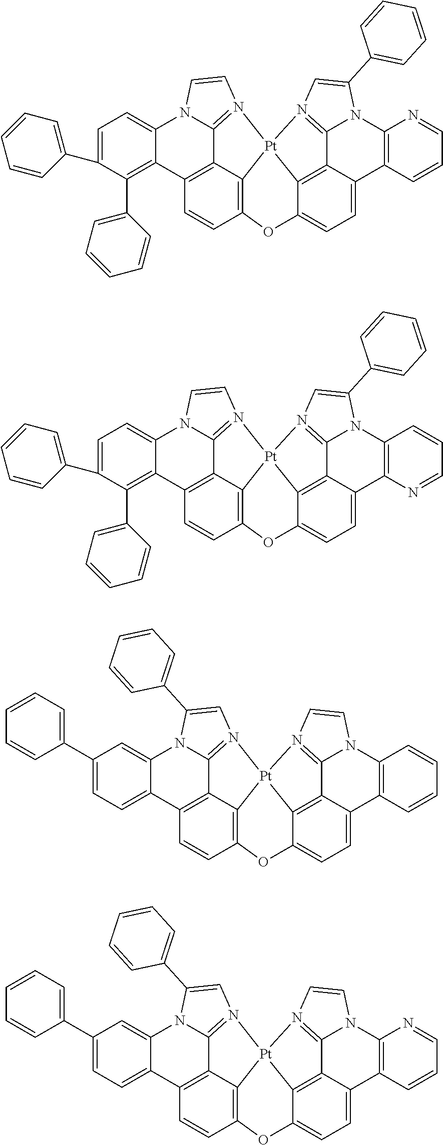

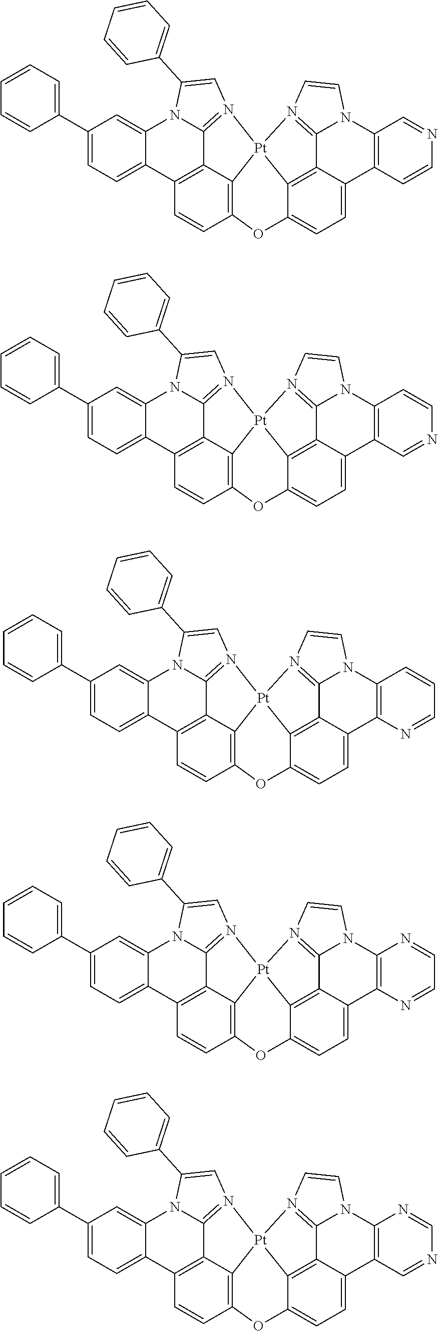

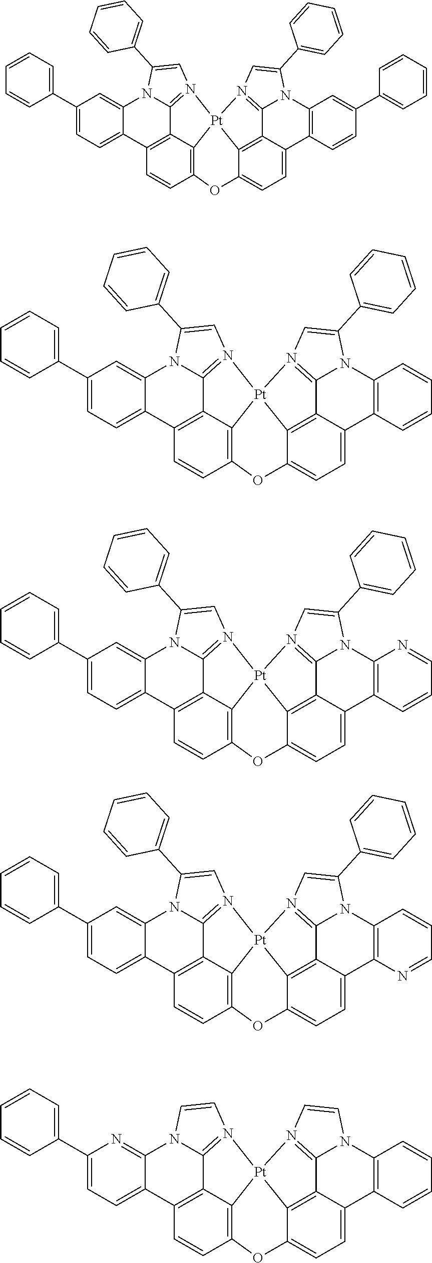

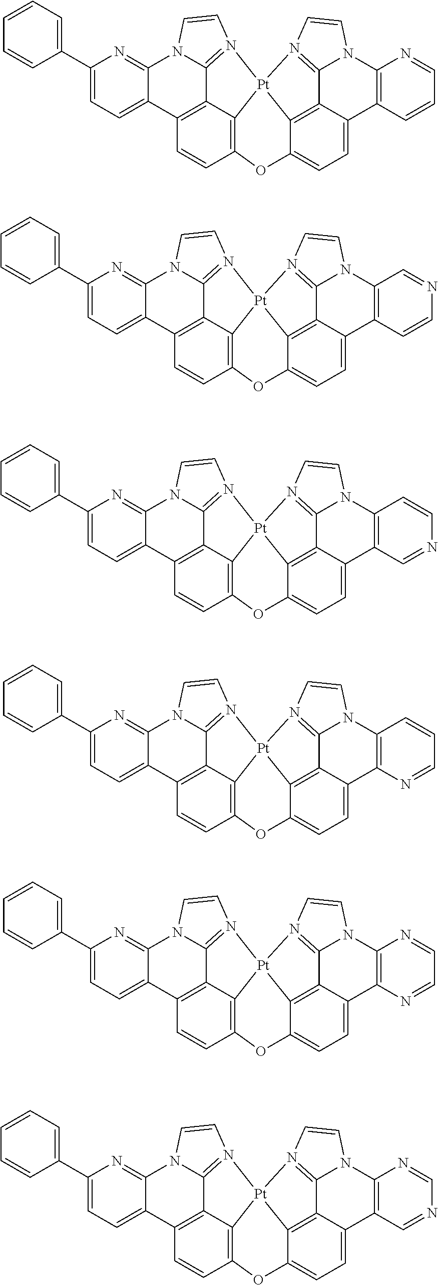

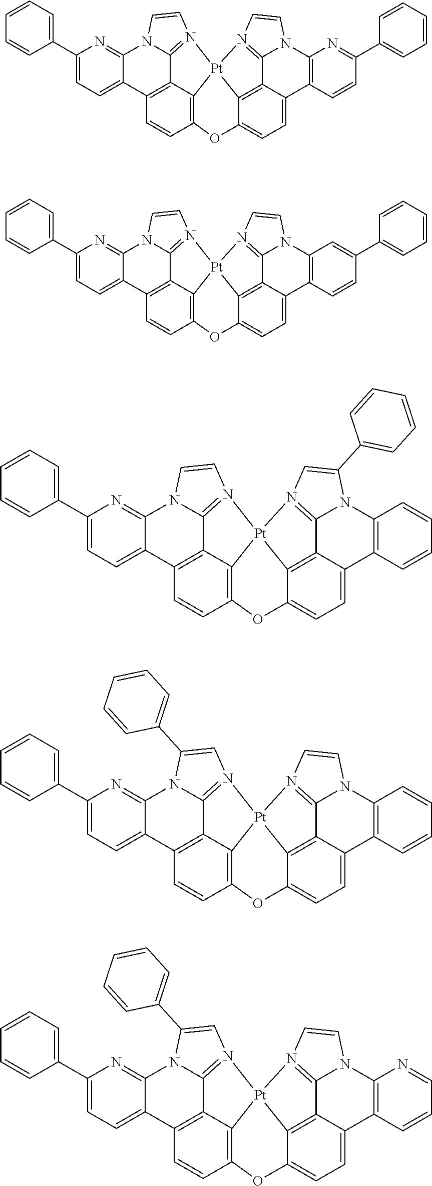

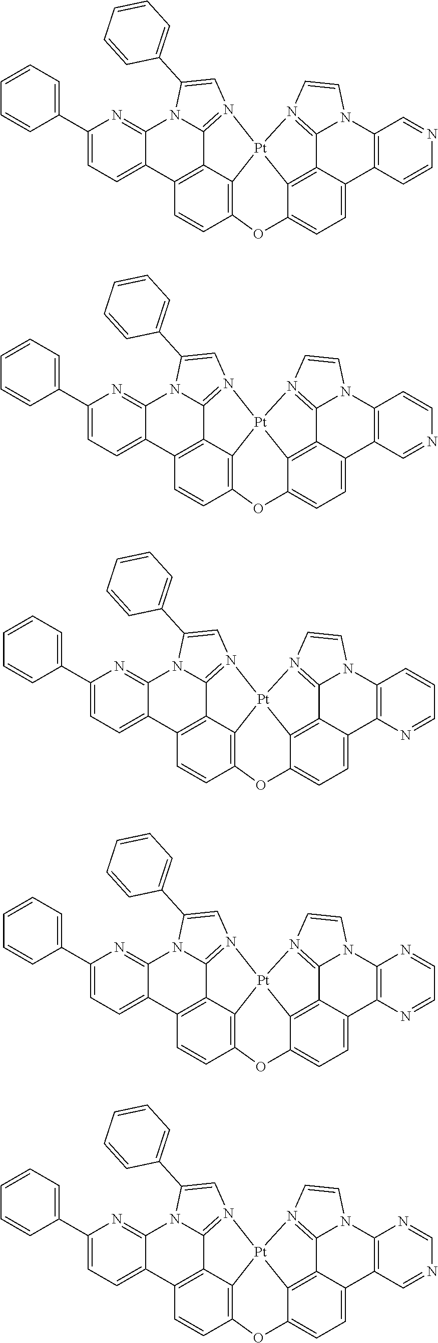

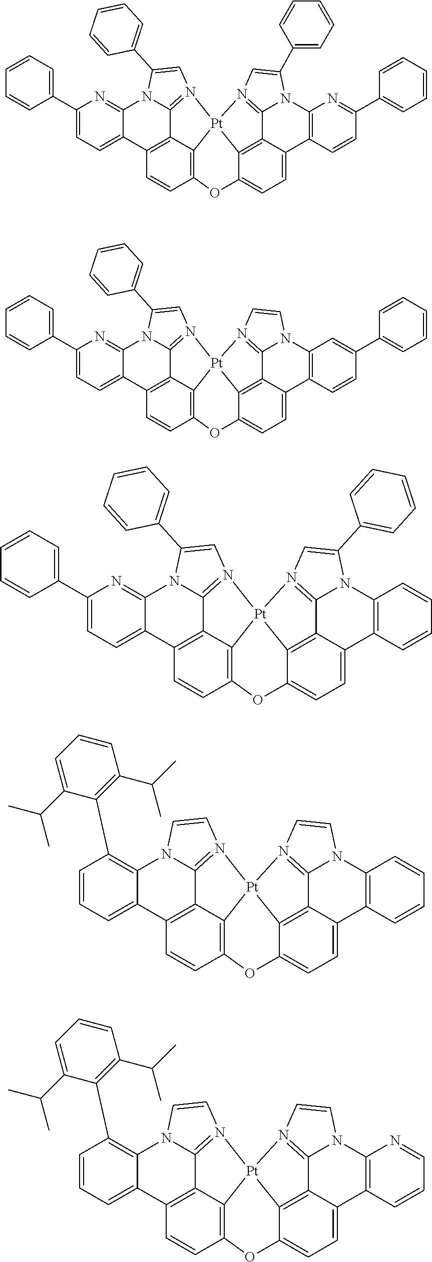

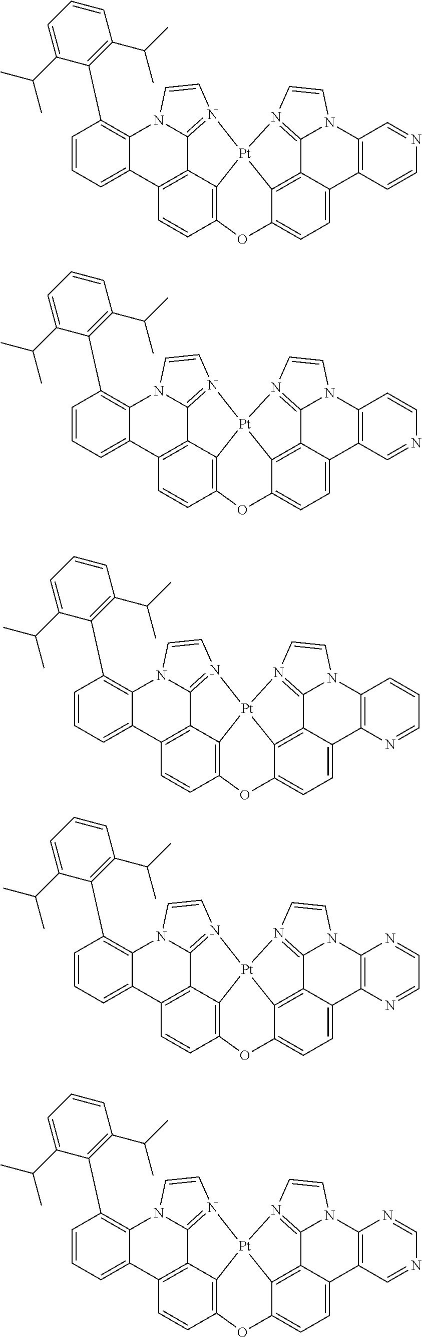

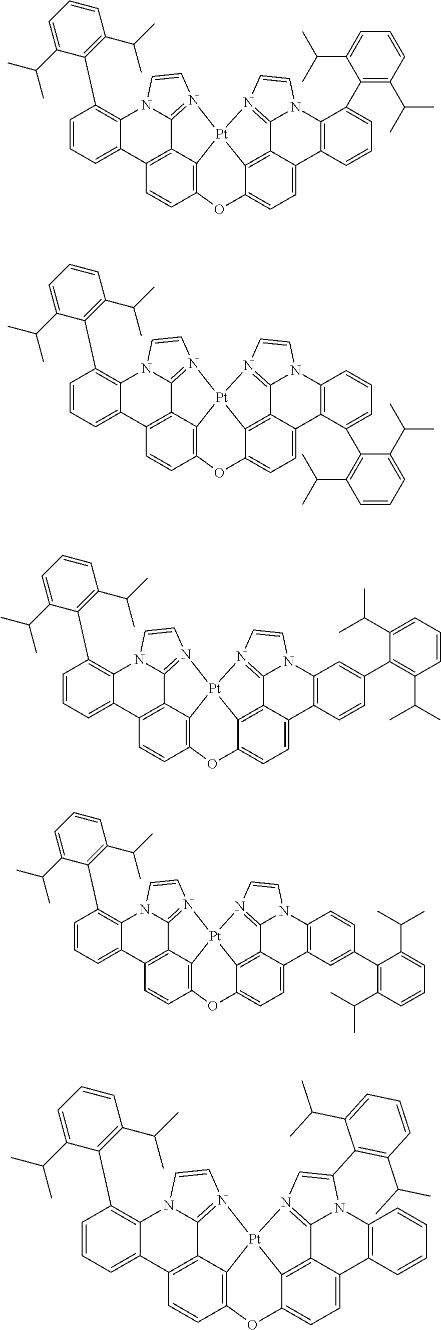

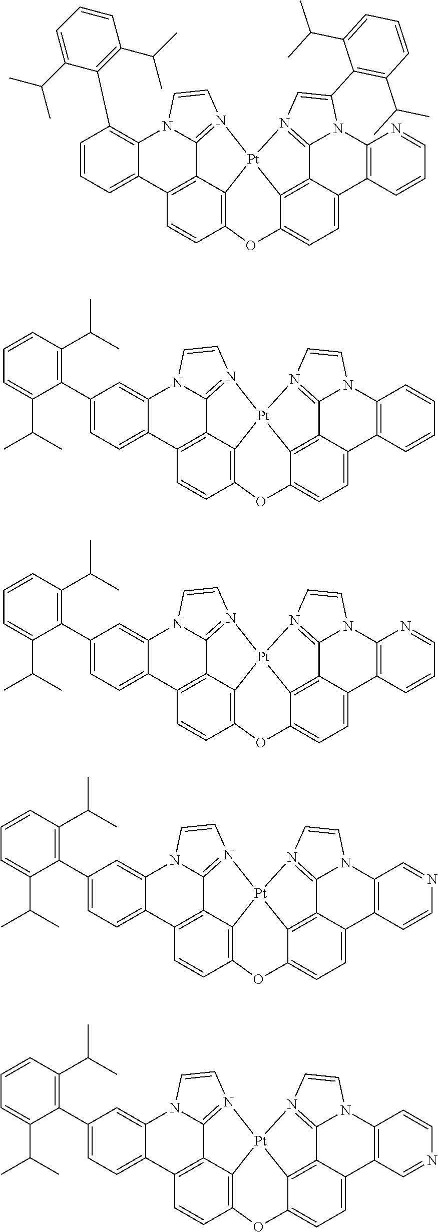

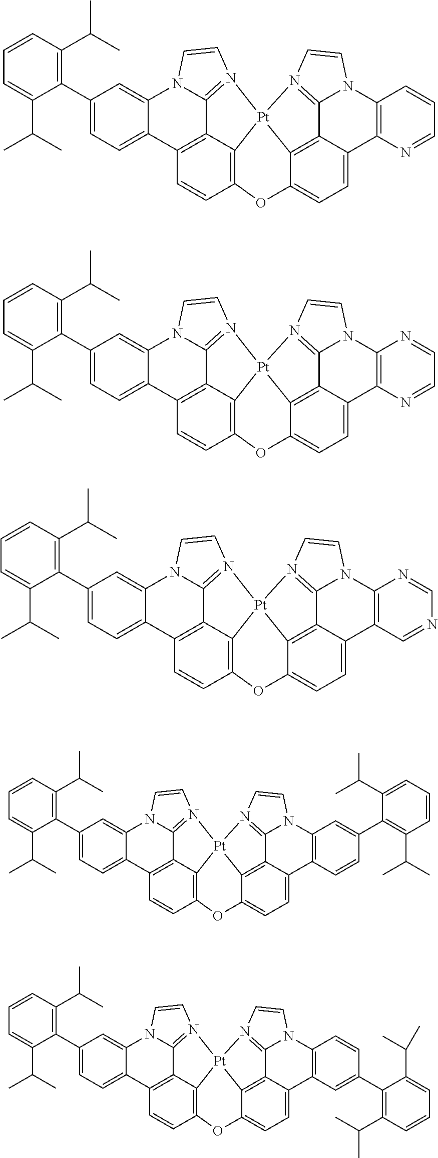

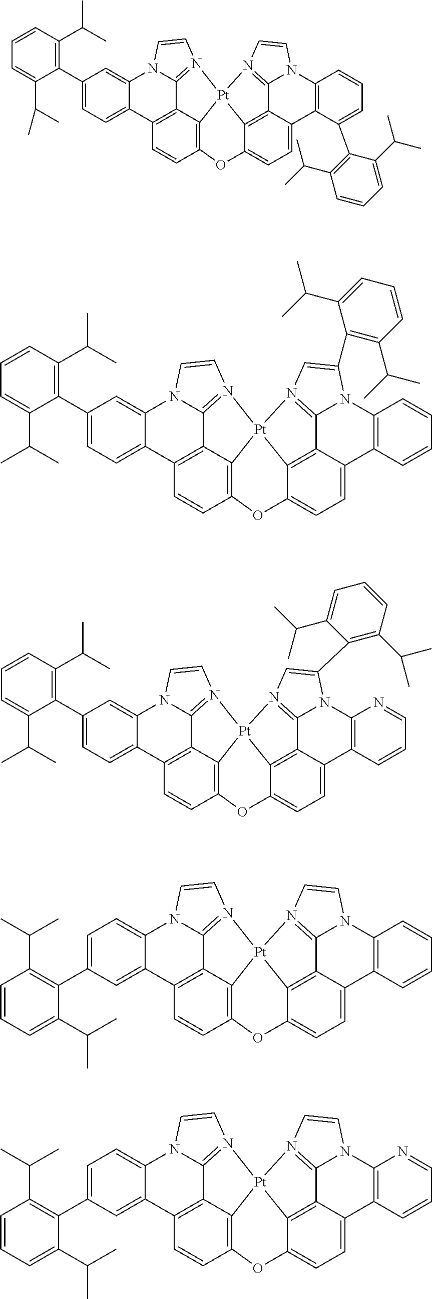

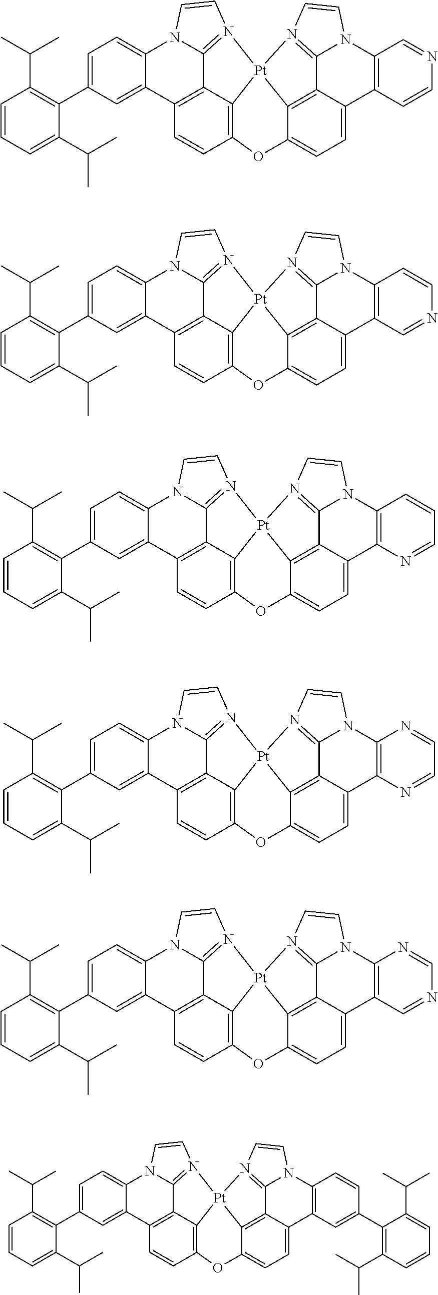

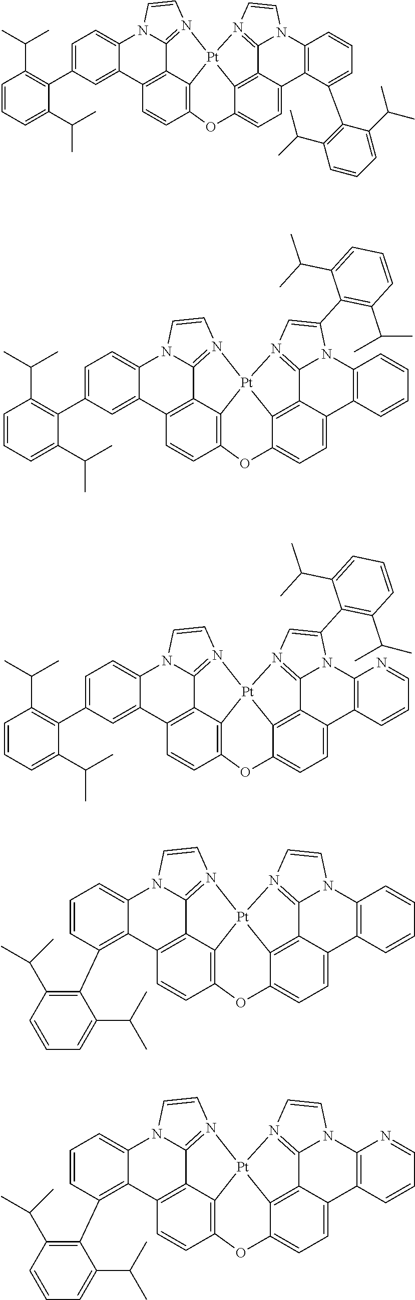

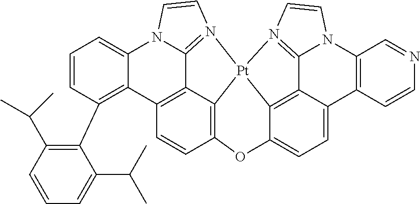

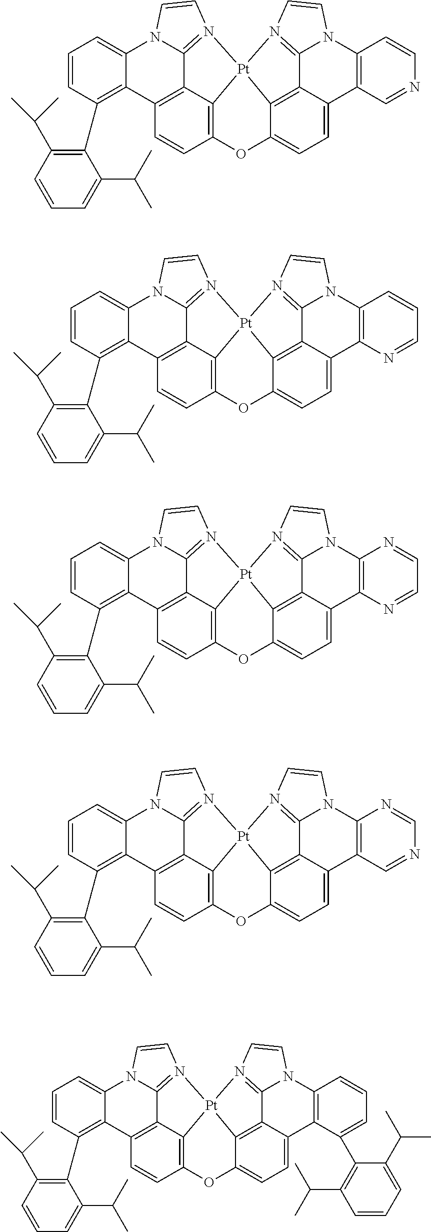

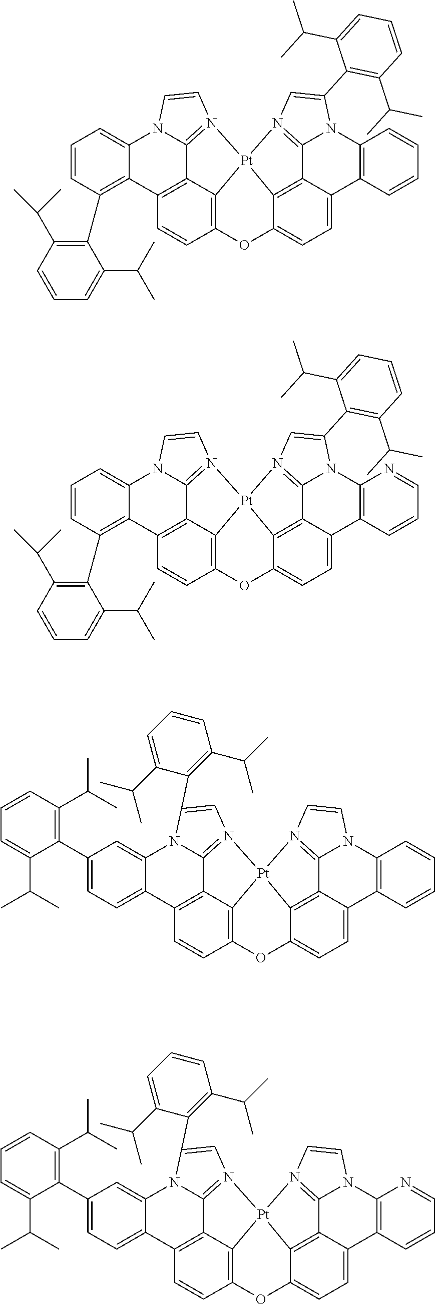

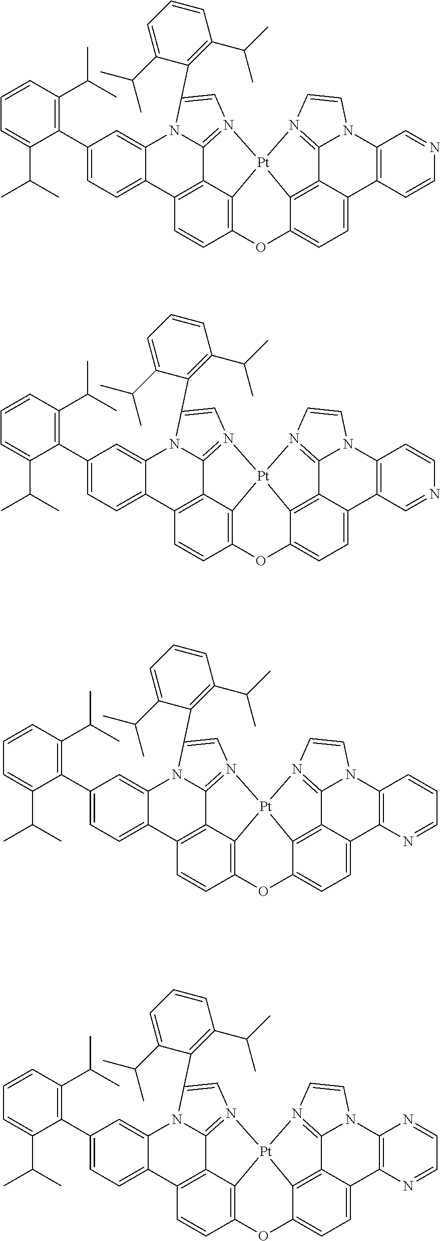

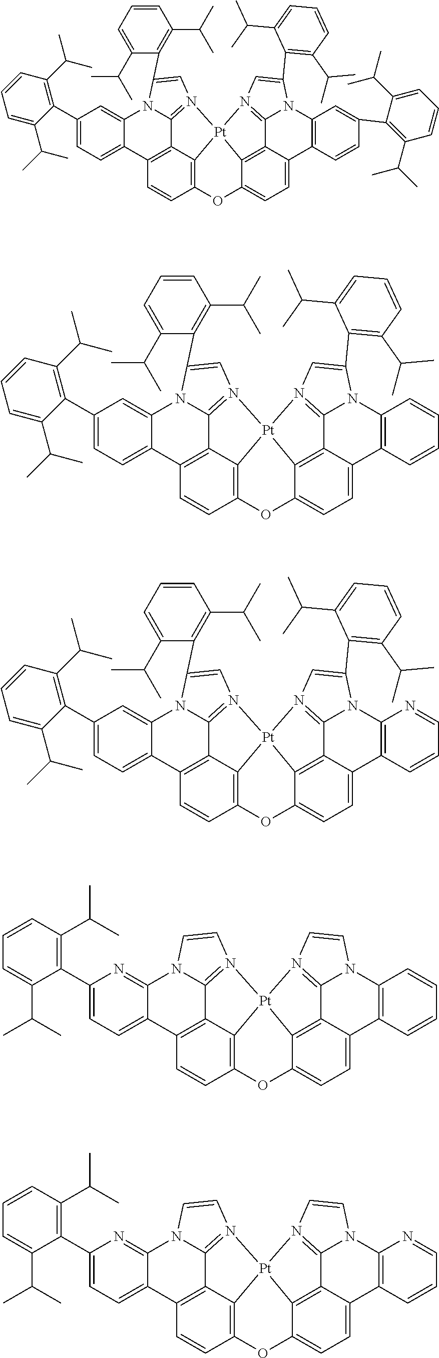

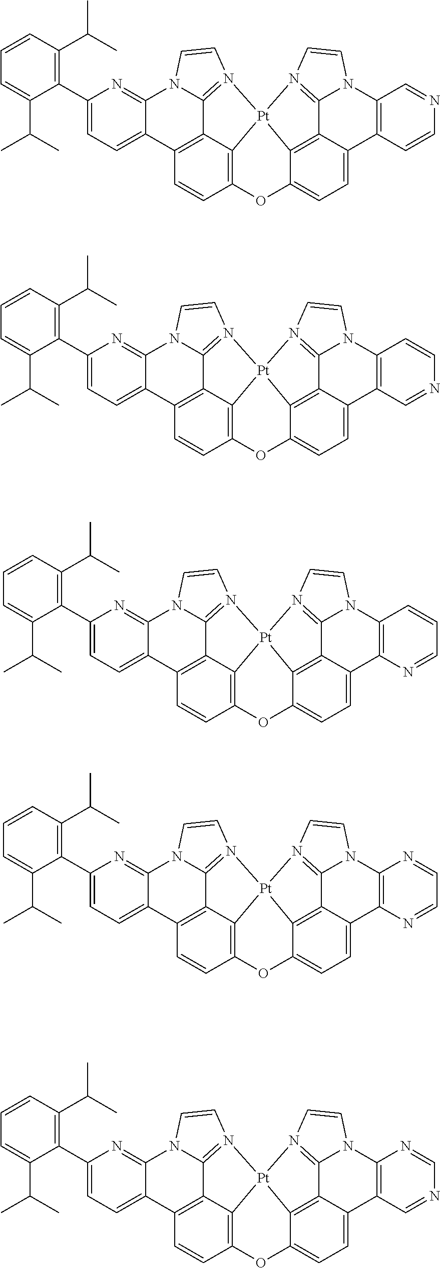

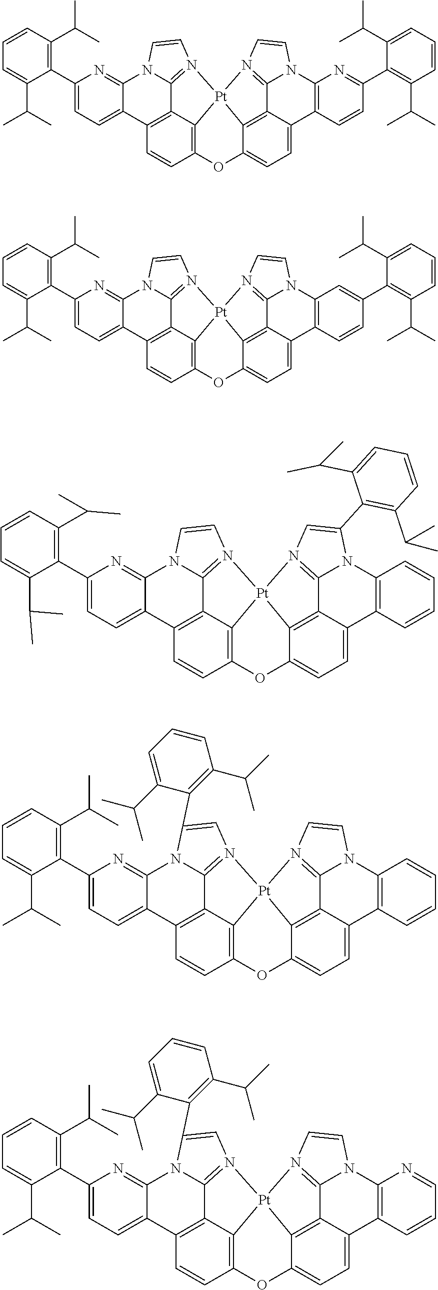

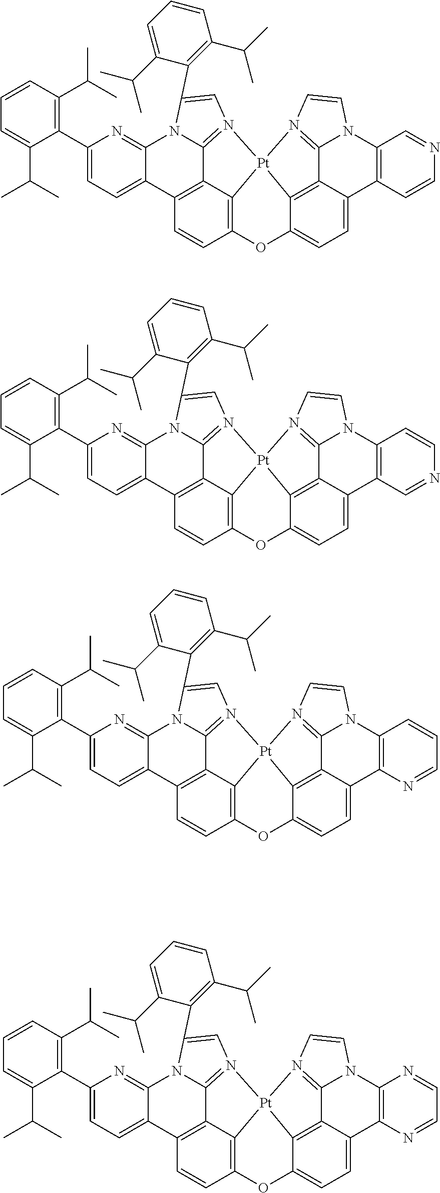

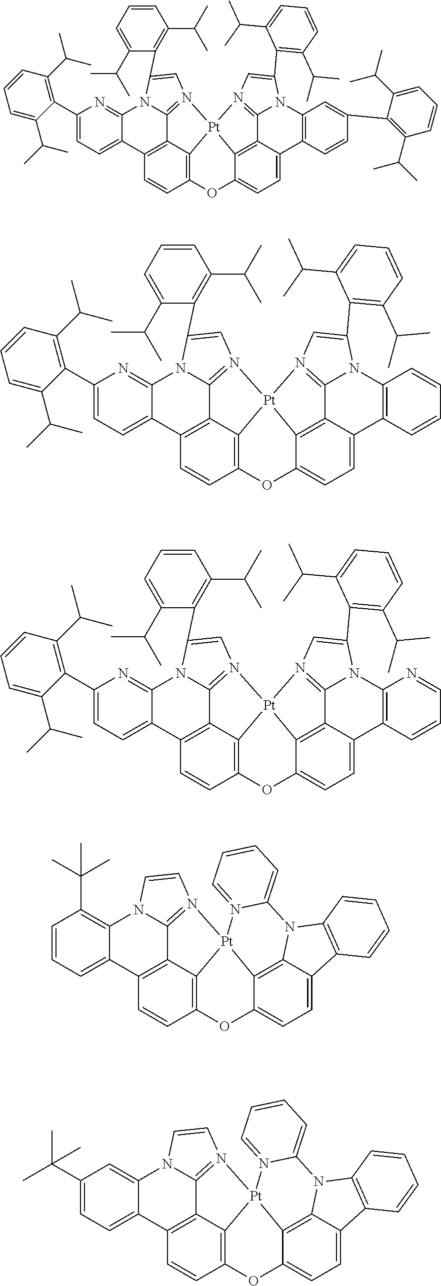

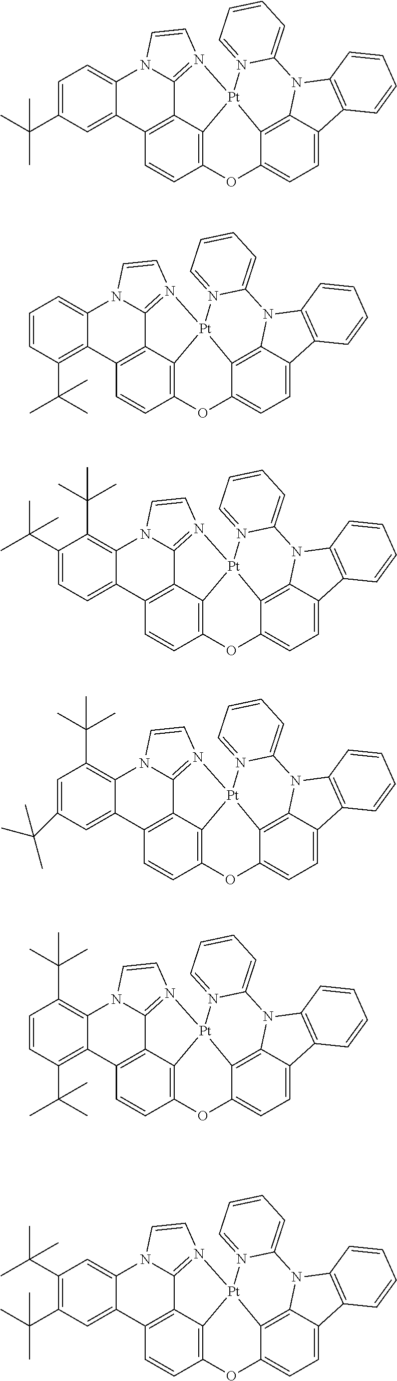

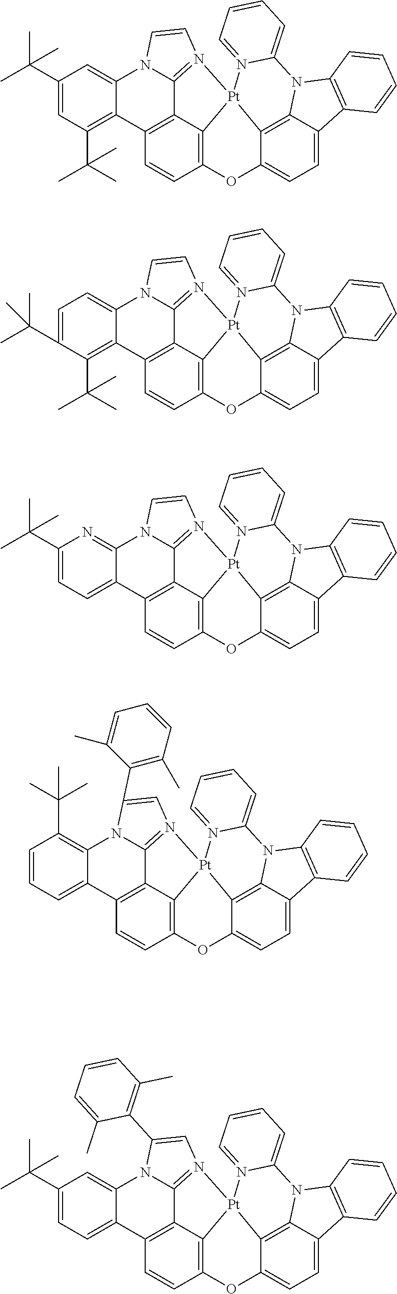

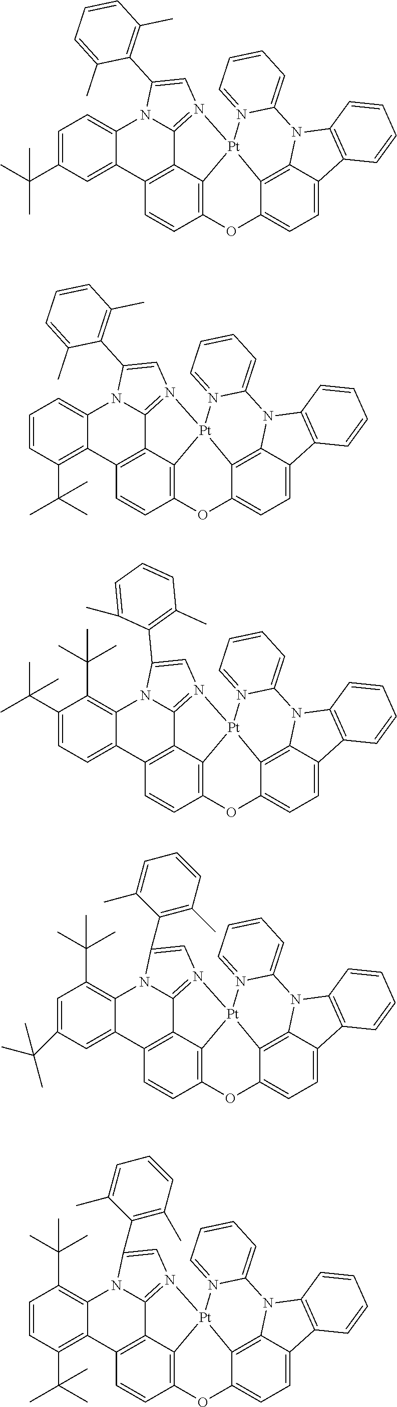

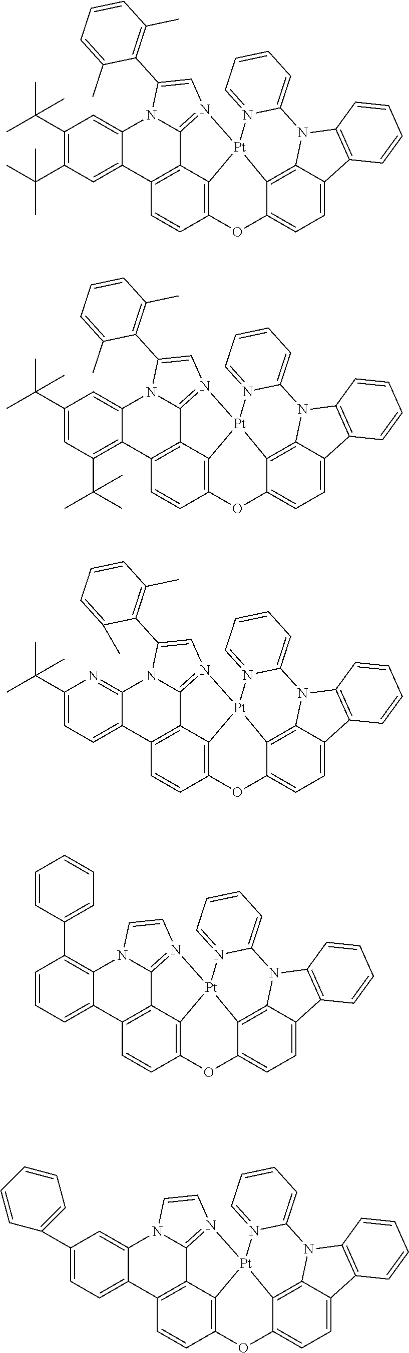

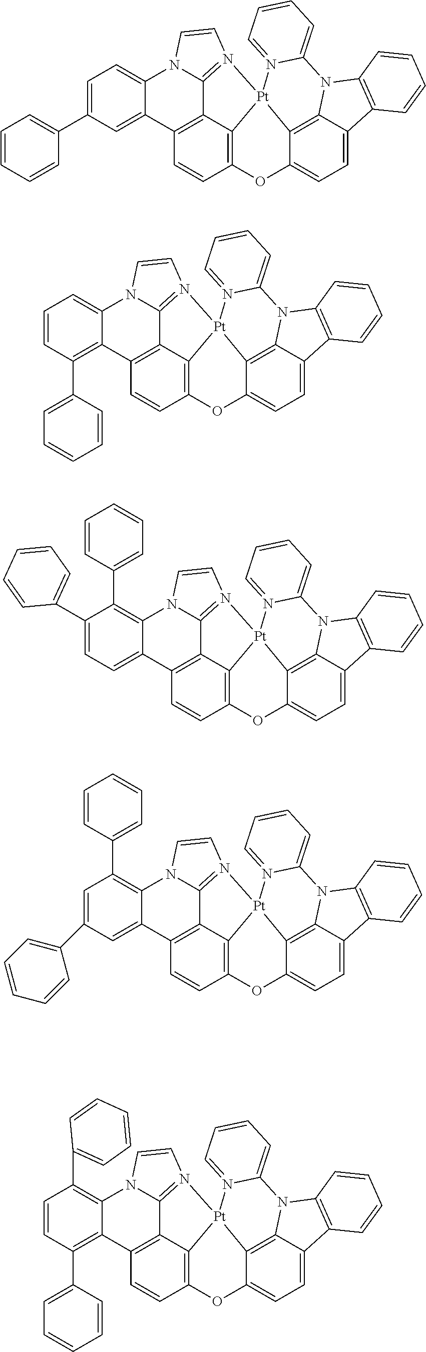

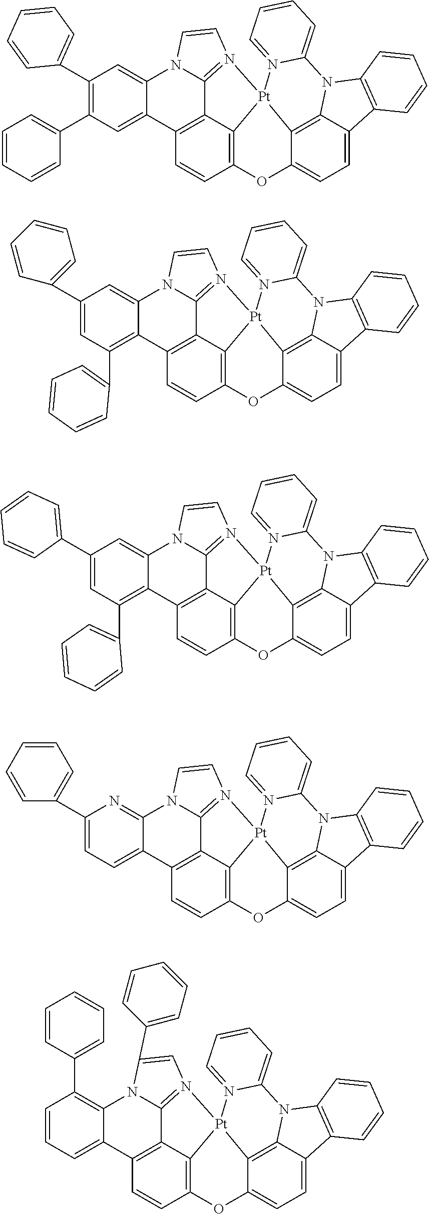

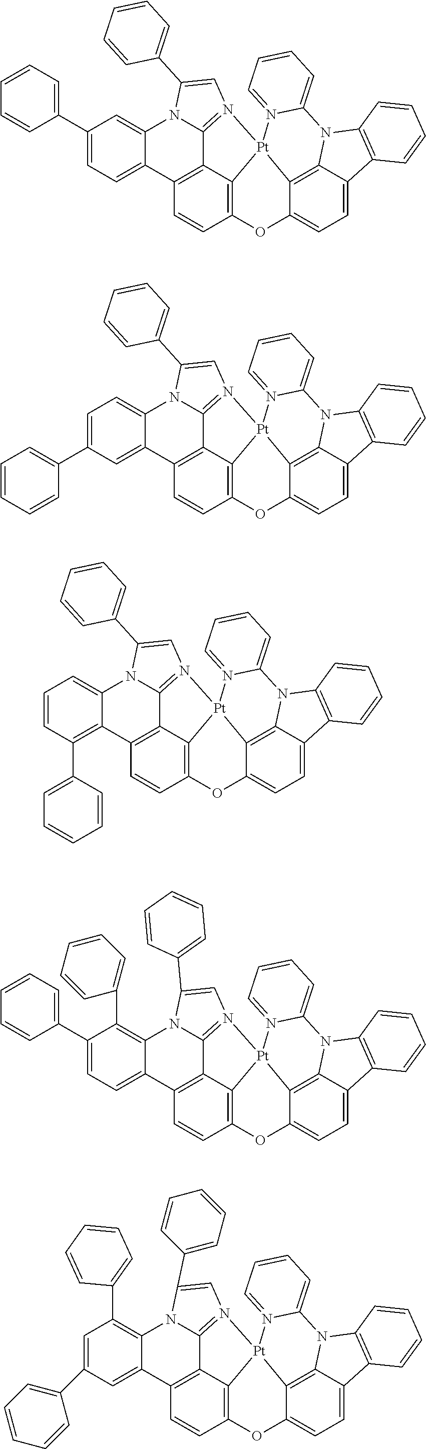

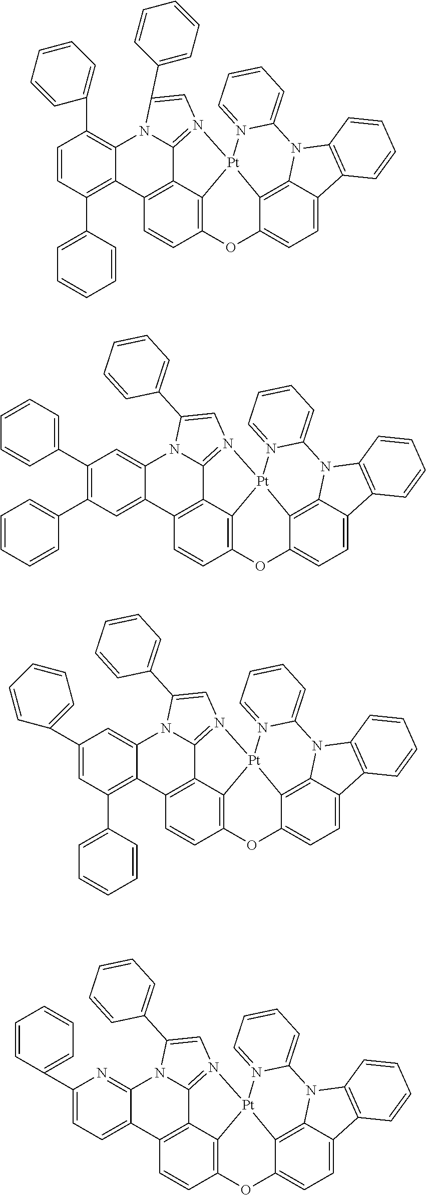

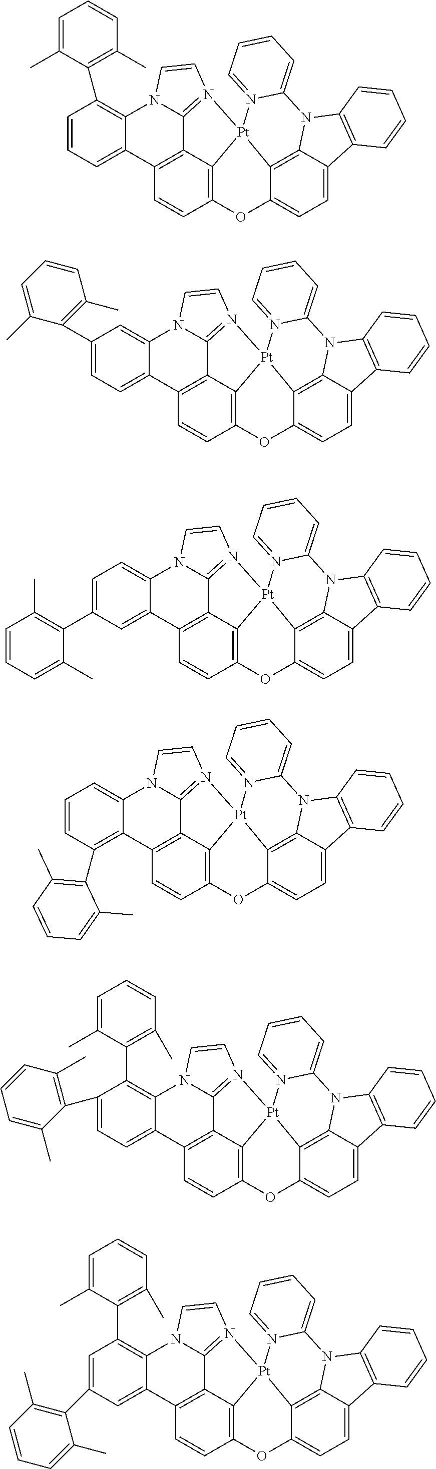

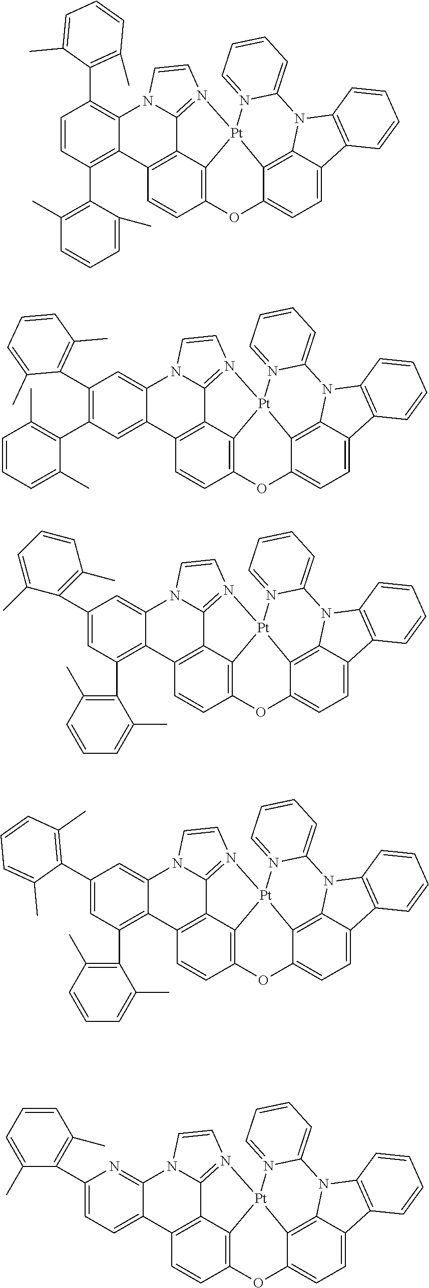

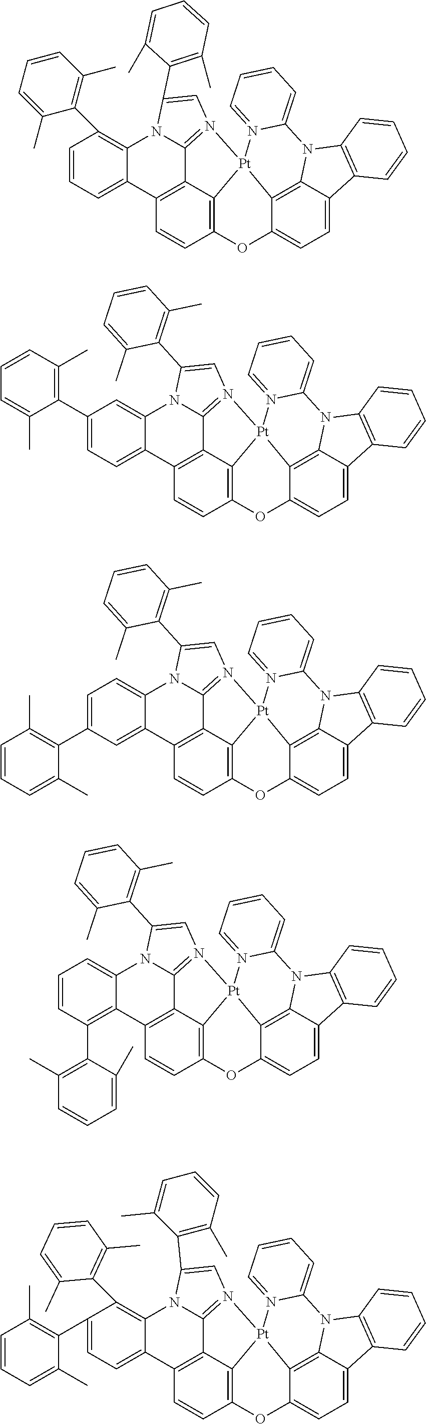

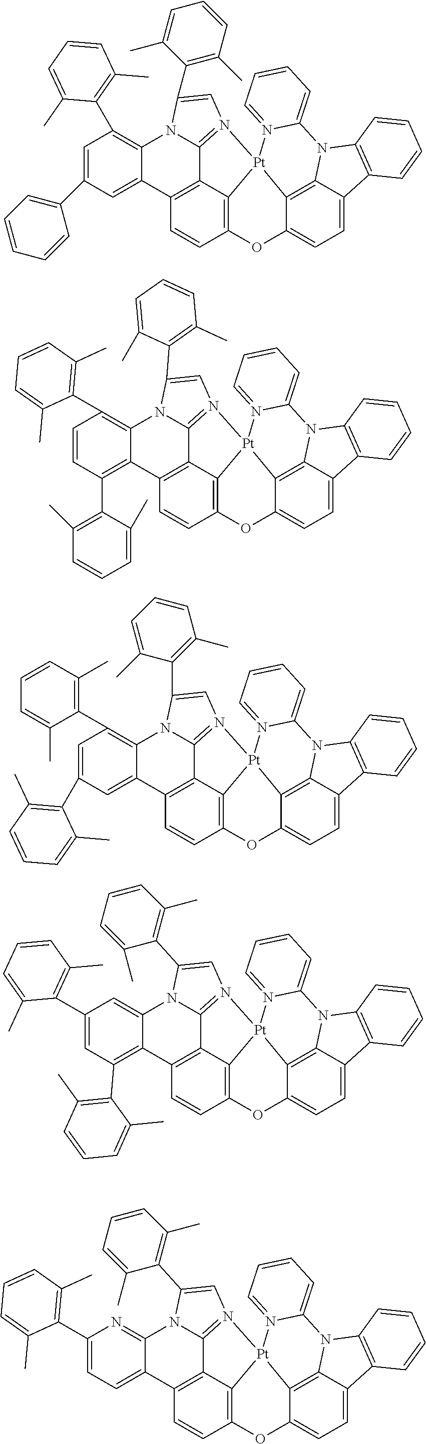

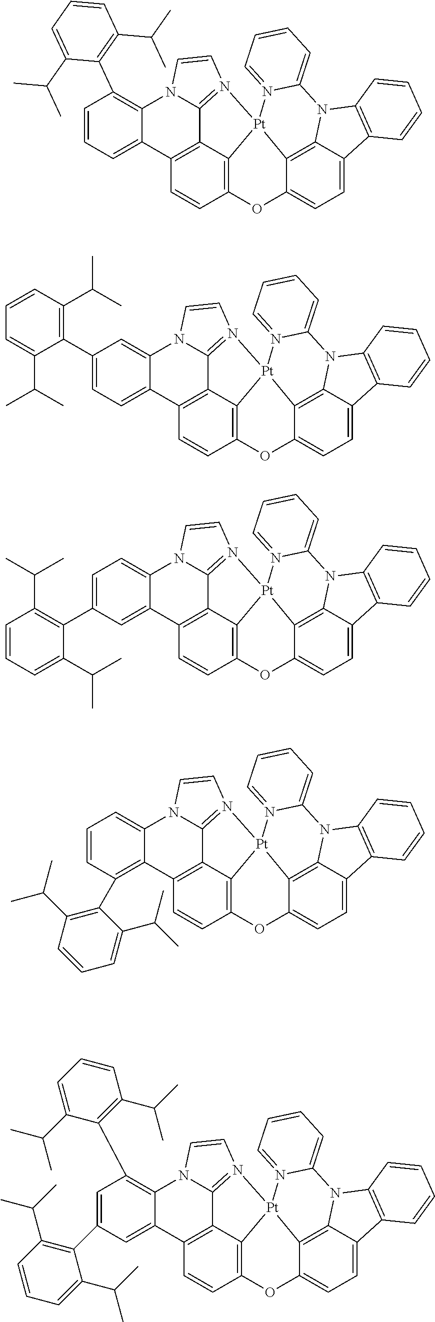

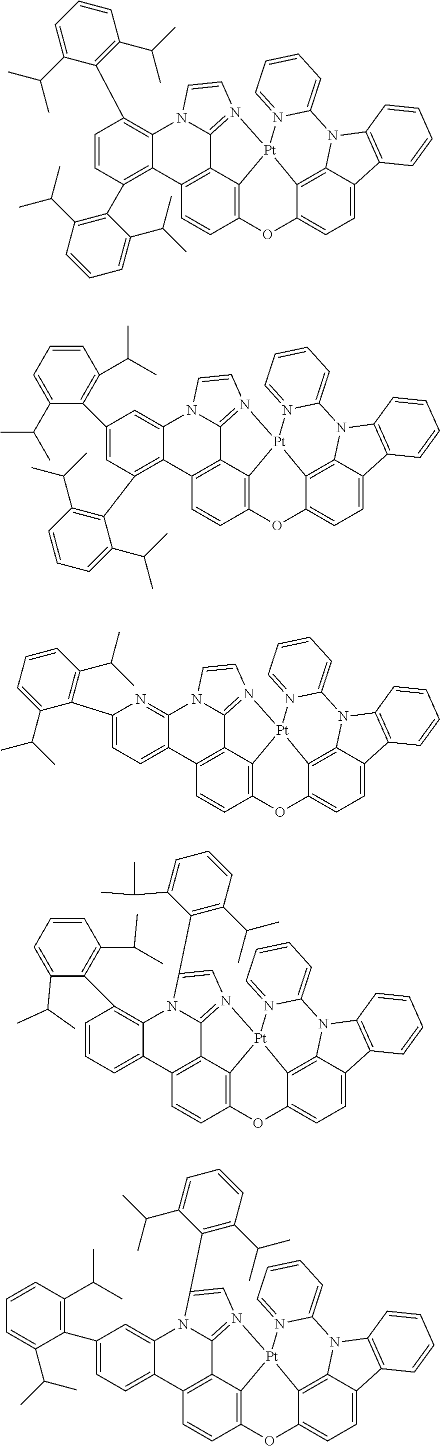

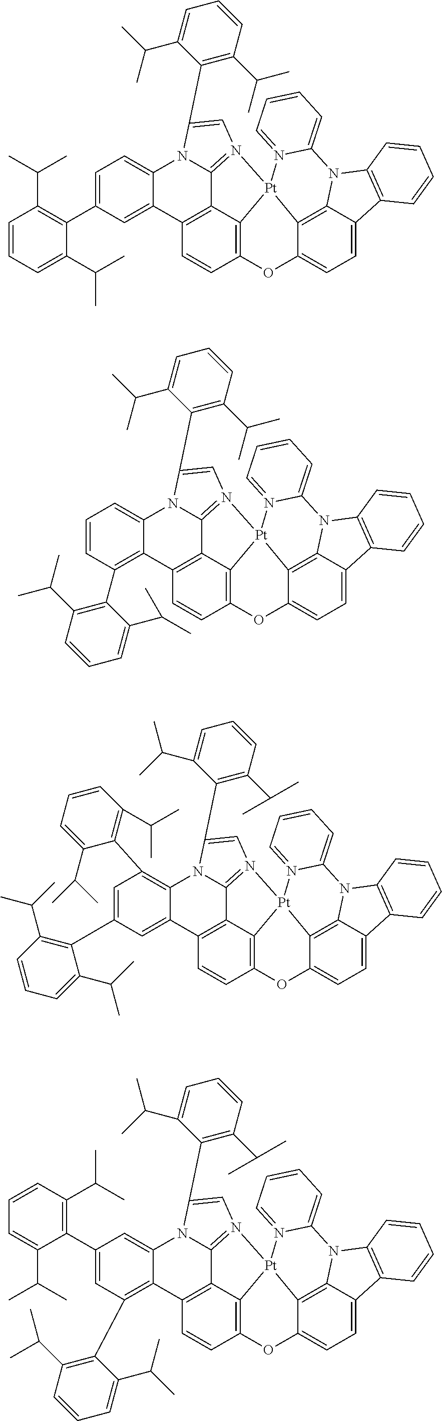

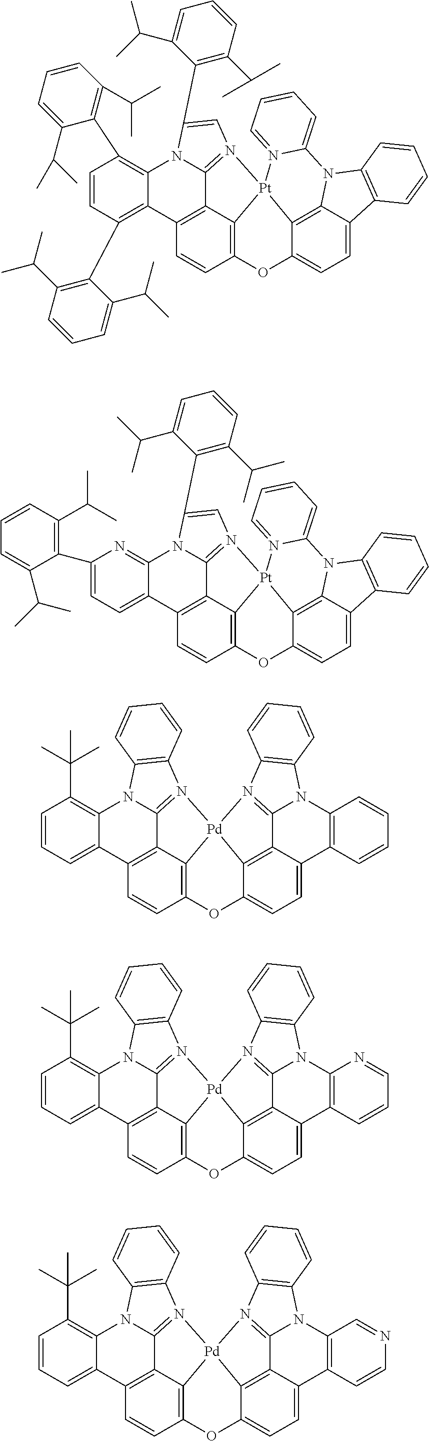

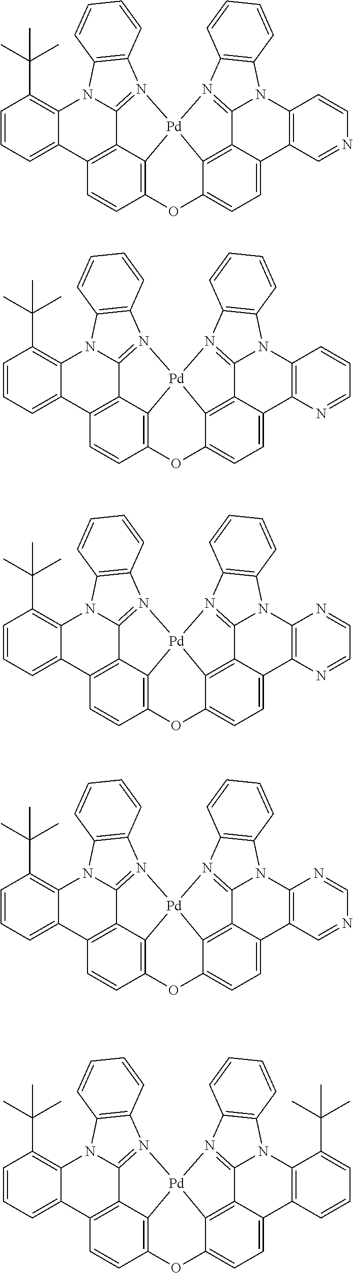

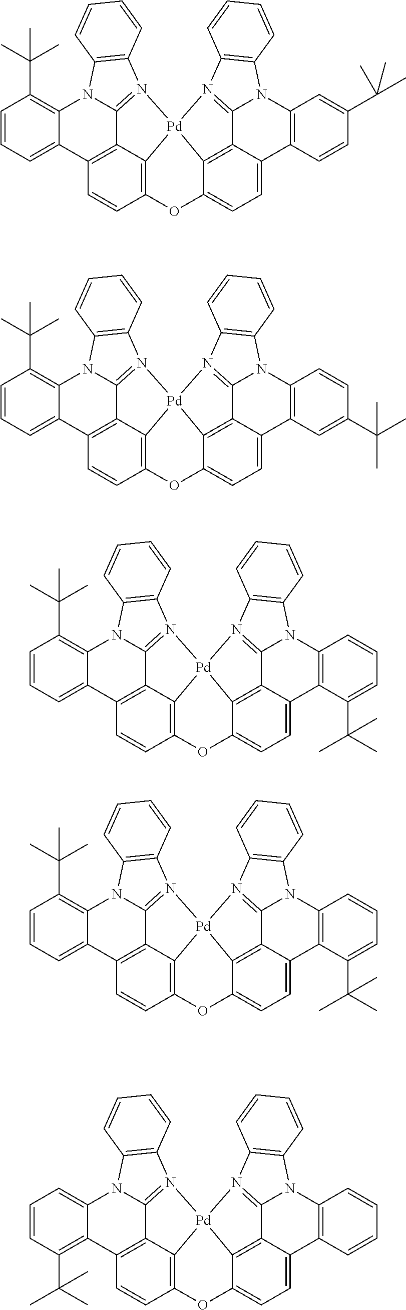

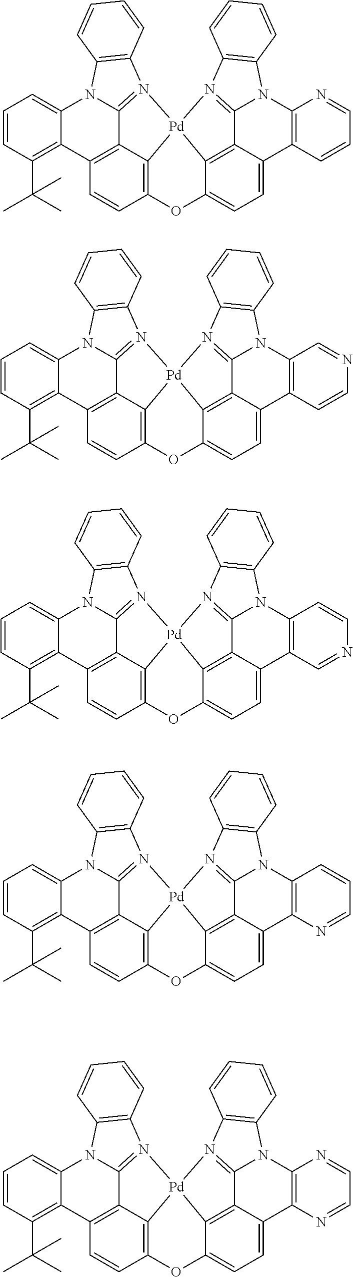

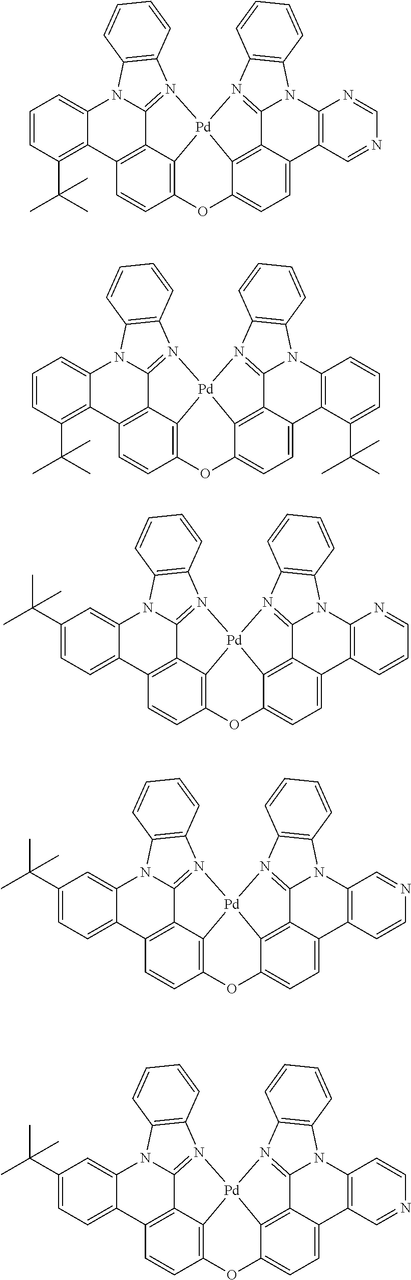

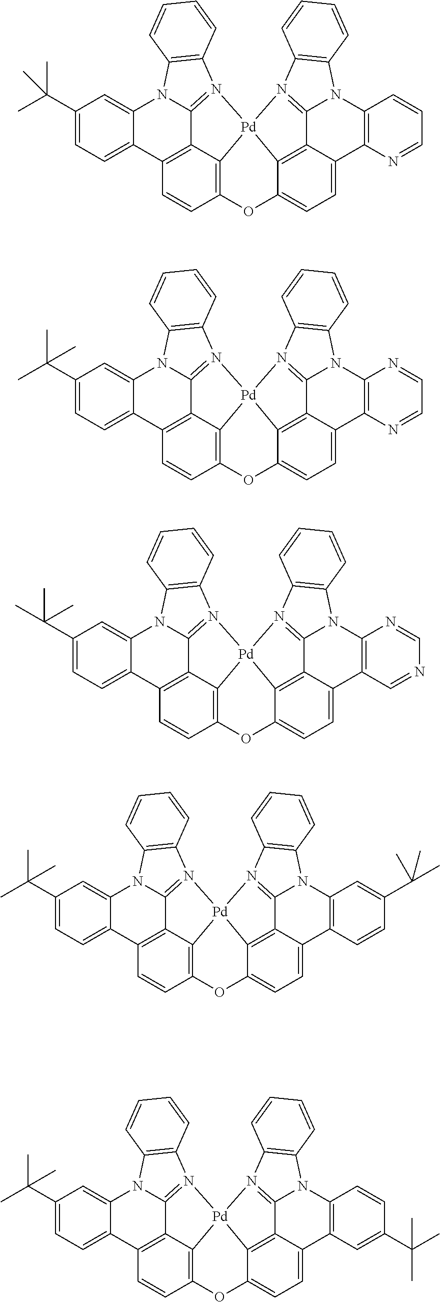

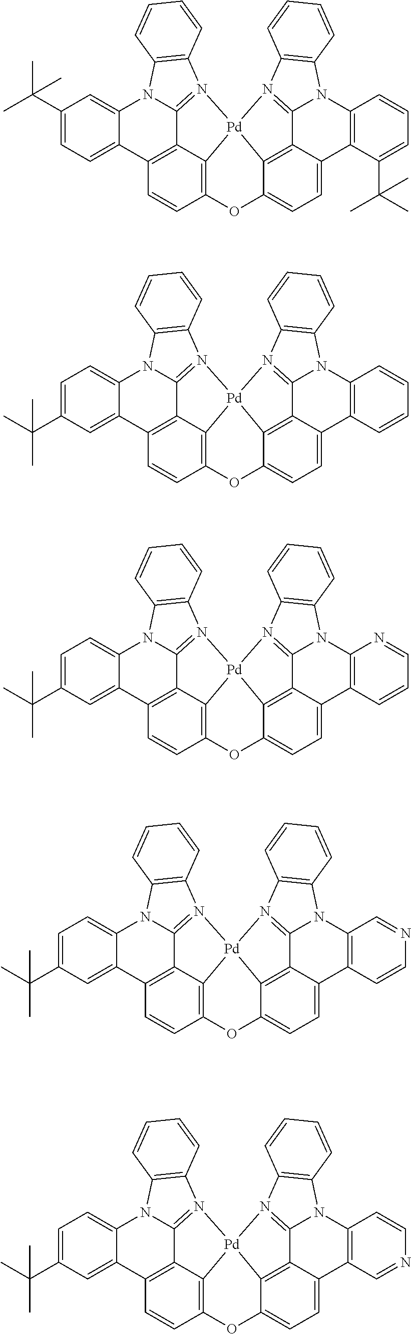

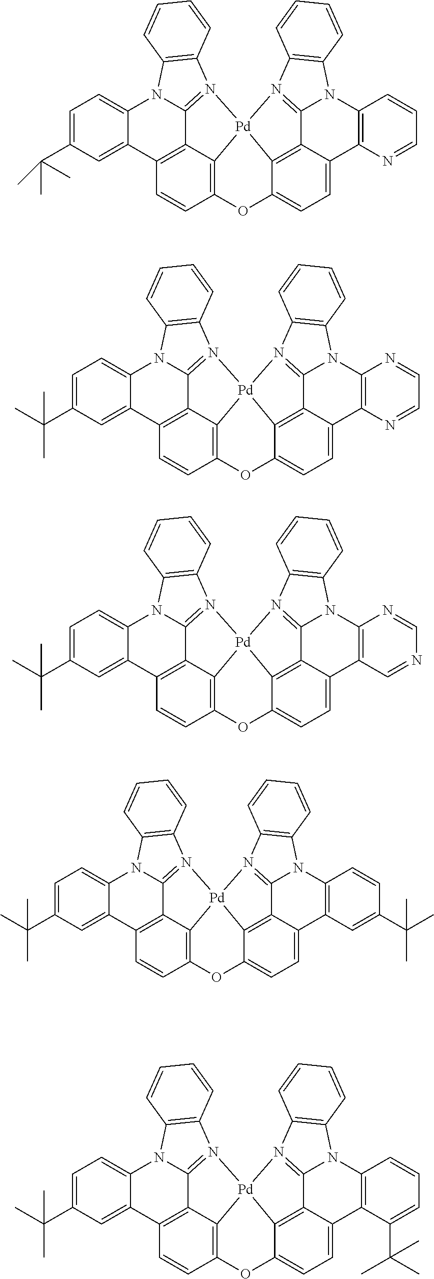

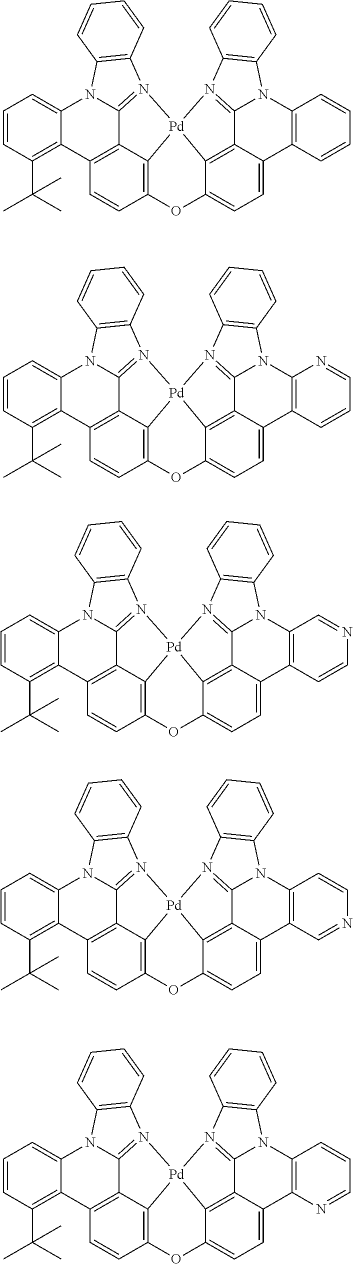

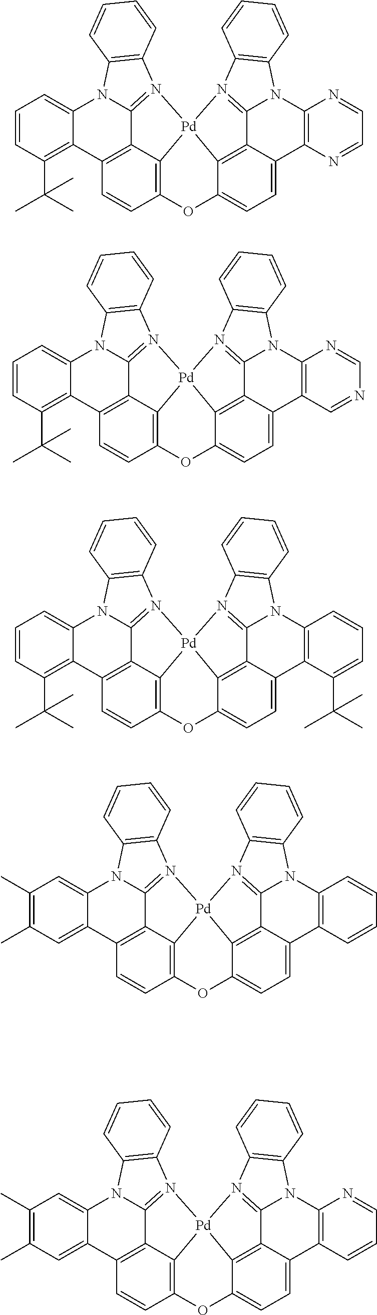

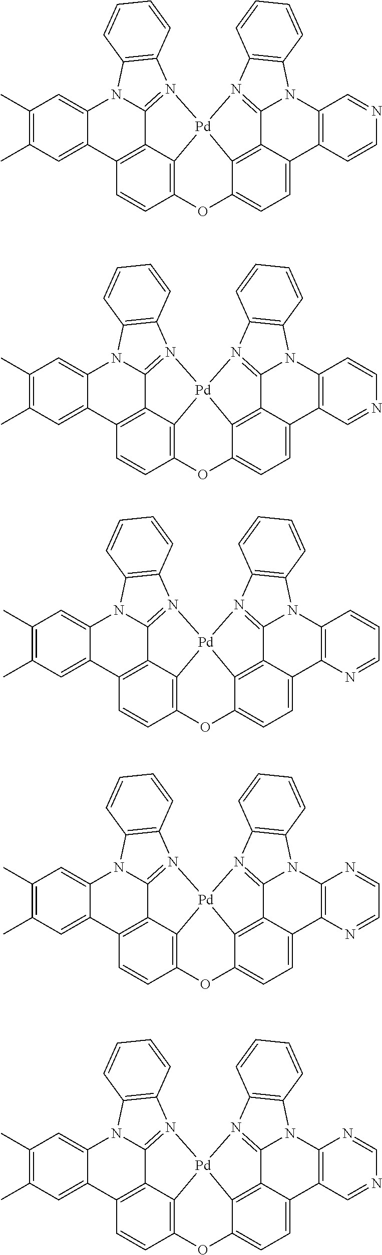

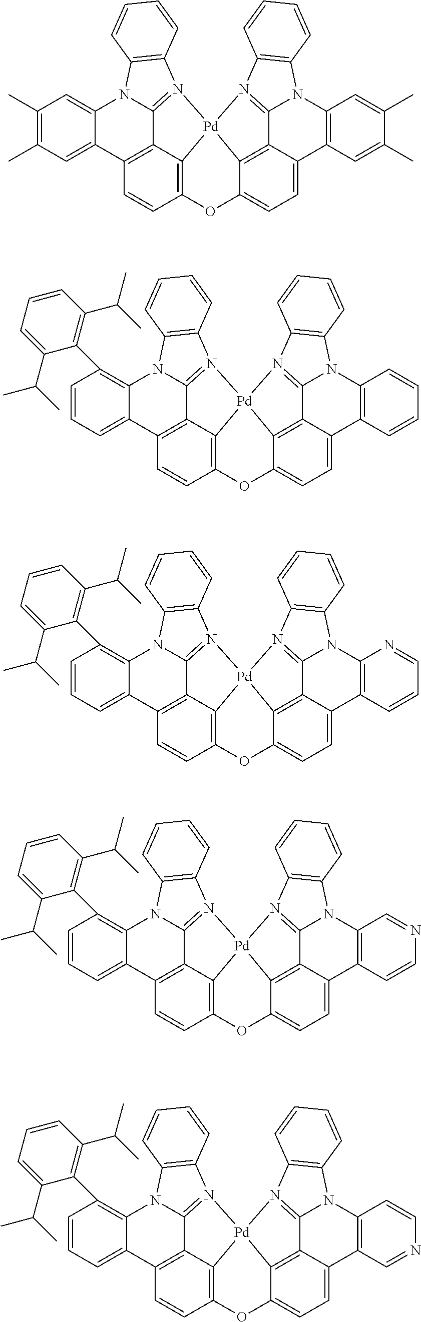

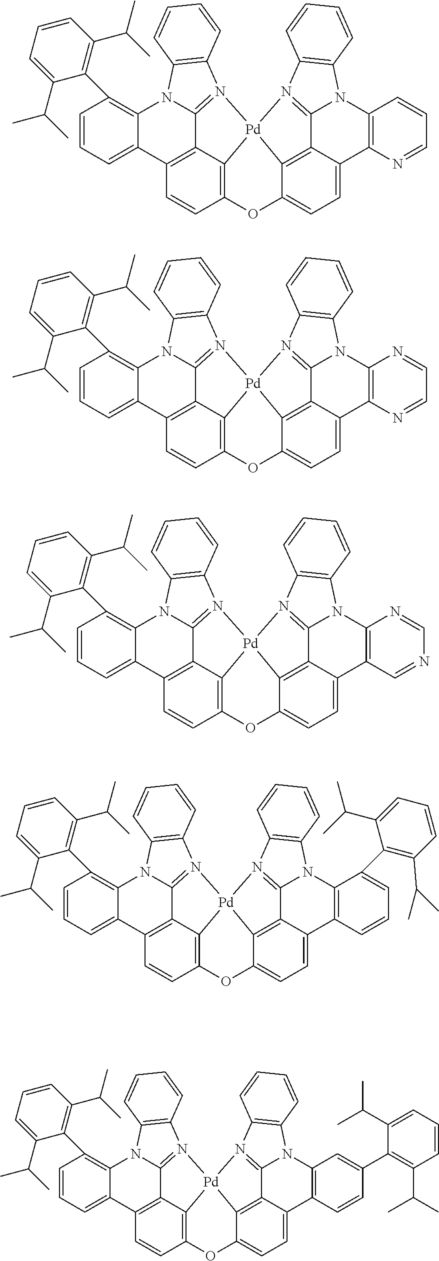

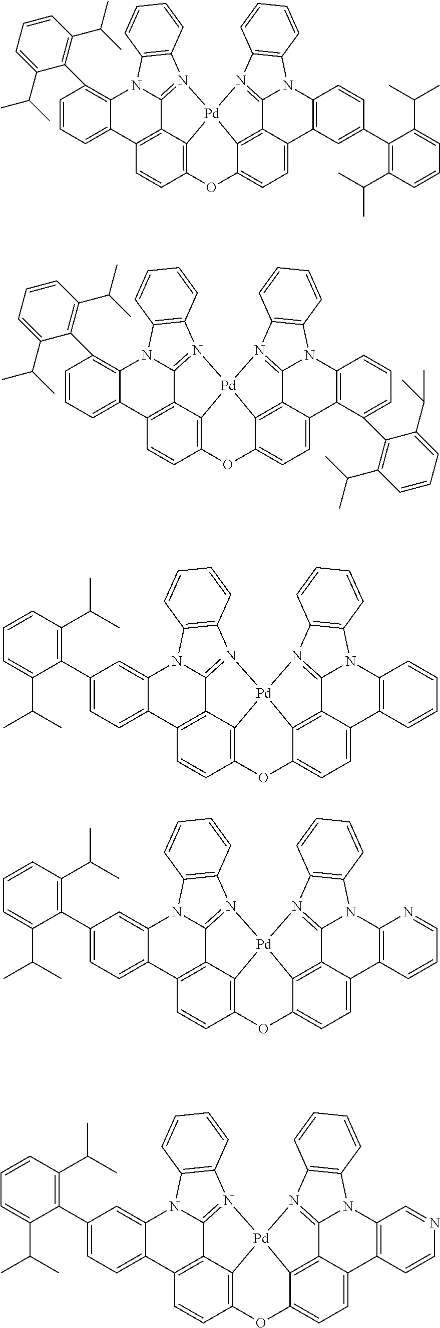

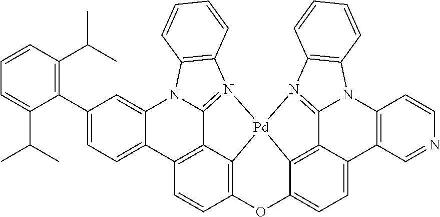

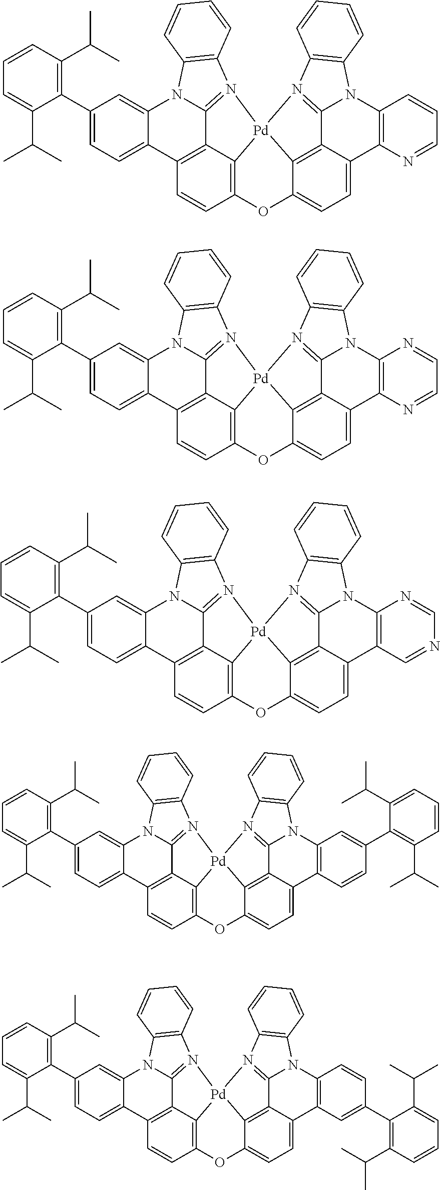

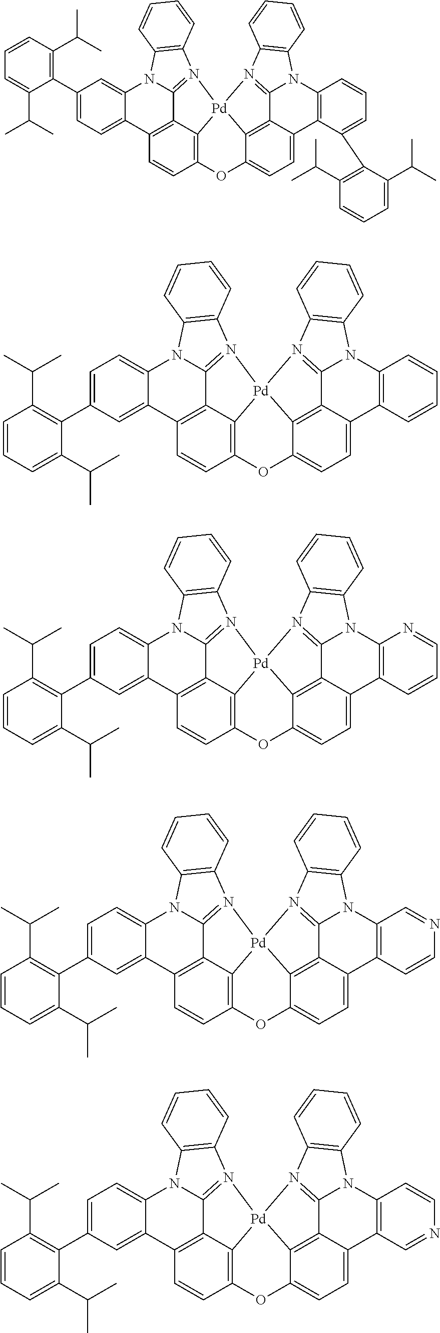

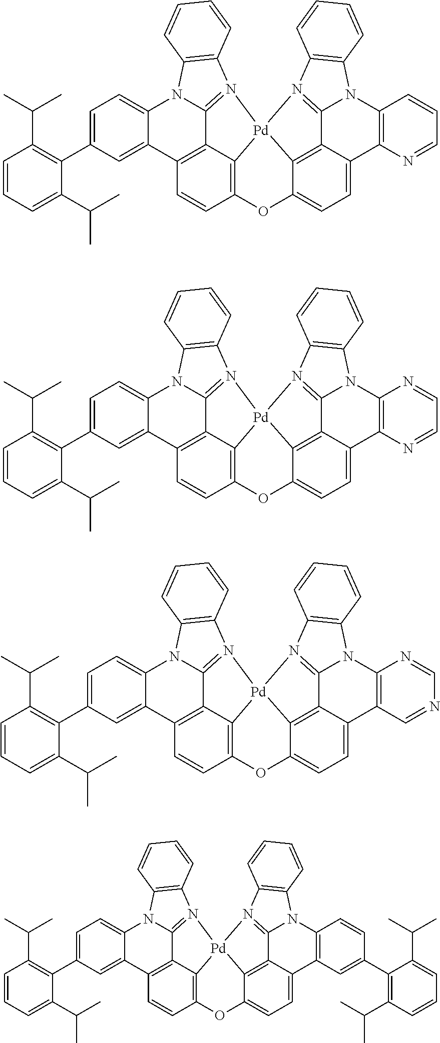

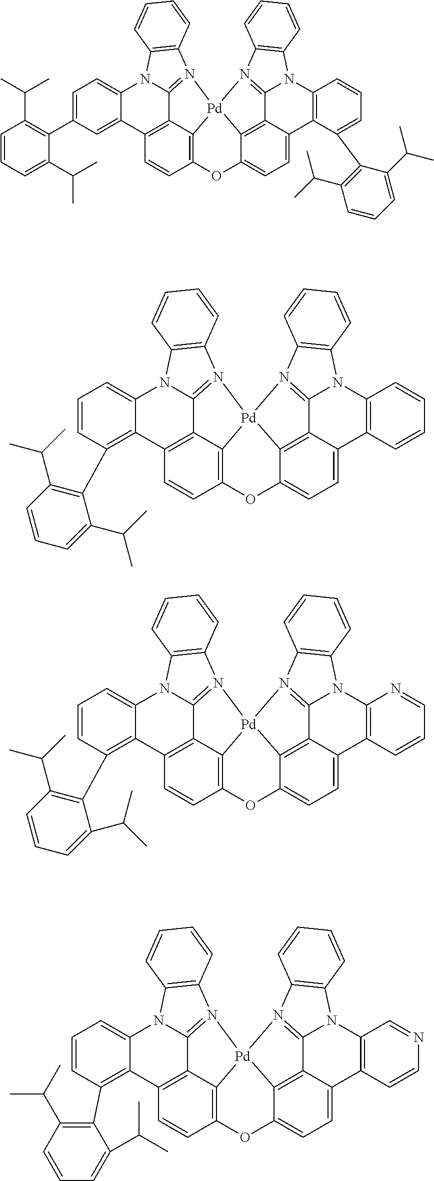

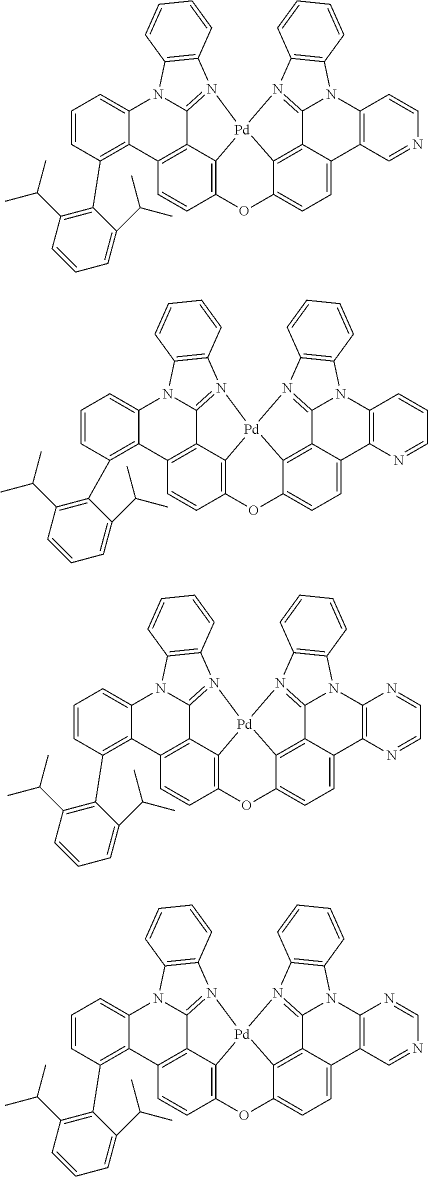

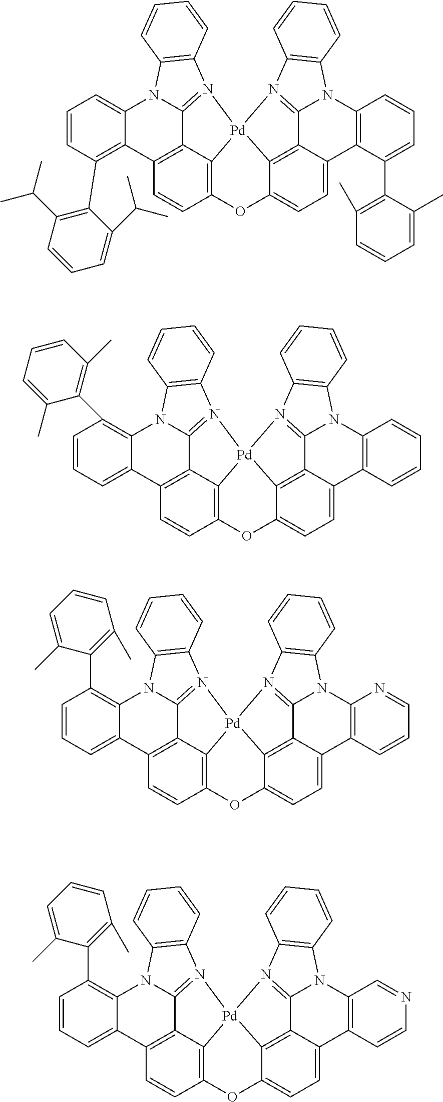

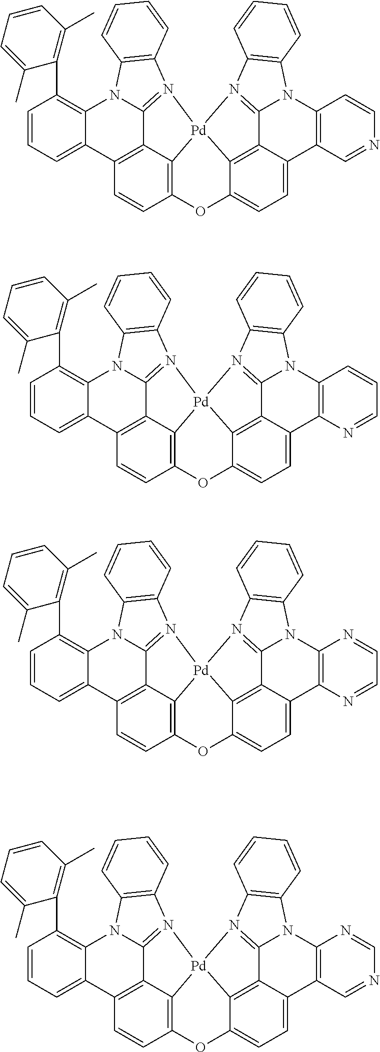

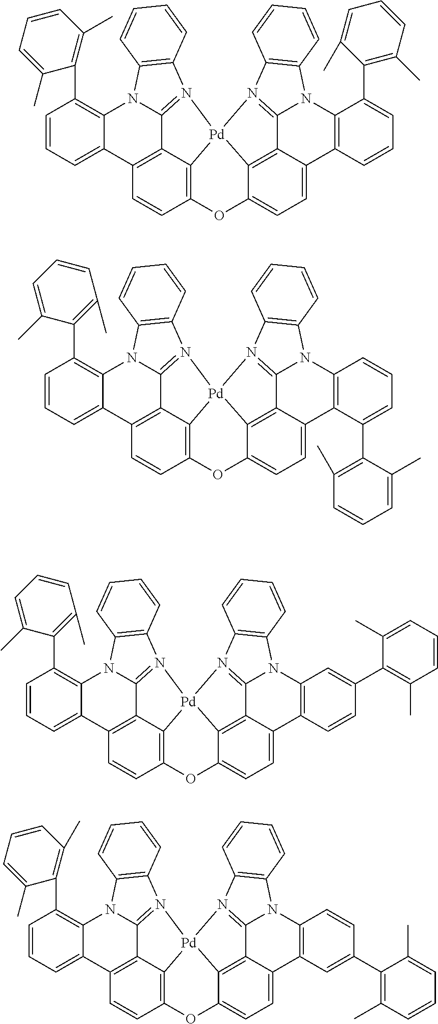

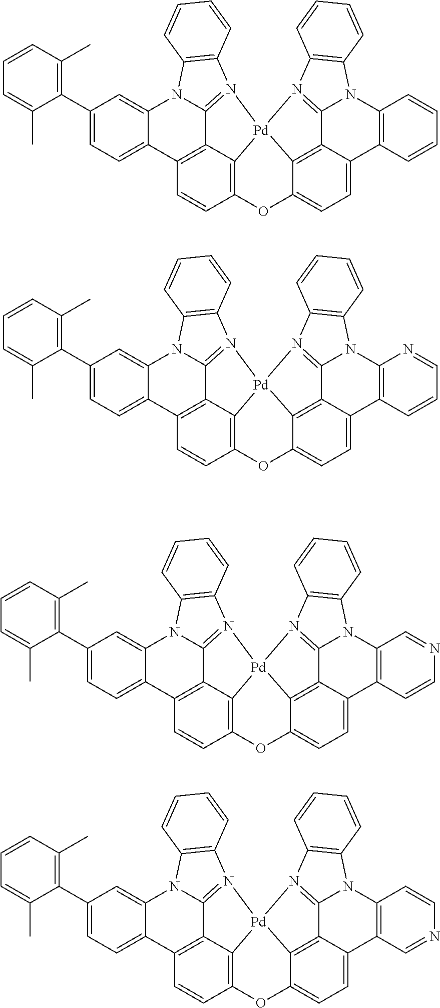

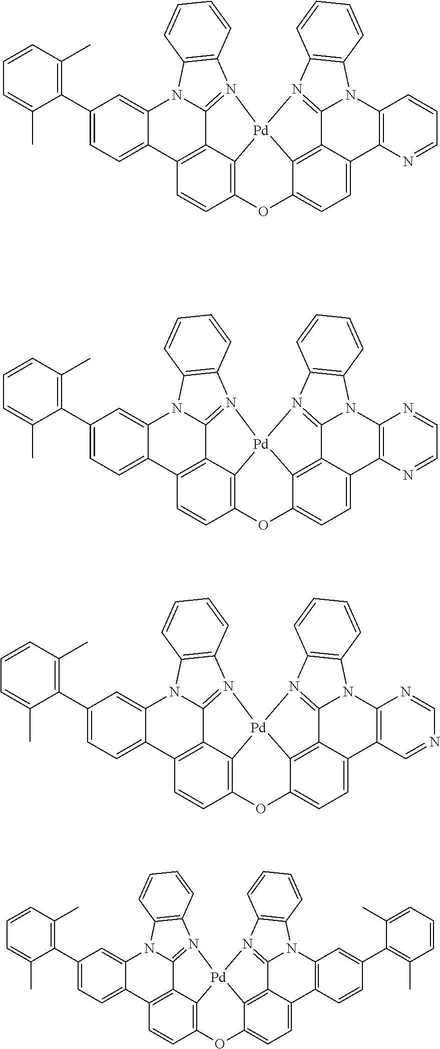

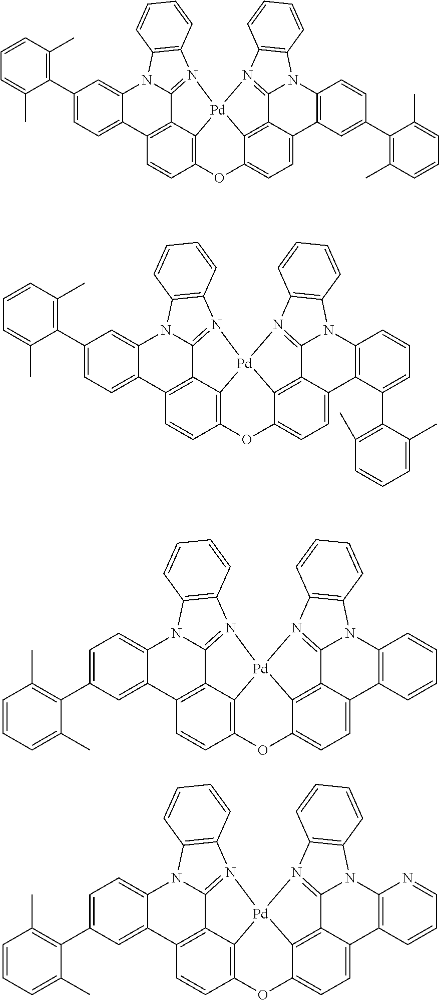

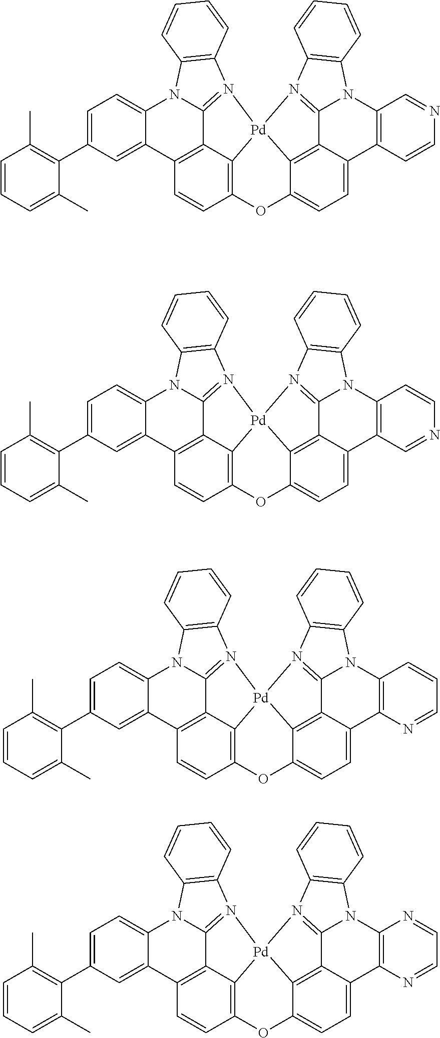

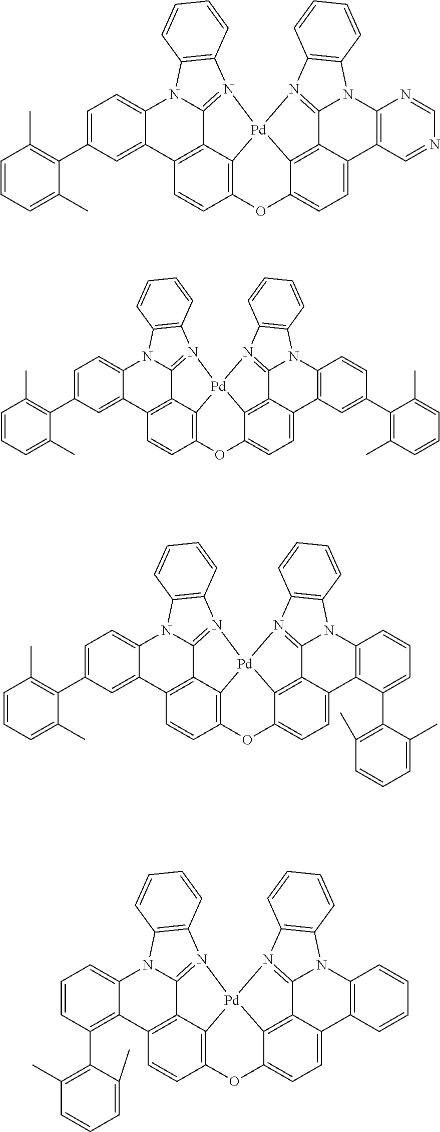

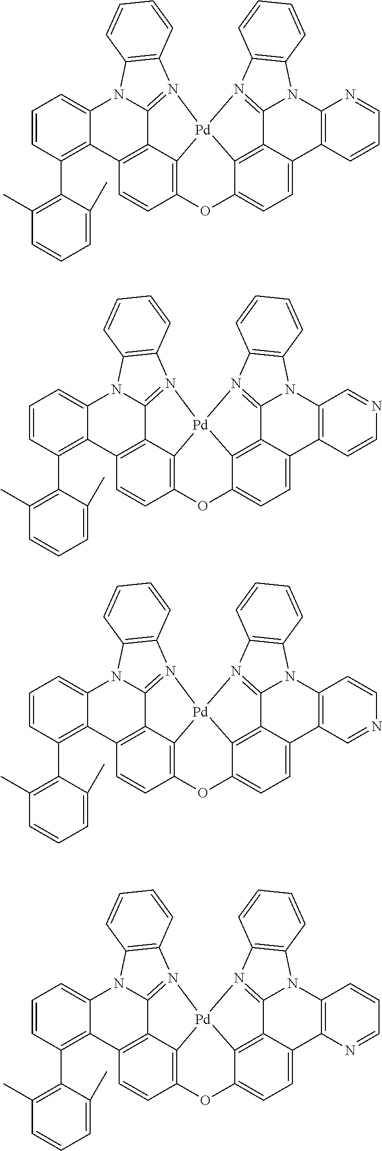

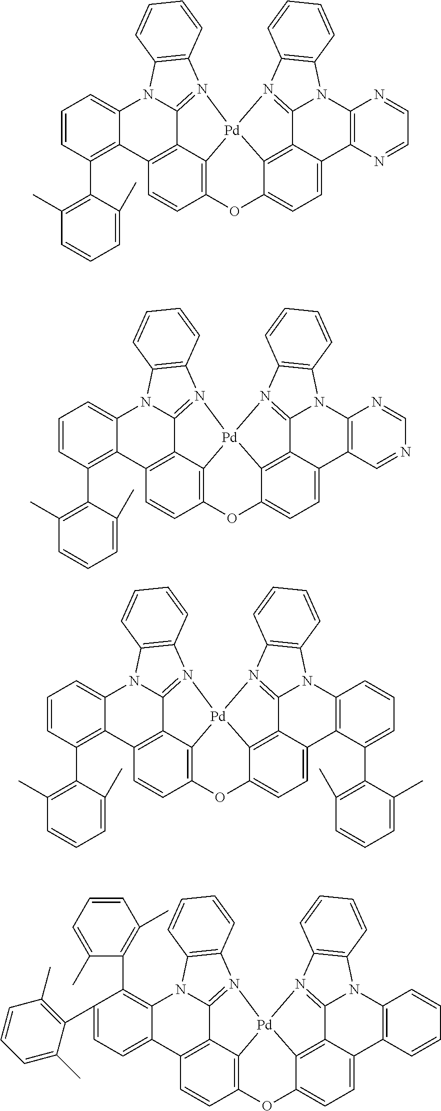

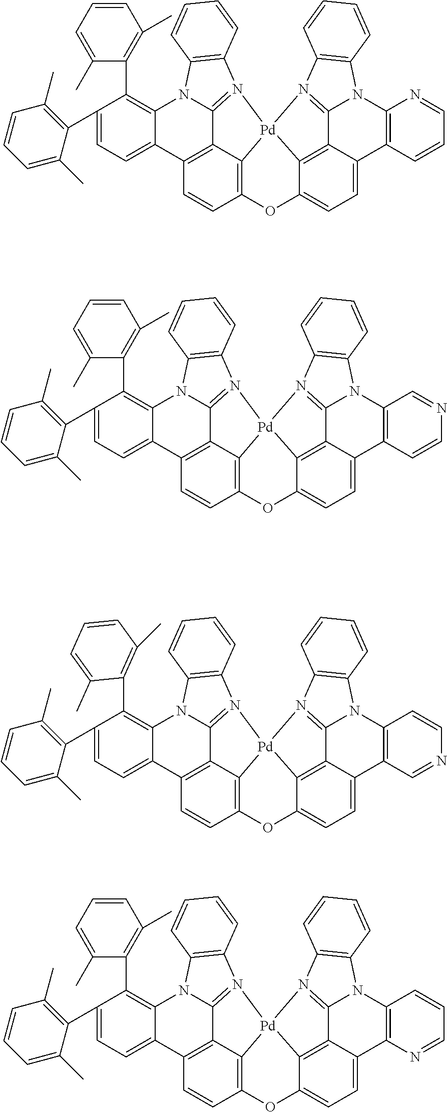

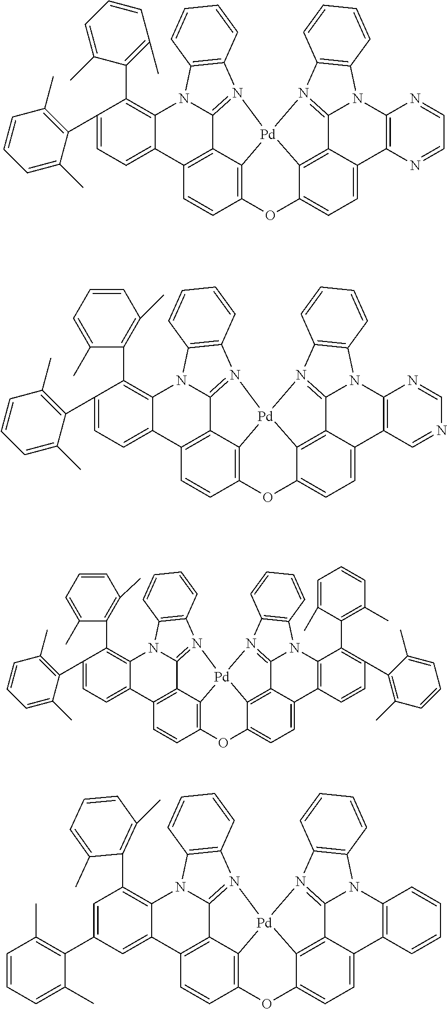

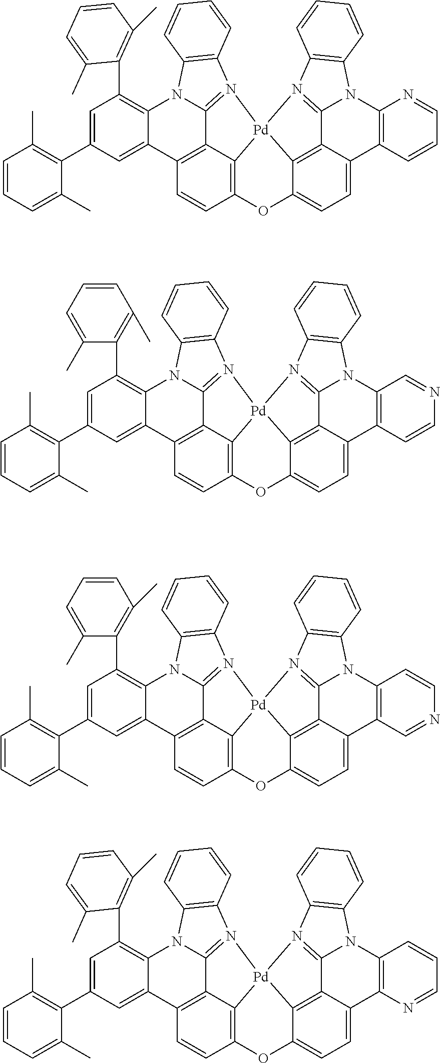

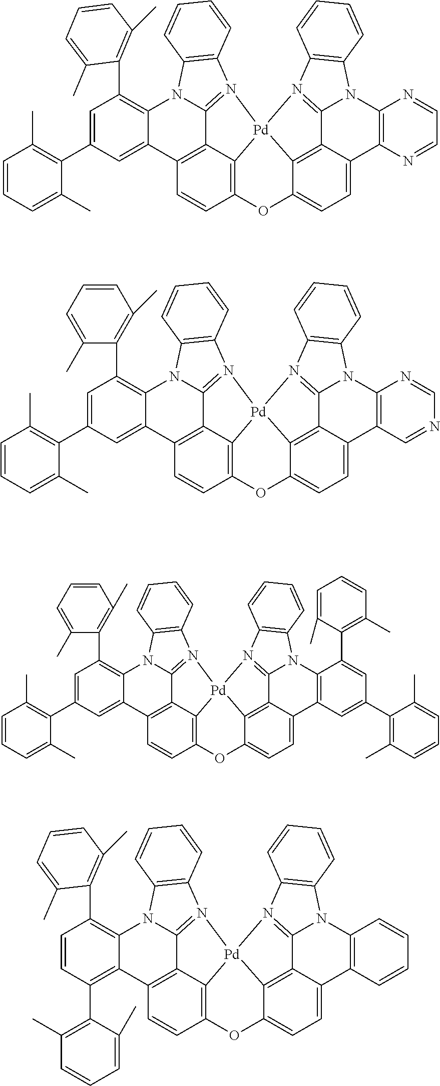

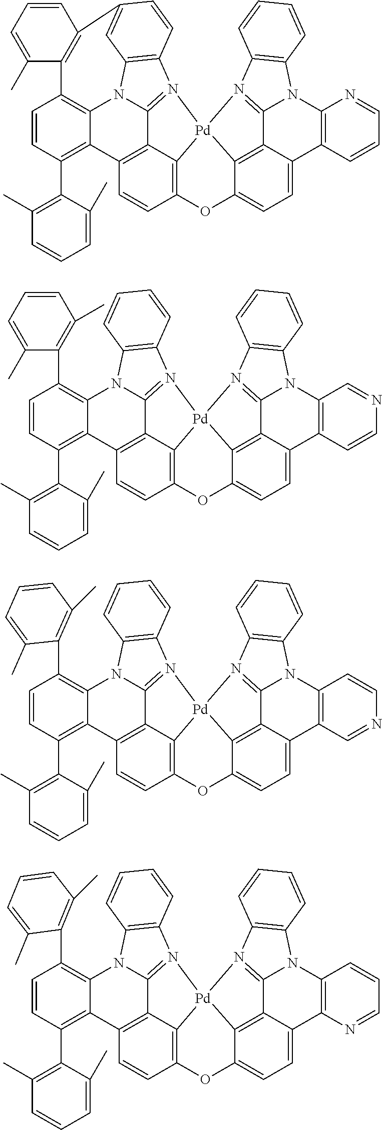

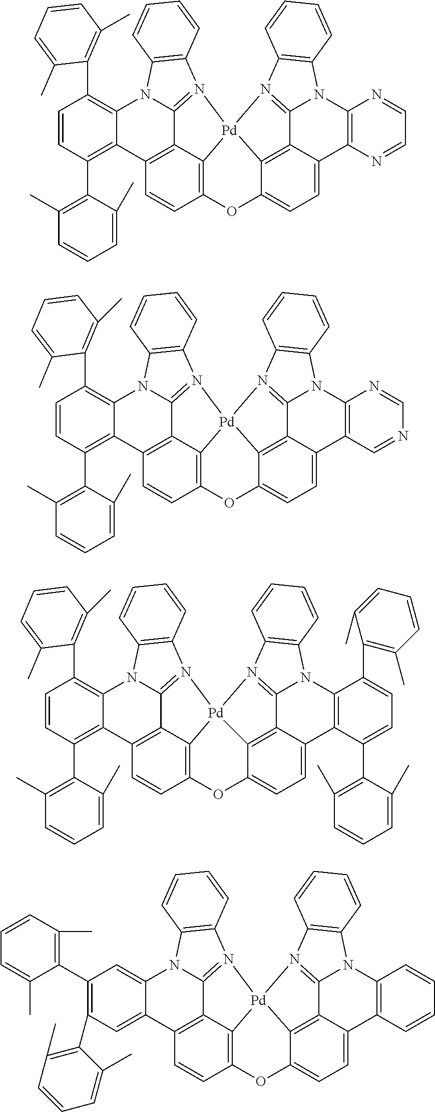

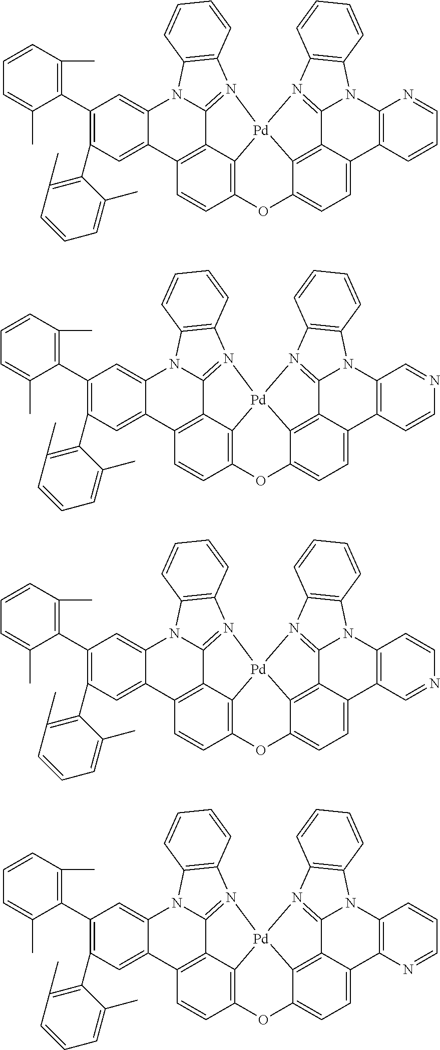

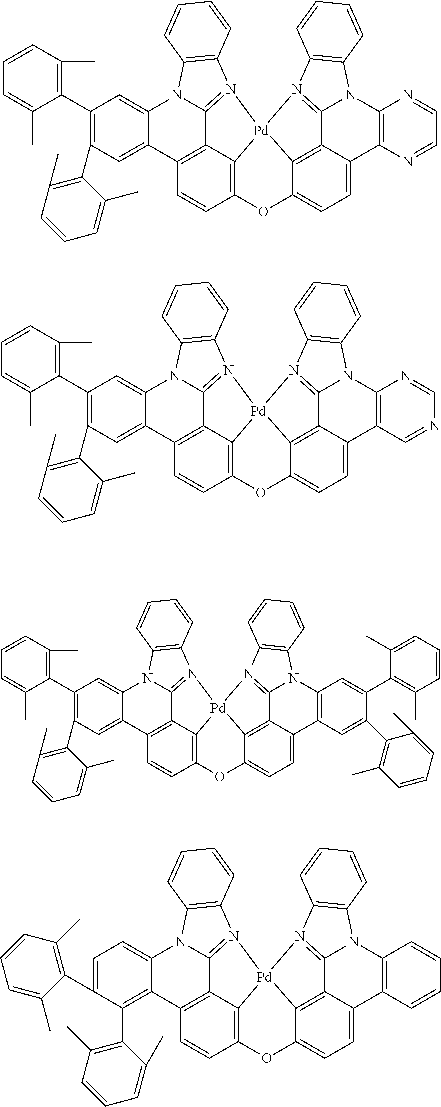

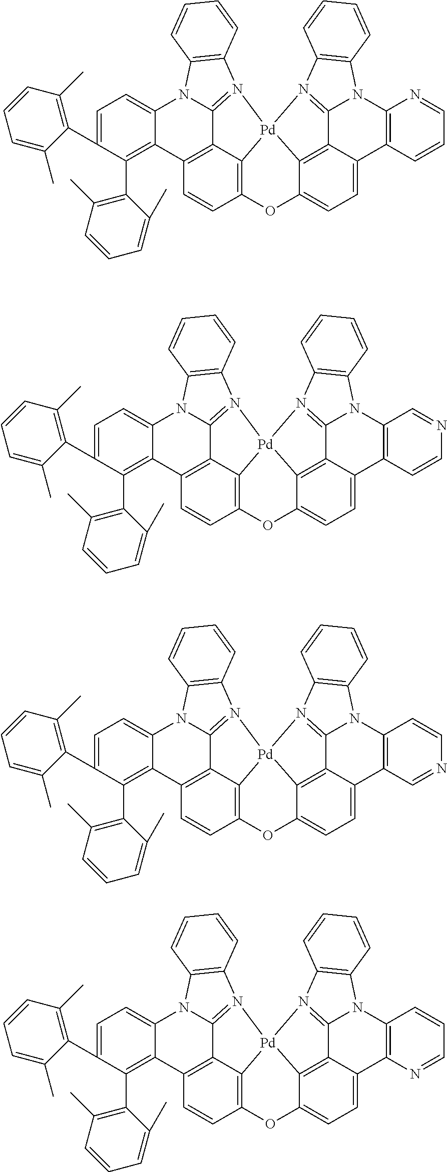

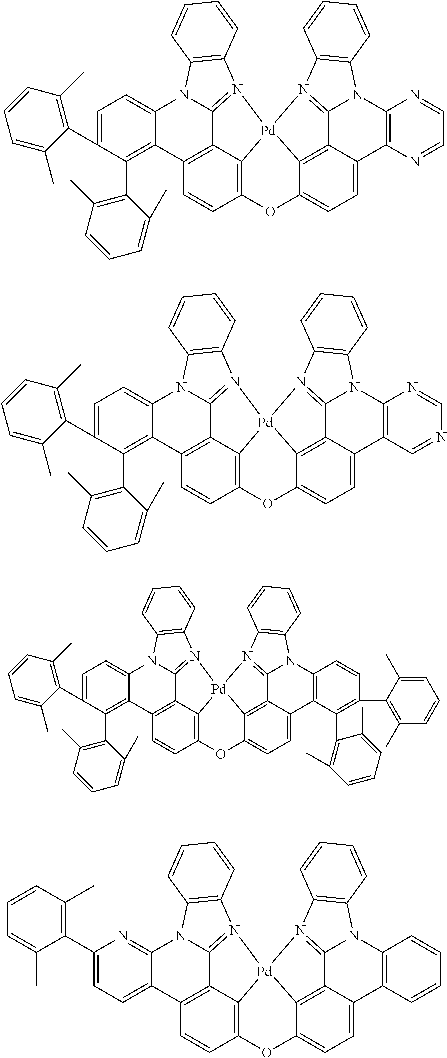

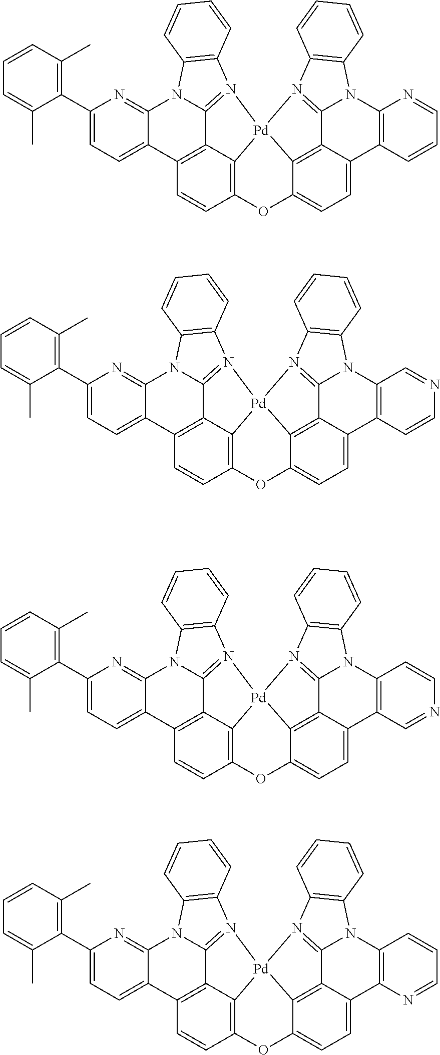

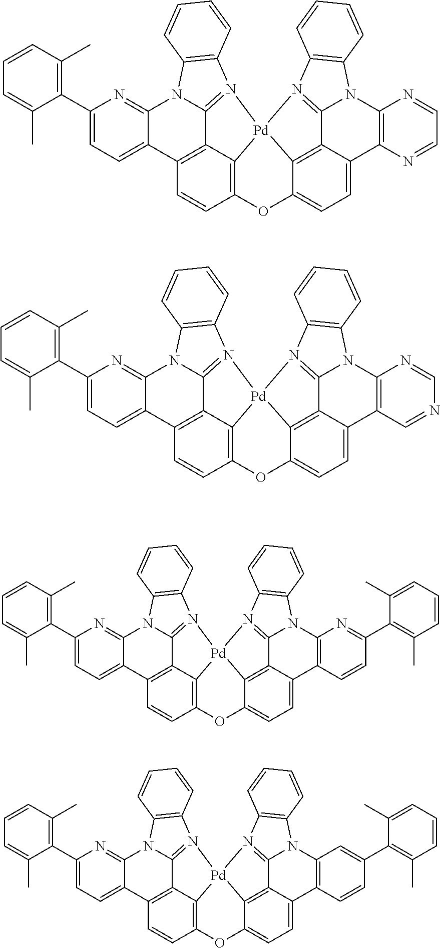

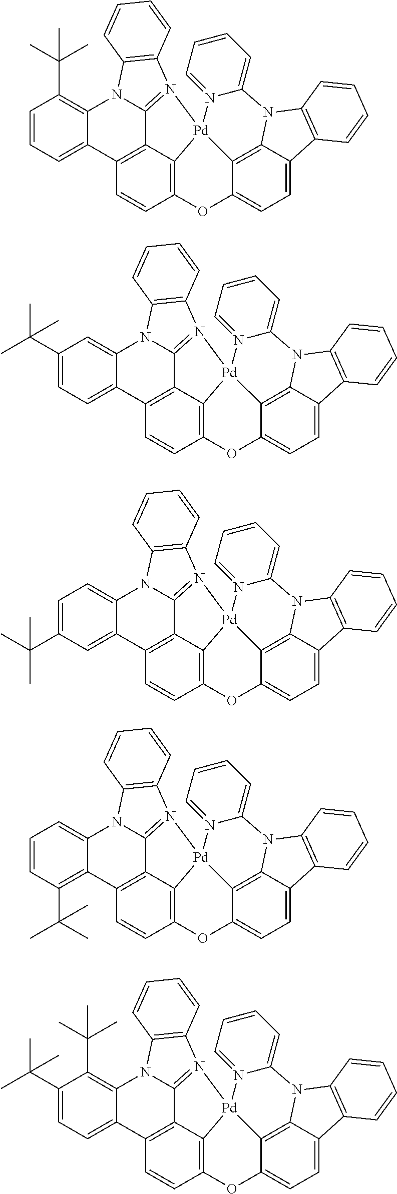

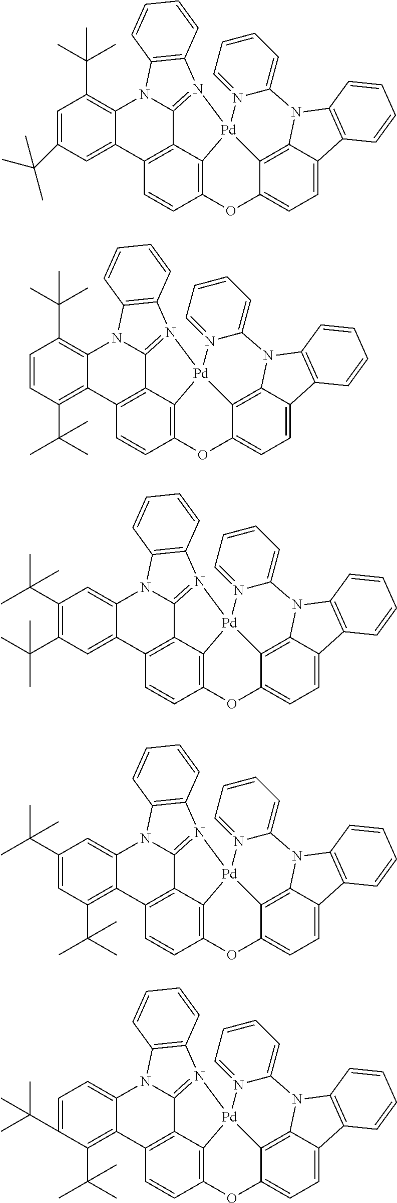

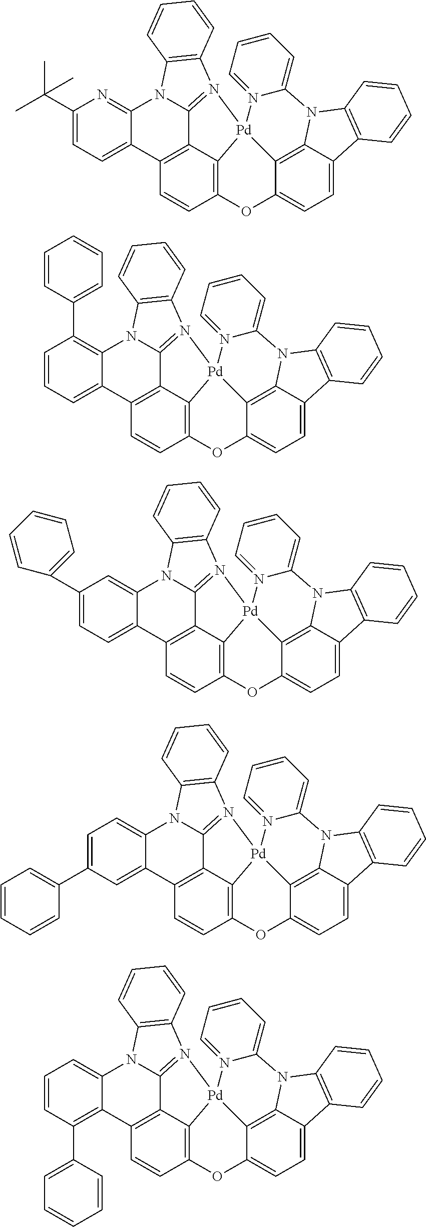

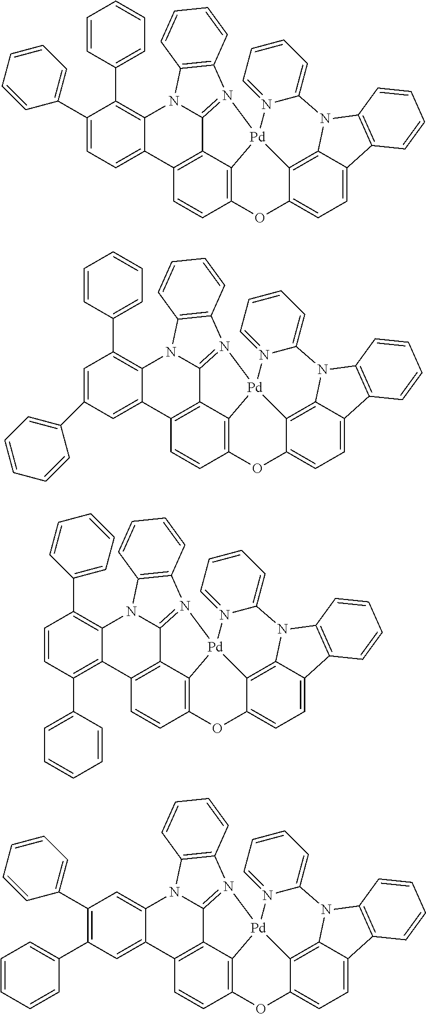

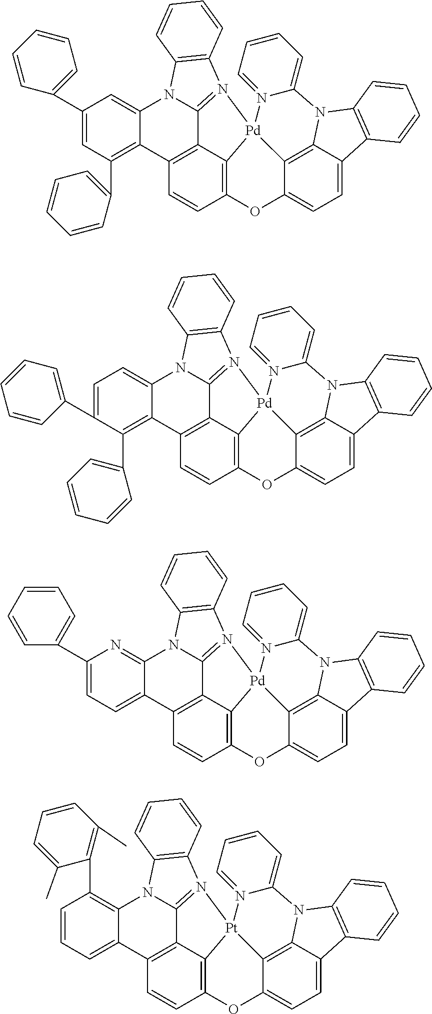

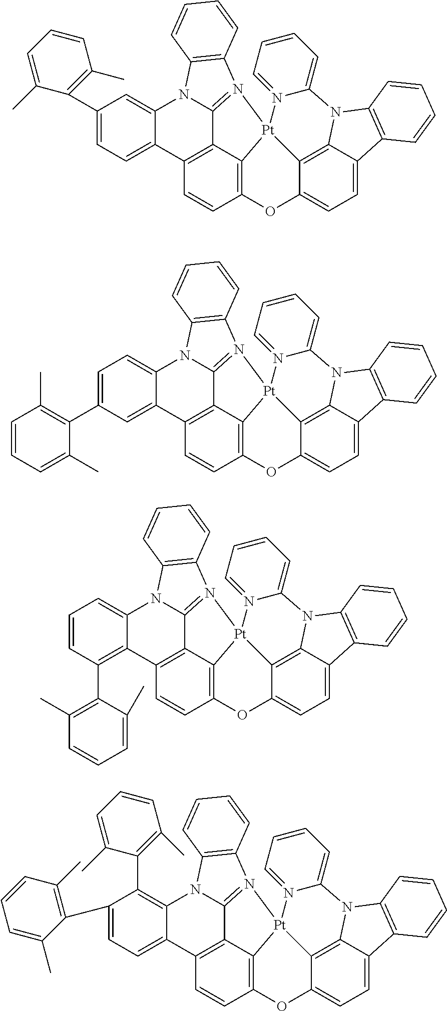

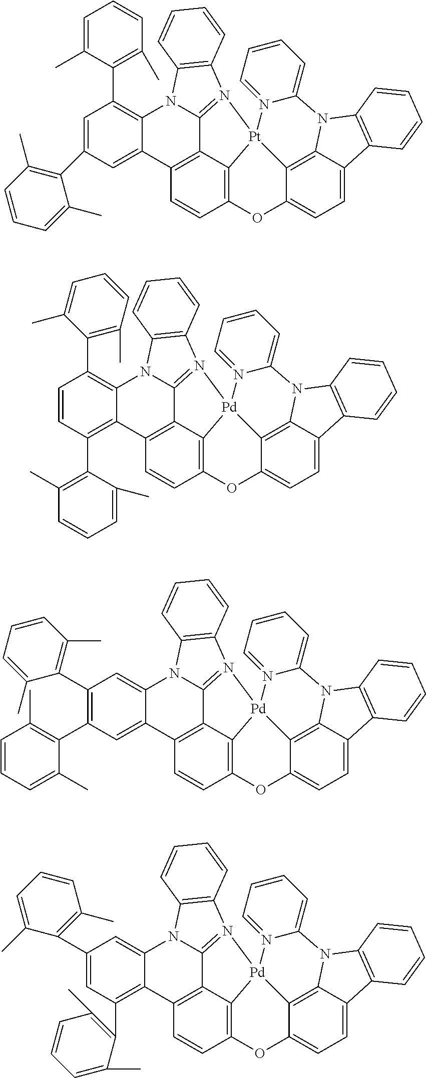

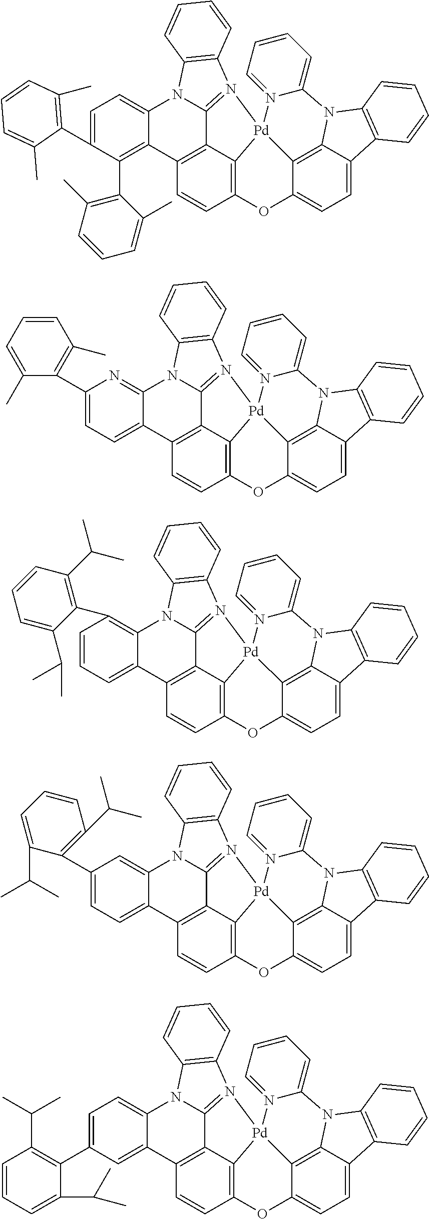

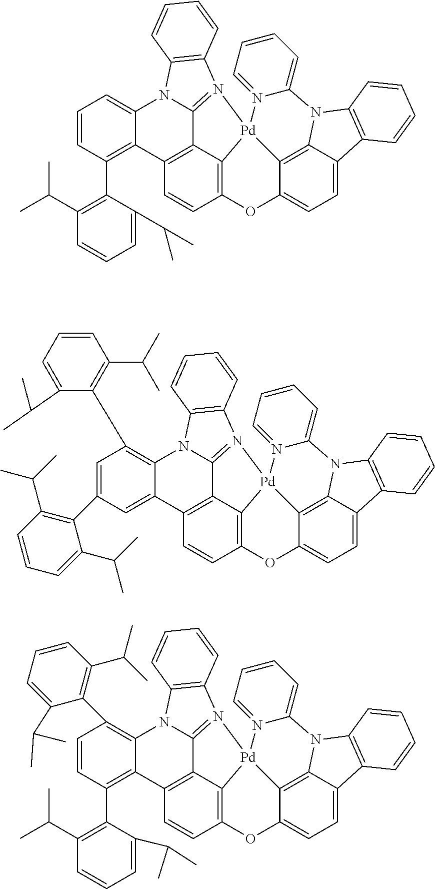

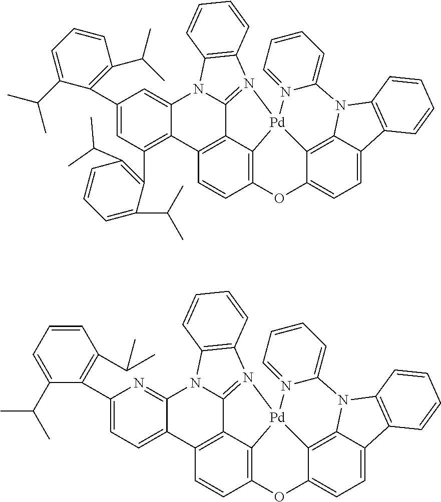

### Compostions and Devices

Also disclosed herein are devices comprising one or more compound and/or compositions discoed herein.

In one aspect, the device is an electro-optical device. Electro-optical devices include, but are not limited to, photo-absorbing devices such as solar- and photo-sensitive devices, organic light emitting devices (OLEDs), photo-emitting devices, or devices capable of both photo-absorption and emission and as markers for bio-applications. For example, the device can be an OLED.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al, “Highly Efficient Phosphorescent Emission from Organic Electroluminescent Devices,” Nature, vol. 395, 151-154, 1998; (“Baldo-I”) and Baldo et alt, “Very high-efficiency green organic light-emitting devices based on electrophosphorescence,” Appl. Phys. Lett., vol. 75, No. 3, 4-6 (1999) (“Baldo-II”), which are incorporated by reference in their entireties. Phosphorescence is described in more detail in U.S. Pat. No. 7,279,704 at cols. 5-6, which are incorporated by reference.

One application for phosphorescent emissive molecules is a full color display. Industry standards for such a display call for pixels adapted to emit particular colors, referred to as “saturated” colors. In particular, these standards call for saturated red, green, and blue pixels. Color may be measured using CIE coordinates, which are well known to the art. Such devices are disclosed herein which comprise one or more of the compounds or compositions disclosed herein.

OLEDs can be produced by methods known to those skilled in the art. In general, the OLED is produced by successive vapor deposition of the individual layers onto a suitable substrate. Suitable substrates include, for example, glass, inorganic materials such as ITO or IZ or polymer films. For the vapor deposition, customary techniques may be used, such as thermal evaporation, chemical vapor deposition (CVD), physical vapor deposition (PVD) and others.

In an alternative process, the organic layers may be coated from solutions or dispersions in suitable solvents, in which case coating techniques known to those skilled in the art are employed. Suitable coating techniques are, for example, spin-coating, the casting method, the Langmuir-Blodgett (“L”) method, the inkjet printing method, dip-coating, letterpress printing, screen printing, doctor blade printing, slit-coating, roller printing, reverse roller printing, offset lithography printing, flexographic printing, web printing, spray coating, coating by a brush or pad printing, and the like. Among the processes mentioned, in addition to the aforementioned vapor deposition, preference is given to spin-coating, the inkjet printing method and the casting method since they are particularly simple and inexpensive to perform. In the case that layers of the OLED are obtained by the spin-coating method, the casting method or the inkjet printing method, the coating can be obtained using a solution prepared by dissolving the composition in a concentration of 0.0001 to 90% by weight in a suitable organic solvent such as benzene, toluene, xylene, tetrahydrofuran, methyltetrahydrofuran, N,N-dimethylformamide, acetone, acetonitrile, anisole, dichloromethane, dimethyl sulfoxide, water and mixtures thereof.

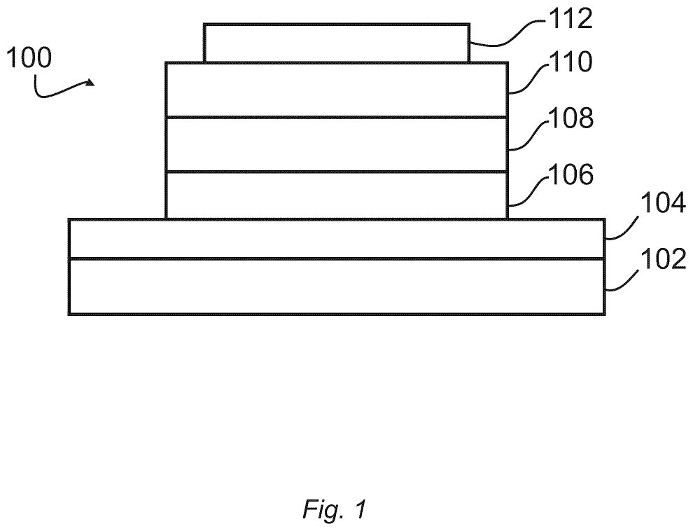

Compounds described herein can be used in a light emitting device such as an OLED. FIG. 1 depicts a cross-sectional view of an OLED 100. OLED 100 includes substrate 102, anode 104, hole-transporting material(s) (HTL) 106, light processing material 108, electron-transporting material(s) (ETL) 110, and a metal cathode layer 112. Anode 104 is typically a transparent material, such as indium tin oxide. Light processing material 108 may be an emissive material (EMIL) including an emitter and a host.

In various aspects, any of the one or more layers depicted in FIG. 1 may include indium tin oxide (ITO), poly(3,4-ethylenedioxythiophene) (PEDOT), polystyrene sulfonate (PSS), N,N′-di-1-naphthyl-N,N-diphenyl-1,1′-biphenyl-4,4′ diamine (NPD), 1,1-bis((di-4-tolylamino)phenyl)cyclohexane (TAPC), 2,6-Bis(N-carbazolyl)pyridine (mCpy), 2,8-bis(diphenylphosphoryl)dibenzothiophene (PO15), LiF, Al, or a combination thereof.

Light processing material 108 may include one or more compounds of the present disclosure optionally together with a host material. The host material can be any suitable host material known in the art. The emission color of an OLE-D is determined by the emission energy (optical energy gap) of the light processing material 108, which can be tuned by tuning the electronic structure of the emitting compounds, the host material, or both. Both the hole-transporting material in the HTL layer 106 and the electron-transporting material(s) in the ETL layer 110 may include any suitable hole-transporter known in the art.

Compounds described herein may exhibit phosphorescence. Phosphorescent OLEDs (i.e., OLEDs with phosphorescent emitters) typically have higher device efficiencies than other OLEDs, such as fluorescent OLEDs. Light emitting devices based on electrophosphorescent emitters are described in more detail in WO2000/070655 to Baldo et al., which is incorporated herein by this reference for its teaching of OLEDs, and in particular phosphorescent OLEDs.

As contemplated herein, an OLED may include an anode, a cathode, and an organic layer disposed between the anode and the cathode. The organic layer may include a host and a phosphorescent dopant. The organic layer can include a compound disclosed herein and its variations as described herein.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLE)D is a lighting panel.

In one embodiment, the consumer product is selected from the group consisting of a flat panel display, a computer monitor, a medical monitor, a television, a billboard, a light for interior or exterior illumination and/or signaling, a heads-up display, a fully or partially transparent display, a flexible display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video wall comprising multiple displays tiled together, a theater or stadium screen, and a sign.

In some embodiments of the emissive region, the emissive region further comprises a host, wherein the host comprises at least one selected from the group consisting of metal complex, triphenylene, carbazole, dibenzothiophene, dibenzofuran, dibenzoselenophene, aza-triphenylene, aza-carbazole, aza-dibenzothiophene, aza-dibenzofuran, and aza-dibenzoselenophene.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be a triphenylene containing benzo-fused thiophene or benzo-fused furan. Any substituent in the host can be an unfused substituent independently selected from the group consisting of CnH2n+1, OCnH2n+1, OAr1, N(CnH2n+1)2, N(Ar1)(Ar2), CH═CH—CnH2n+1, C≡C—CnH2n+1, Ar1, Ar1-Ar2, and CnH2n-Ar1, or the host has no substitutions. In the preceding substituents n can range from 1 to 10; and Ar1 and Ar2 can be independently selected from the group consisting of benzene, biphenyl, naphthalene, triphenylene, carbazole, and heteroaromatic analogs thereof. The host can be an inorganic compound. For example, a Zn containing inorganic material e.g. ZnS.

Suitable hosts may include, but are not limited to, mCP (1,3-bis(carbazol-9-yl)benzene), mCPy (2,6-bis(N-carbazolyl)pyridine), TCP (1,3,5-tris(carbazol-9-yl)benzene), TCTA (4,4′,4″-tris(carbazol-9-yl)triphenylamine), TPBi (1,3,5-tris(1-phenyl-1-benzimidazol-2-yl)benzene), mCBP (3,3-di(9H-carbazol-9-yl)biphenyl), pCBP (4,4′-bis(carbazol-9-yl)biphenyl), CDBP (4,4′-bis(9-carbazolyl)-2,2′-dimethylbiphenyl), DMF L-CBP (4,4′-bis(carbazol-9-yi)-9,9-dimethylfluorene), FL-4CBP (4,4′-bis(carbazol-9-yl)-9,9-bis(9-phenyl-91-1-carbazole)fluorene), FL-2CBP (9,9-bis(4-carbazol-9-yl)phenyl)fluorene, also abbreviated as CPF), DPFL-CBP (4,4′-bis(carbazol-9-yl)-9,9-ditolylfluorene), FL-2CBP (9,9-bis(9-phenyl-9H-carbazole)fluorene), Spiro-CBP (2,2′,7,7′-tetrakis(carbazol-9-yl)-9,9′-spirobifluorene), ADN (9,10-di(naphth-2-yl)anthracene), TBADN (3-tert-butyl-9,10-di(naphth-2-yl)anthracene), DPVBi (4,4′-bis(2,2-diphenylethen-1-yl)-4,4′-dimethylphenyl), p-DMDPVBi (4,4′-bis(2,2-diphenylethen-1-yl)-4,4′-dimethylphenyl), TDAF (tert(9,9-diarylfluorene)), BSBF (2-(9,9′-spirobifluoren-2-yl)-9,9′-spirobifluorene), TSBF (2,7-bis(9,9′-spirobifluoren-2-yl)-9,9′-spirobifluorene), BDAF (bis(9,9-diarylfluorene)), p-TDPVBi (4,4′-bis(2,2-diphenylethen-1-yl)-4,4′-di-(tert-butyl)phenyl), TPB3 (1,3,5-tri(pyren-1-yl)benzene, PBD (2-(4-biphenylyl)-5-(4-tert-butylphenyl)-1,3,4-oxadiazole), BCP (2,9-dimethyl-4,7-diphenyl-1,10-phenanthroline), BP-OXD-Bpy (6,6′-bis[5-(biphenyl-4-yl)-1,3,4-oxadiazo-2-yl]-2,2′-bipyridyl), NTAZ (4-(naphth-1-yl)-3,5-diphenyl-4H-1,2,4-triazole), Bpy-OXD (1,3-bis[2-(2,2′-bipyrid-6-yl)-1,3,4oxadiazo-5-yl]benzene), BPhen (4,7-diphenyl-1,10-phenanthroline), TAZ (3-(4-biphenylyl)-4-phenyl-5-tert-butylphenyl-1,2,4-triazole), PADN (2-phenyl-9,10-di(naphth-2-yl)anthracene), Bpy-FOXD (2,7-bis[2-(2,2′-bipyrid-6-yl)-1,3,4-oxadiazol-5-yl]-9,9-dimethylfluorene), OXD-7 (1,3-bis[2-(4-tert-butylphenyl)-1,3,4-oxadiazol-5-yl]benzene), HNBphen (2-(naphth-2-yl)-4,7-diphenyl-1,10-phenanthroline), NBphen (2,9-bis(naphth-2-yl)-4,7-diphenyl-1,10-phenanthroline), 3TPYMB (tris(2,4,6-trimethyl-3-(pyrid-3-yl)phenyl)borane), 2-NPIP (1-methyl-2-(4-(naphth-2-yl)phenyl)-11-1-imidazo[4,5-f]-[1,10]phenanthroline), Liq (8-hydroxyquninolinolatolithium), and Alq (bis(2-methyl-8-quinolinolate)-4-(phenylphenolato)aluminum), and also of mixtures of the aforesaid substances.

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

Non-limiting examples of the conductivity dopants that may be used in an OLED in combination with materials disclosed herein are exemplified below together with references that disclose those materials: EP01617493, EP01968131, EP2020694, EP2684932, US20050139810, US20070160905, US20090167167, US2010288362, WO06081780, WO2009003455, WO2009008277, WO2009011327, WO2014009310, US2007252140, US2015060804, US20150123047, and US2012146012.

A hole injecting/transporting material is not particularly limited, and any compound may be used as long as the compound is typically used as a hole injecting/transporting material. Examples of the material include, but are not limited to: a phthalocyanine or porphyrin derivative; an aromatic amine derivative; an indolocarbazole derivative; a polymer containing fluorohydrocarbon; a polymer with conductivity dopants; a conducting polymer, such as PEDOT/PSS; a self-assembly monomer derived from compounds such as phosphonic acid and silane derivatives; a metal oxide derivative, such as MoOₓ; a p-type semiconducting organic compound, such as 1,4,5,8,9,12-Hexaazatriphenylenehexacarbonitrile; a metal complex, and a cross-linkable compounds.

An electron blocking layer (EBL) may be used to reduce the number of electrons and/or excitons that leave the emissive layer. The presence of such a blocking layer in a device may result in substantially higher efficiencies, and/or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and/or higher triplet energy than one or more of the hosts closest to the EBL interface. In one aspect, the compound used in EBL contains the same molecule or the same functional groups used as one of the hosts described below.

The light emitting layer of the organic EL device preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

One or more additional emitter dopants may be used in conjunction with the compound of the present disclosure. Examples of the additional emitter dopants are not particularly limited, and any compounds may be used as long as the compounds are typically used as emitter materials. Examples of suitable emitter materials include, but are not limited to, compounds which can produce emissions via phosphorescence, fluorescence, thermally activated delayed fluorescence, i.e., TADF (also referred to as E-type delayed fluorescence), triplet-triplet annihilation, or combinations of these processes.

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and/or higher triplet energy than the emitter closest to the HBL interface. In some embodiments, the HBL material has a lower HOMO (further from the vacuum level) and/or higher triplet energy than one or more of the hosts closest to the HIBL interface.

Electron transport layer (ETL) may include a material capable of transporting electrons. Electron transport layer may be intrinsic (undoped), or doped. Doping may be used to enhance conductivity. Examples of the ETL material are not particularly limited, and any metal complexes or organic compounds may be used as long as they are typically used to transport electrons.

In tandem or stacked OLEDs, the CCL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

In any above-mentioned compounds used in each layer of the OLED device, the hydrogen atoms can be partially or fully deuterated. Thus, any specifically listed substituent, such as, without limitation, methyl, phenyl, pyridyl, etc. may be undeuterated, partially deuterated, and fully deuterated versions thereof. Similarly, classes of substituents such as, without limitation, alkyl, aryl, cycloalkyl, heteroaryl, etc. also may be undeuterated, partially deuterated, and fully deuterated versions thereof.

In yet another aspect of the present disclosure, a formulation that comprises the novel compound disclosed herein is described. The formulation can include one or more components selected from the group consisting of a solvent, a host, a hole injection material, hole transport material, and an electron transport layer material, disclosed herein.

### EXPERIMENTAL EXAMPLES

The following experimental examples are provided for purposes of illustration only, and are not intended to be limiting unless otherwise specified. Thus, the disclosure should in no way be construed as being limited to the following examples, but rather, should be construed to encompass any and all variations which become evident as a result of the teaching provided herein.

Without further description, it is believed that one of ordinary skill in the art can, using the preceding description and the following illustrative examples, make and utilize the composite materials disclosed herein and practice the claimed methods. The following working examples therefore, specifically point out the preferred embodiments of the present disclosure, and are not to be construed as limiting in any way the remainder of the disclosure.

### Materials and Methods

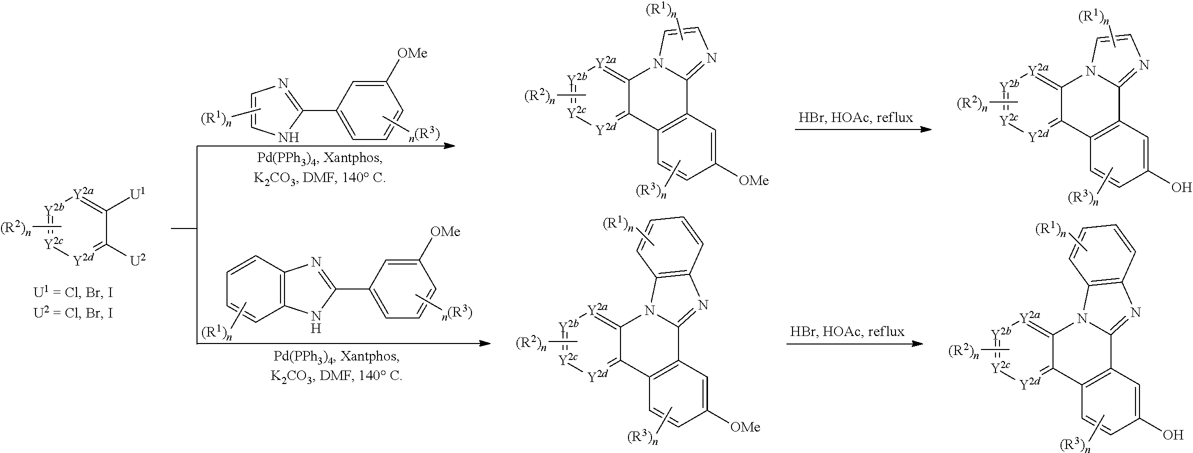

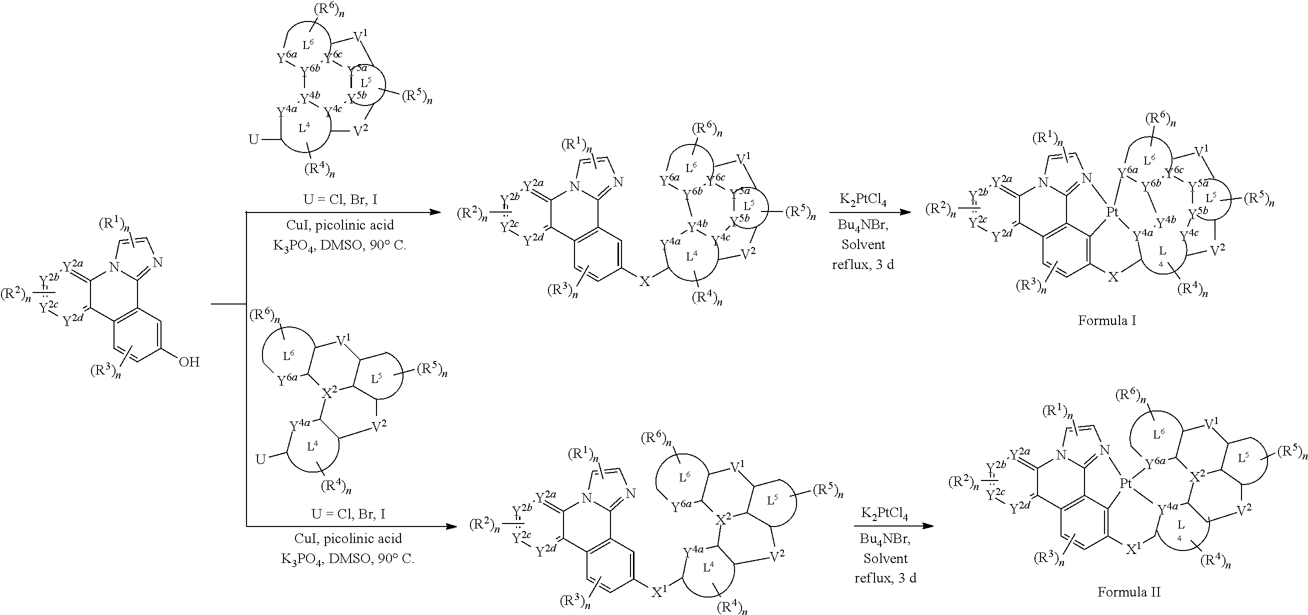

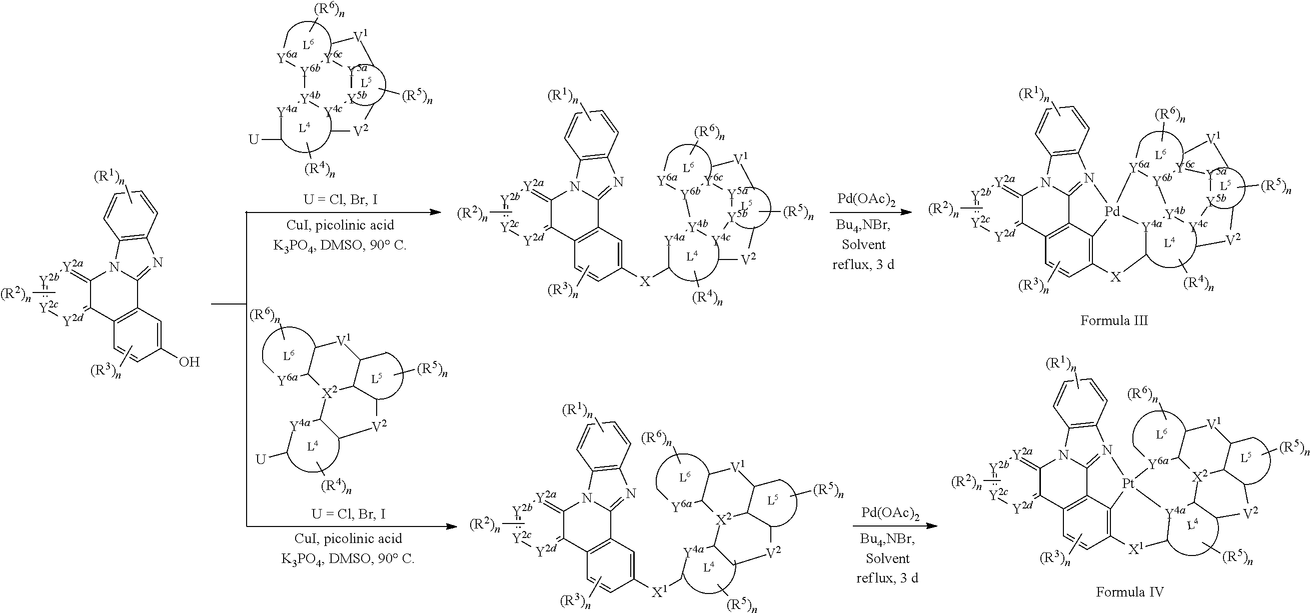

### Example 1

In one embodiment, an exemplary compound maybe prepared according to the following scheme:

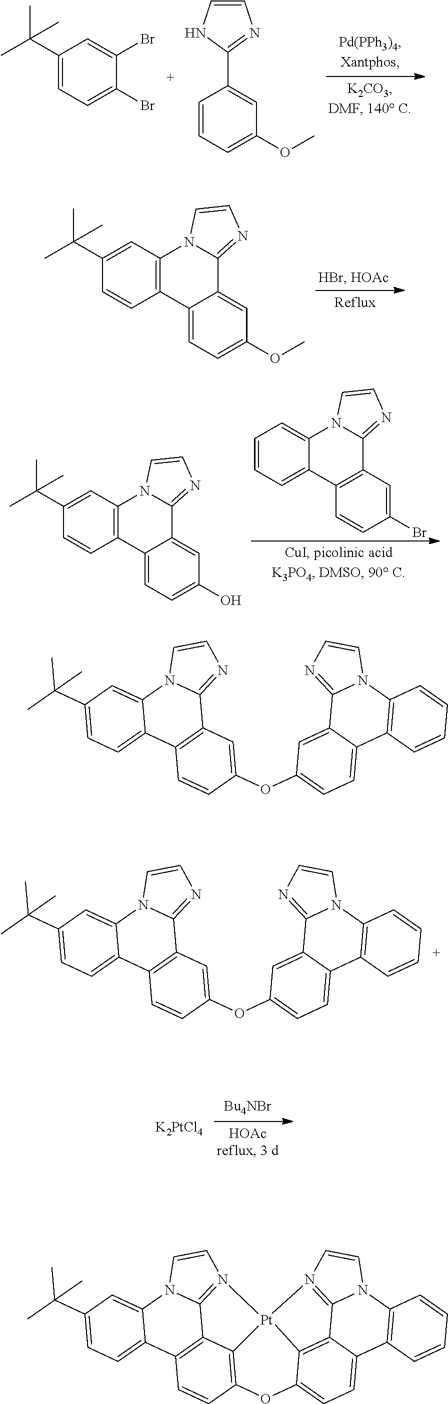

### Example 2

In one embodiment, an exemplary compound may be prepared according to the following scheme:

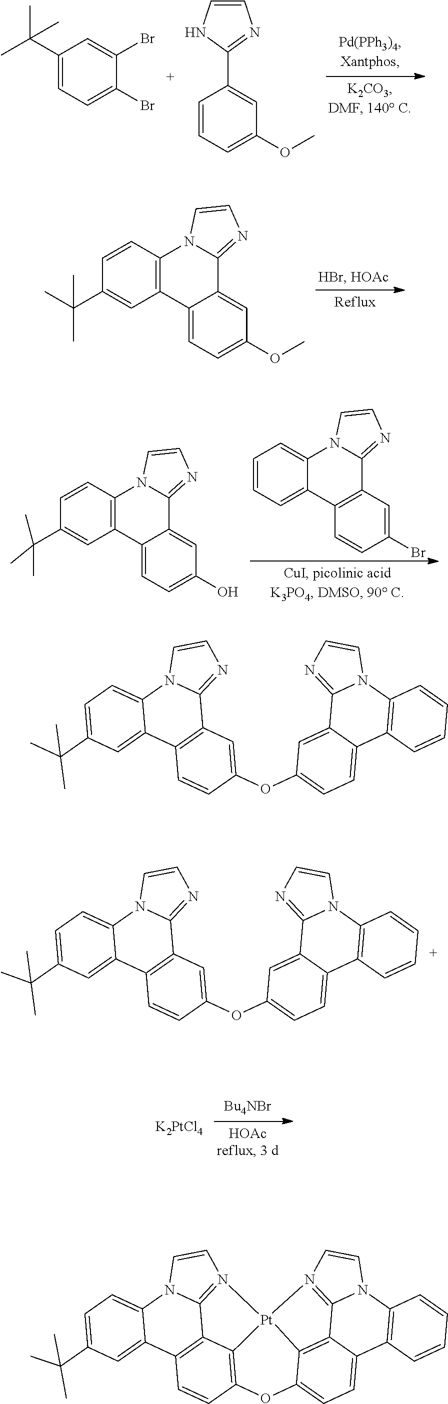

Synthesis of 6-(tert-buty)-11-methoxyimidazo[1,2-f]phenanthridine: 2-(3-methoxyphenyl)-1H-imidazole (1.0 g, 5.74 mmol, 1.0 eq), 1,2-dibromo-4-(tert-butyl)benzene (2.18 g, 7.46 mmol, 1.3 eq), Pd(PPh₃)₄ (0.66 g, 0.57 mmol, 0.1 eq), Xantphos (0.33 g, 0.57 mmol, 0.1 eq), and K₂CO₃ (2.38 g, 17.22 mmol. 3.0 eq) were added to a dry flask equipped with a magnetic stir bar. The flask was evacuated and backfilled with nitrogen for three times and DMF (30 mL) was added under the protection of nitrogen, the reaction mixture was stirred at 140° C. under nitrogen atmosphere overnight. After cooling to room temperature, the mixture was poured into water, extracted with ethyl acetate. The combined organic layer was dried with anhydrous Na₂SO₄, filtered and concentrated under reduced pressure. The residue was purified by column chromatography on silica gel to afford the desired product (0.68 g, 36%).

Synthesis of 6-(tert-butyl)imidazo[1,2-f]phenanthridin-11-ol: 6-(tert-butyl)-11-methoxyimidazo[1,2-f]phenanthridine (0.68 g, 2.23 mmol), 8 mL of HBr, and 24 mL of HOAc were added to a round bottom flask. The reaction mixture was stirred at 130° C. under nitrogen atmosphere for 2 days. The mixture was neutralized with K₂CO₃ aqueous solution to pH value of 6. Then the precipitate was filtered off and washed with water for several times. The collected solid was dried in air under reduced pressure to afford the product as an off-white solid (0.62 g, 92%).

Synthesis of ligand: A mixture of 6-tert-butyl)imidazo[1,2-f]phenanthridin-11-ol (0.4 g, 1.38 mmol, 1.0 eq), 11-bromobenzo[c]imidazo[1,2-a][1,5]naphthyridine (0.49 g, 1.65 mmol, 1.2 eq), CuI (0.053 g, 0.276 mmol, 0.2 eq), 2-picolinic acid (0.034 g, 0,276 mmol, 0.2 eq), K₃PO₄ (0.59 g, 2.76 mmol, 2.0 eg), and 15 mL of DMSO was stirred at 90° C. for 2 days under a nitrogen atmosphere, then cooled down to ambient temperature. The mixture was concentrated under reduced pressure. The residue was purified through column chromatography or silica gel using hexane/ethyl acetate as eluent to obtain the desired ligand as white solid (0.50 g, 71%).

Synthesis of Pt (II) complex: A mixture of ligand (0.05 g, 0.1 mmol, 1.0 eq), K₂PtCl₄ (0.043 g, 0.105 mmol, 1.05 eq), ⁿBu₄Br (0.003 g, 0.01 mmol, 0.1 eq), and 7 mL of 2-ethoxyethanol was stirred under reflux for 3 days via nitrogen atmosphere protection, then cooled down to ambient temperature. The mixture was concentrated under reduced pressure. The residue was purified through column chromatography on silica gel using hexane/methylene chloride as eluent to obtain the desired platinum compound as white solid (0.01 g, 14%).

### Example 3

In one embodiment, an exemplary compound may be prepared according to the following scheme:

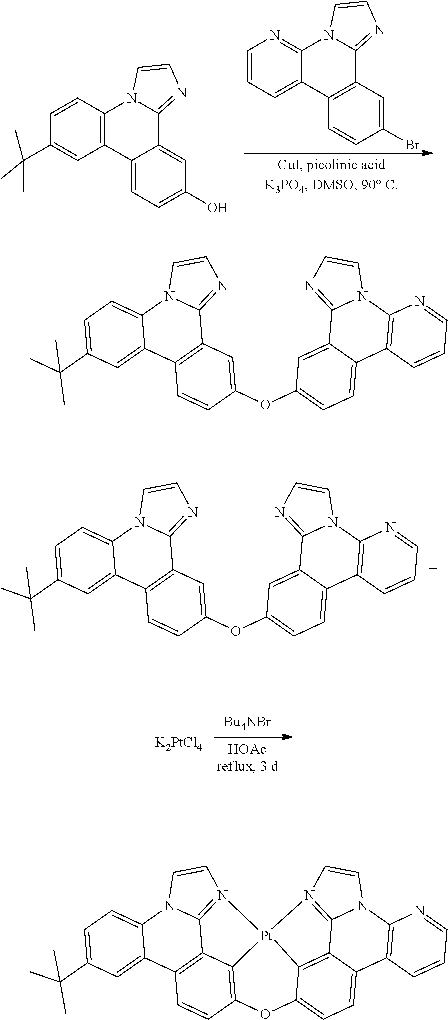

### Example 4

In one embodiment, an exemplary compound may be prepared according to the following scheme:

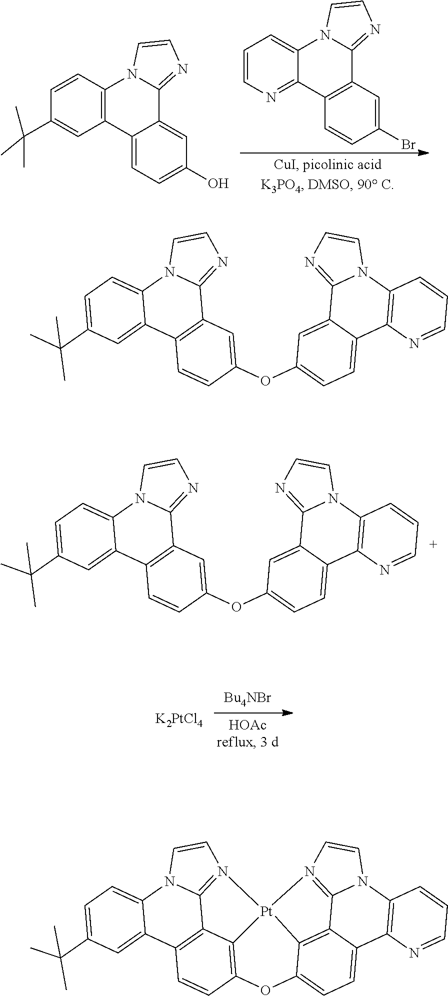

### Example 5

In one embodiment, an exemplary compound may be prepared according to the following scheme:

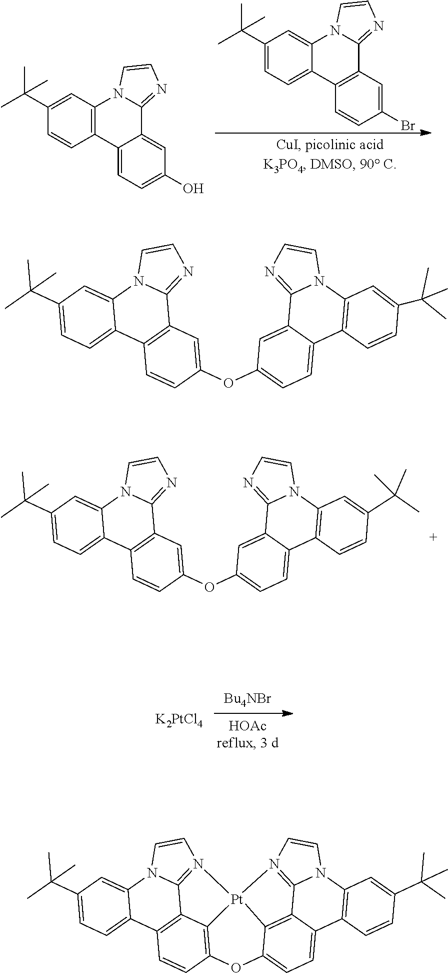

### Example 6

In one embodiment, an exemplary compound may be prepared according to the following scheme:

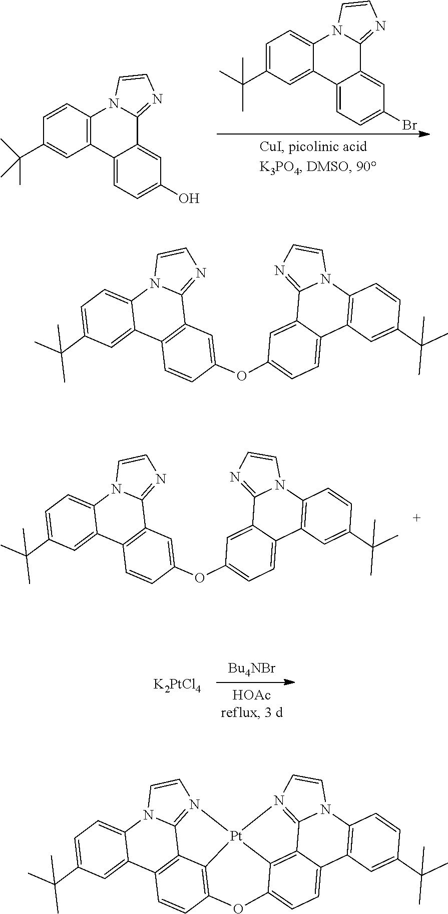

### Example 7

In one embodiment, an exemplary compound may be prepared according to the following scheme:

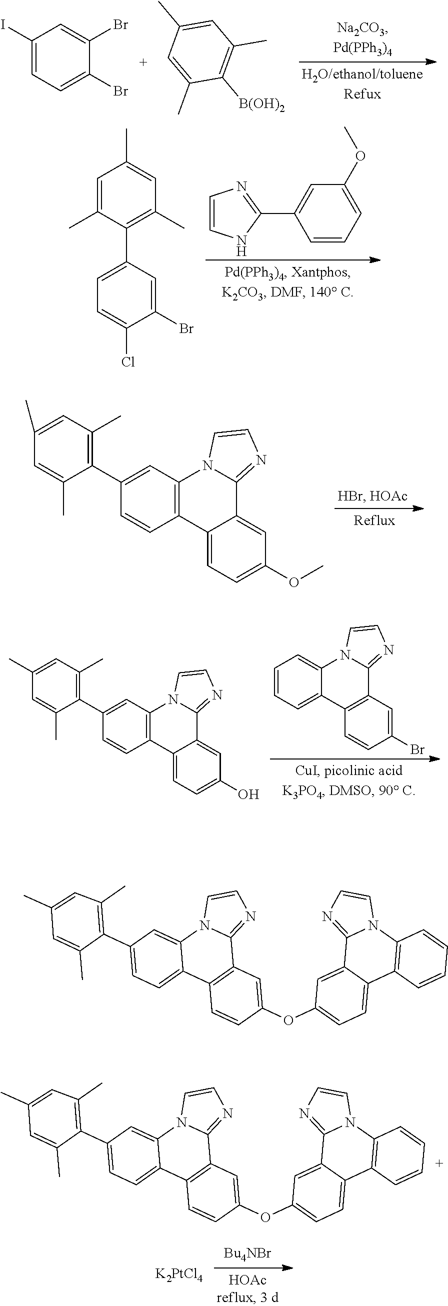

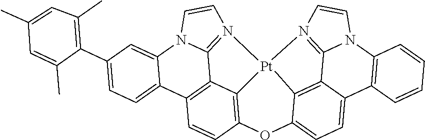

Synthesis of ligand: A mixture of 6-mesitylimidazo[1,2-f]phenanthridin-11-ol (0.2 g, 0.567 mmol, 1.0 eq), 11-bromobenzo[c]imidazo[1,2-a][1,5]naphthyridine (0.19 g, 0.62 mmol, 1.1 eq), CuI (0.022 g, 0.113 mmol, 0.2 eq), 2-picolinic acid (0.014 g, 0.113 mmol, 0.2 eq), K₃PO₄ (0.24 g, 1.13 mmol, 2.0 eq), and 7 mL of DMSO was stirred at 90° C. for 2 days under a nitrogen atmosphere, then cooled down to ambient temperature. The mixture was concentrated under reduced pressure. The residue was purified through column chromatography on silica gel using hexane/ethyl acetate as eluent to obtain the desired ligand as white solid (0.22 g, 65%).

Synthesis of Pt (II) complex: A mixture of ligand (0.057 g, 0.1 mmol, 1.0 eq), K₂PtCl₄ (0.043 g, 0.105 mmol, 1.05 eq), ⁿBu₄Br (0.003 g, 0.01 mmol, 0.1 eq), and 7 mL of 2-ethoxyethanol was stirred under reflux for 3 days via nitrogen atmosphere protection, then cooled down to ambient temperature. The mixture was concentrated under reduced pressure. The residue was purified through column chromatography on silica gel using hexane/methylene chloride as eluent to obtain the desired platinum compound as a white solid (0.012 g, 16%).

### Example 8

In one embodiment, an exemplary compound may be prepared according to the following scheme:

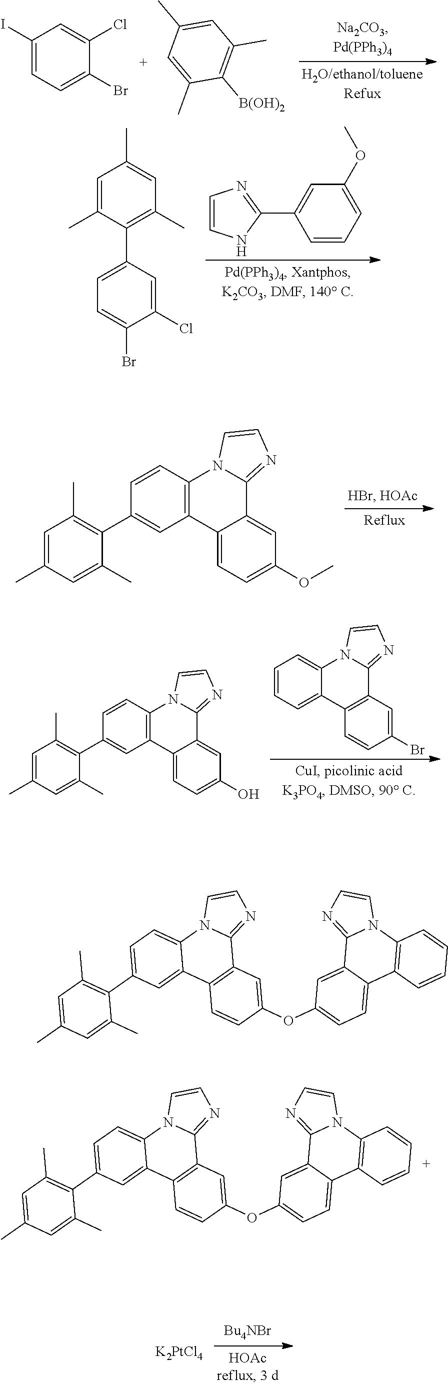

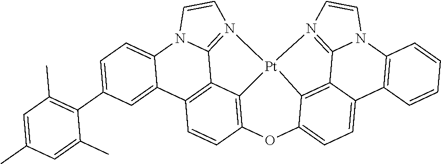

### Example 9

In one embodiment, an exemplary compound may be prepared according to the following scheme:

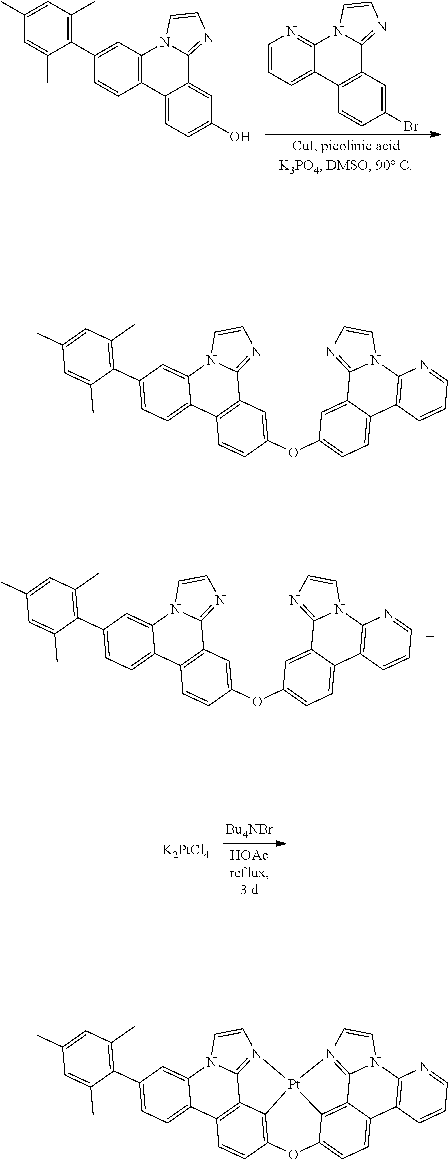

### Example 10

In one embodiment, an exemplary compound may be prepared according to the following scheme:

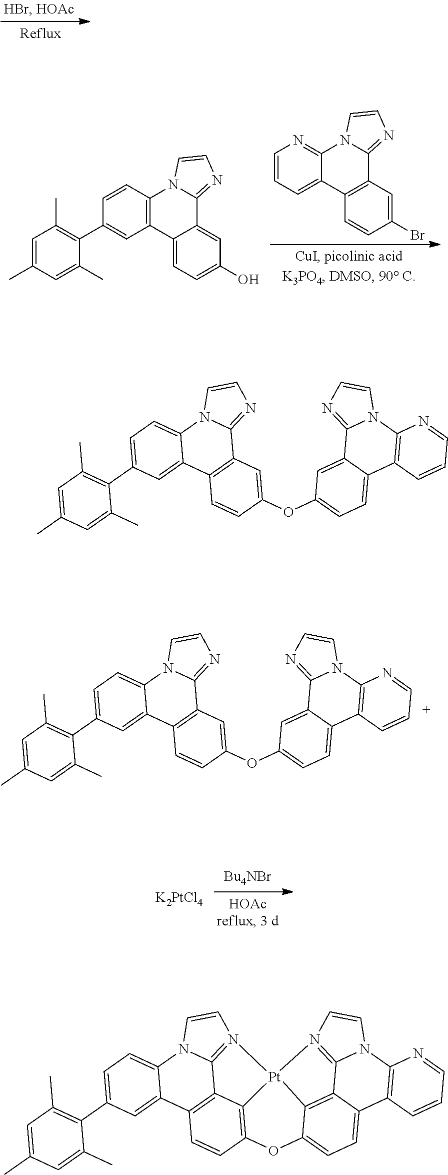

### Example 11

In one embodiment, an exemplary compound may be prepared according to the following scheme:

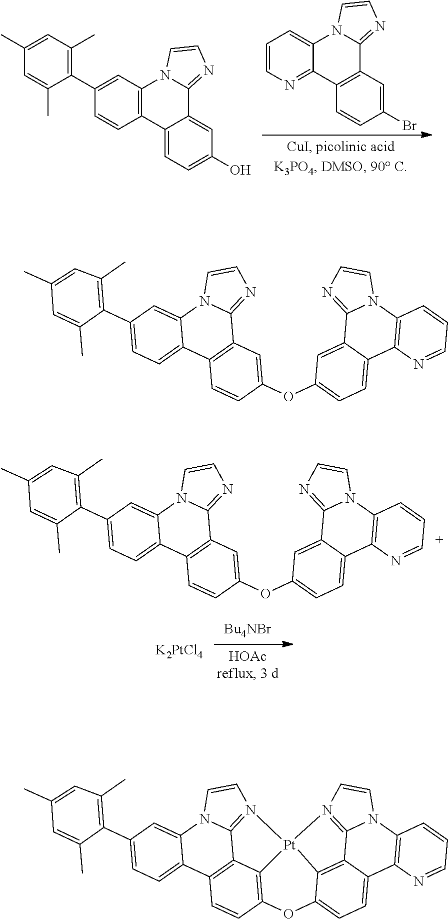

### Example 12

In one embodiment, an exemplary compound may be prepared according to the following scheme:

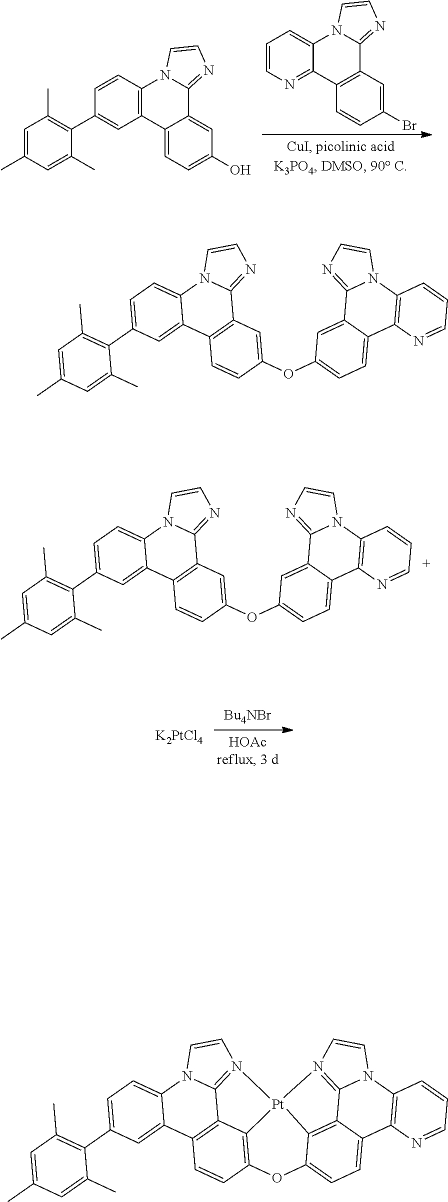

### Example 13

In one embodiment, an exemplary compound may be prepared according to the following scheme:

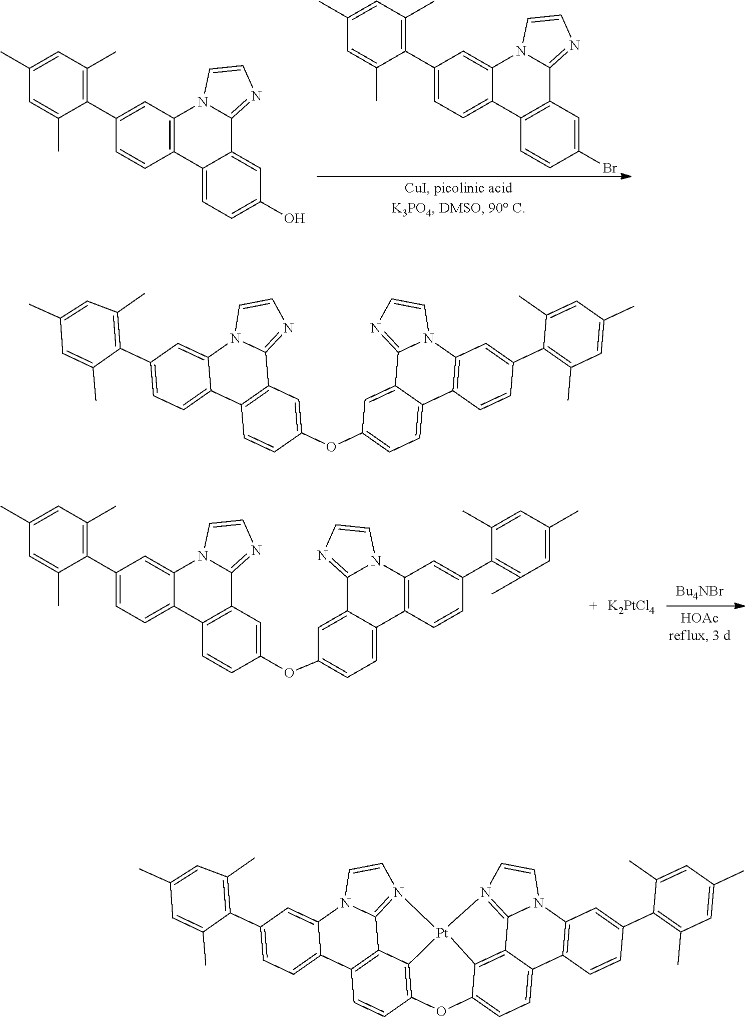

### Example 14

In one embodiment, an exemplary compound may be prepared according to the following scheme:

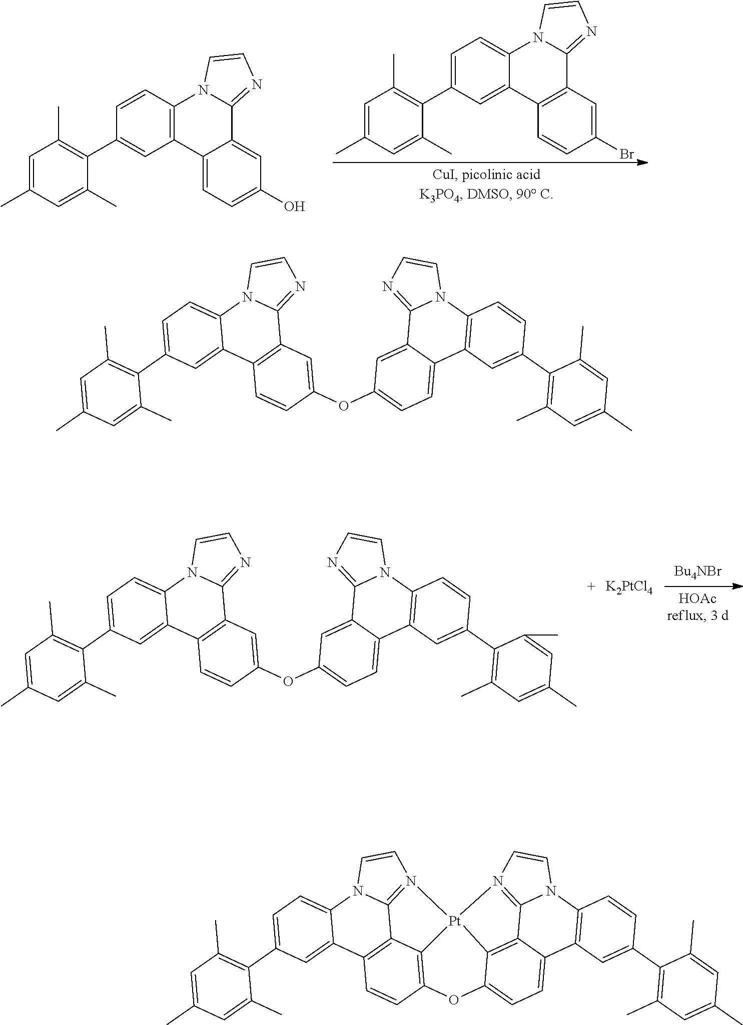

### Example 15

In one embodiment, an exemplary compound may be prepared according to the following scheme:

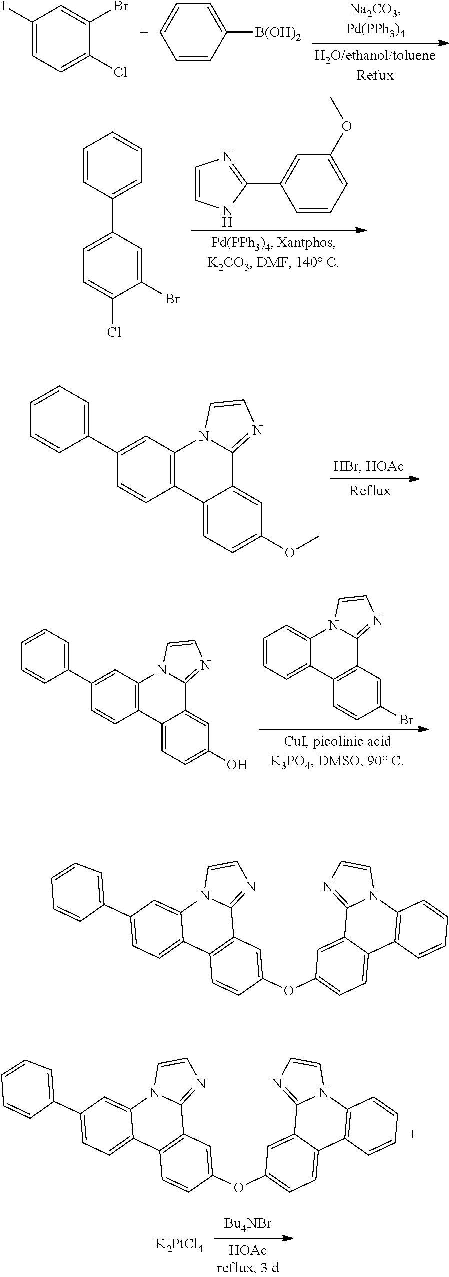

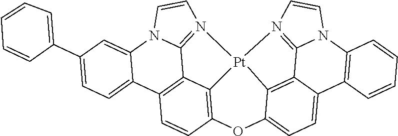

### Example 16

In one embodiment, an exemplary compound may be prepared according to the following scheme:

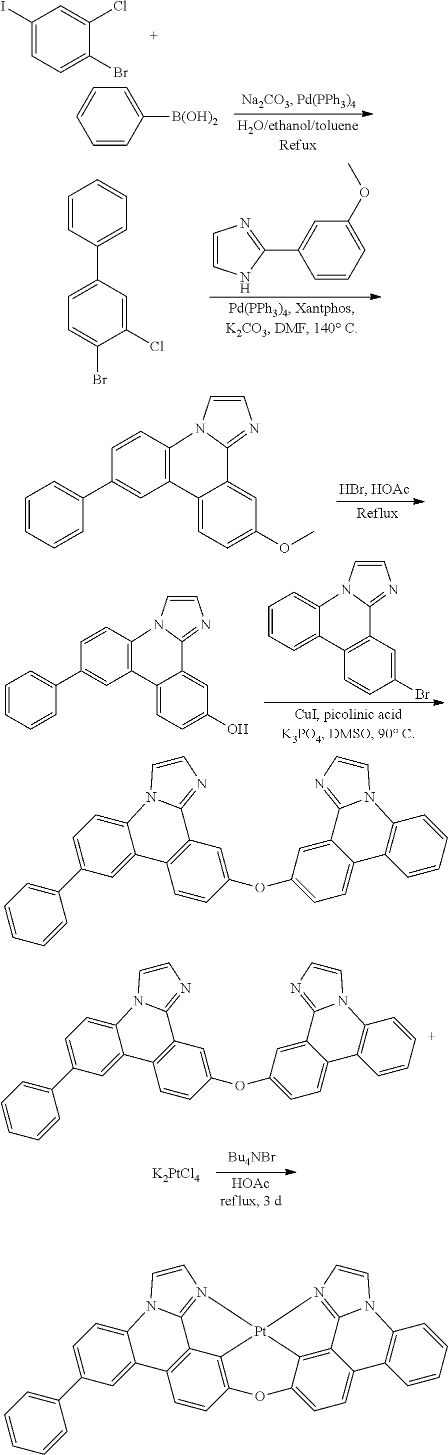

### Example 17

In one embodiment an exemplary compound may be prepared according to the following scheme:

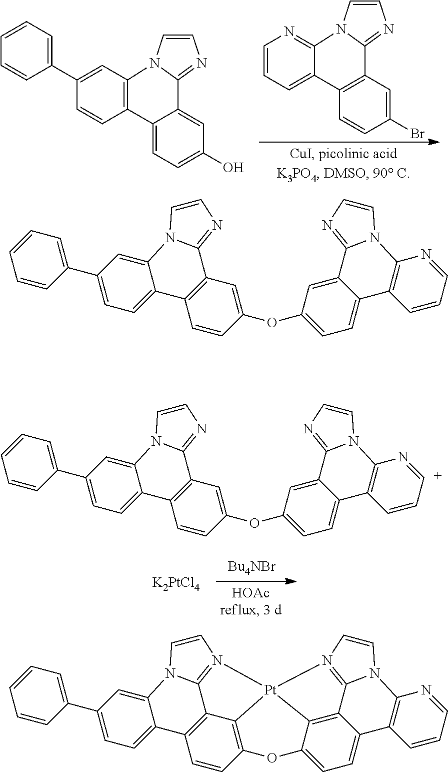

### Example 18

In one embodiment, an exemplary compound may be prepared according to the following scheme:

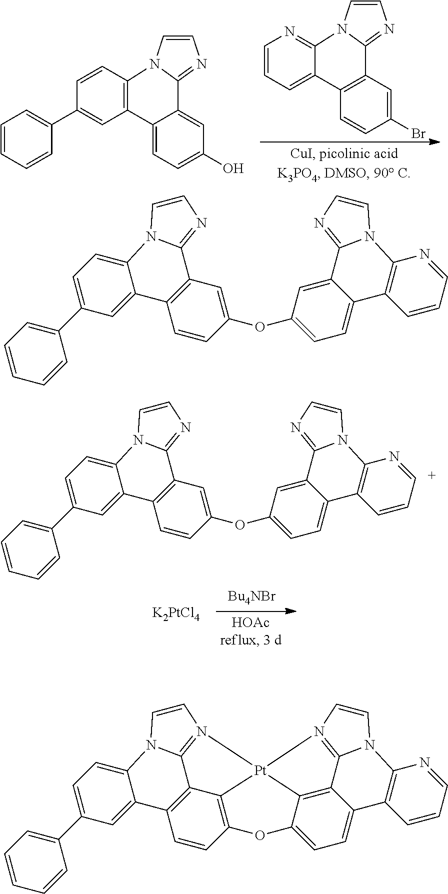

### Example 19

In one embodiment, an exemplary compound may be prepared according to the following scheme:

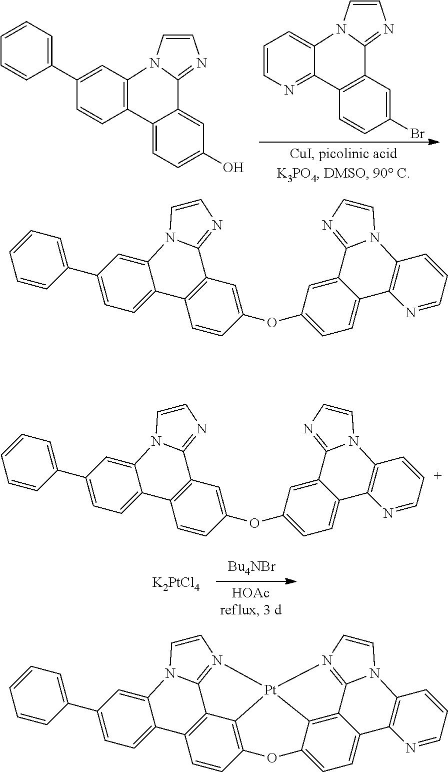

### Example 20

In one embodiment, an exemplary compound may be prepared according to the following scheme:

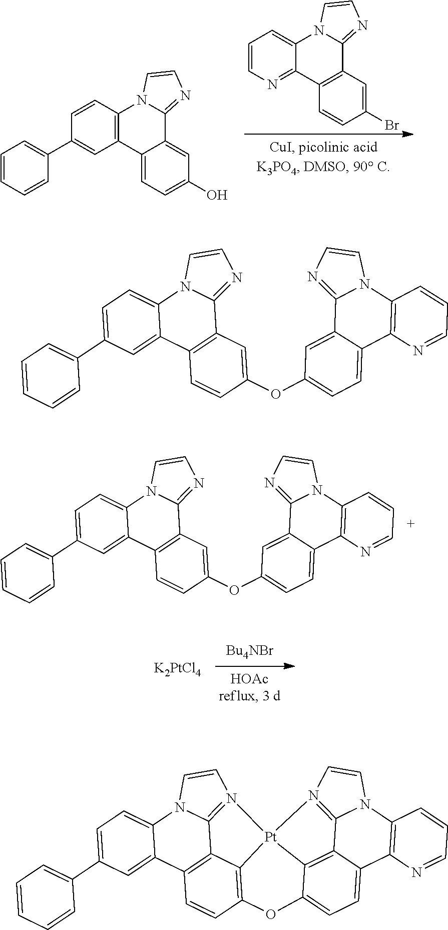

### Example 21

In one embodiment, an exemplary compound may be prepared according to the following scheme:

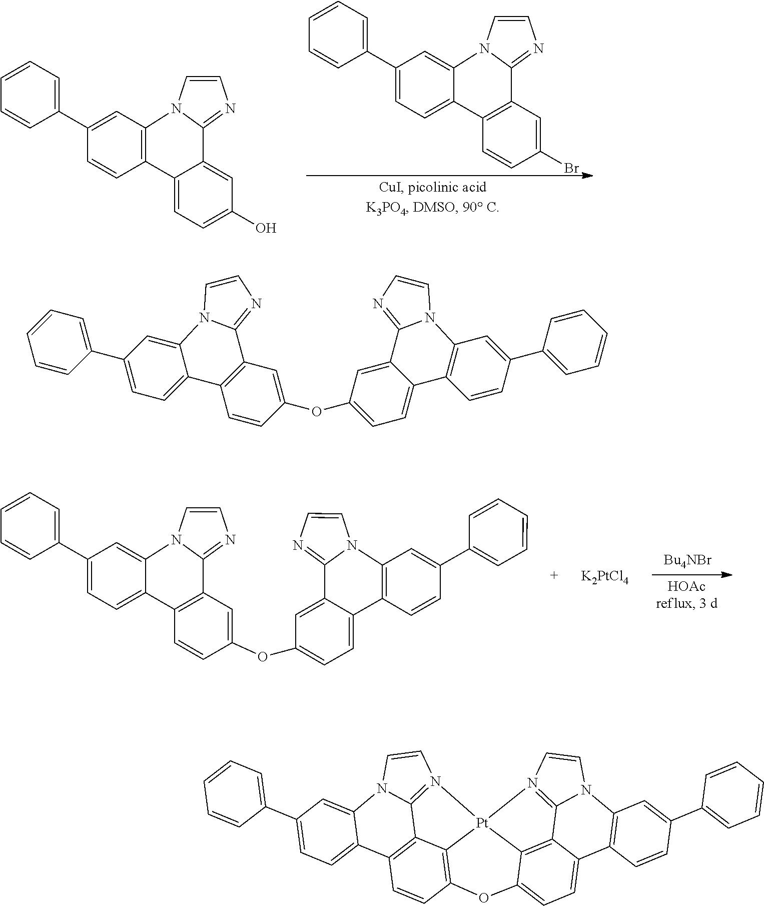

### Example 22

In one embodiment, an exemplary compound may be prepared according to the following scheme:

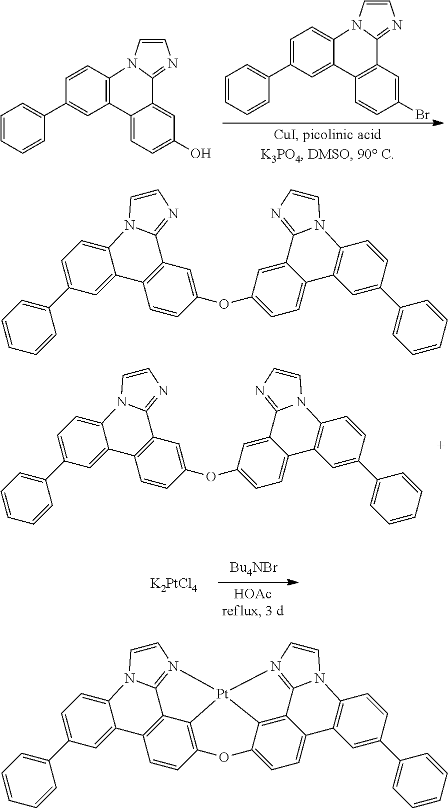

### Example 23

In one embodiment, an exemplary compound may be prepared according to the following scheme:

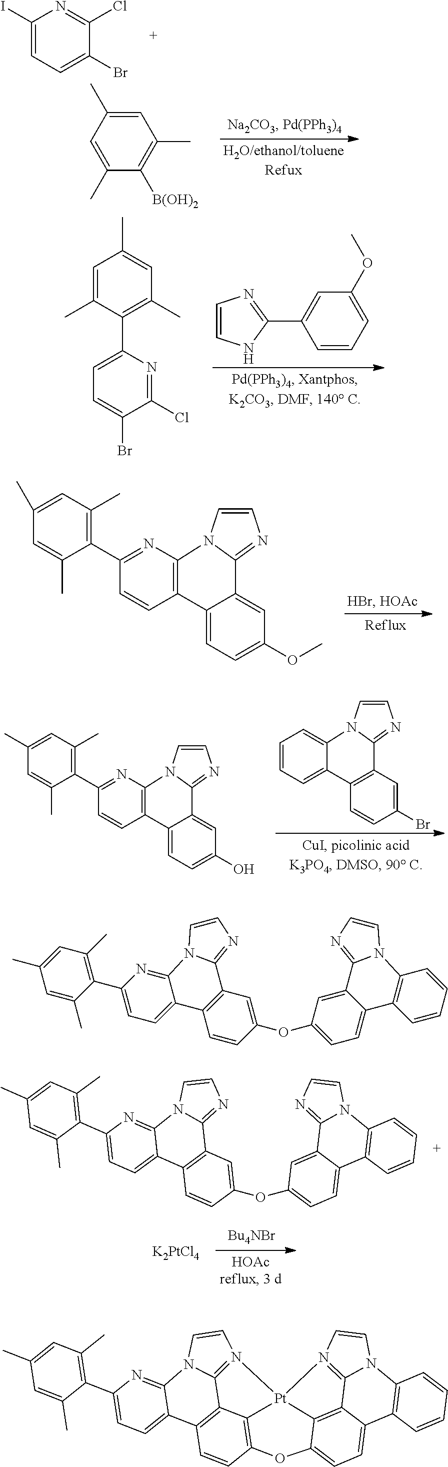

### Example 24

In one embodiment, an exemplary compound may be prepared according to the following scheme:

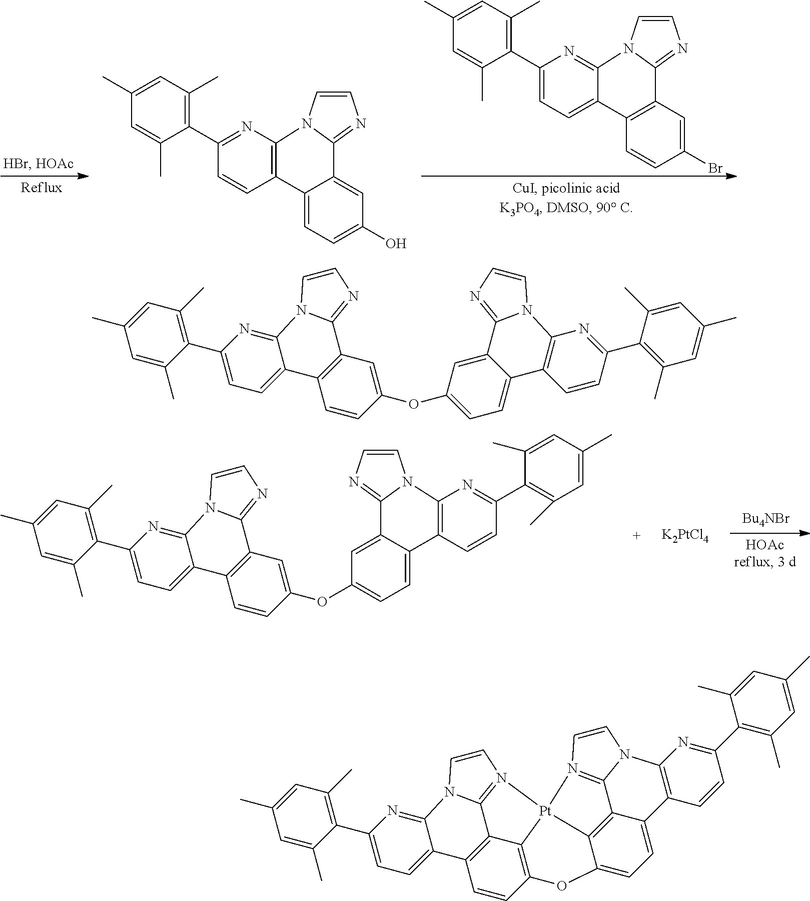

### Example 25

In one embodiment, an exemplary compound may be prepared according to the following scheme:

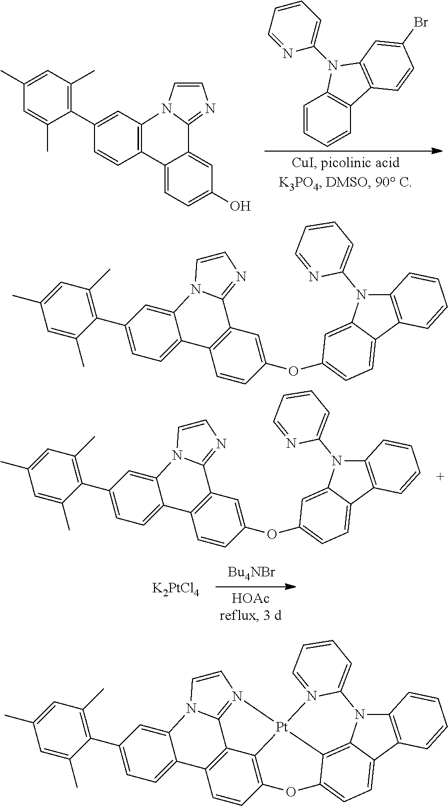

### Example 26

In one embodiment, an exemplary compound may be prepared according to the following scheme:

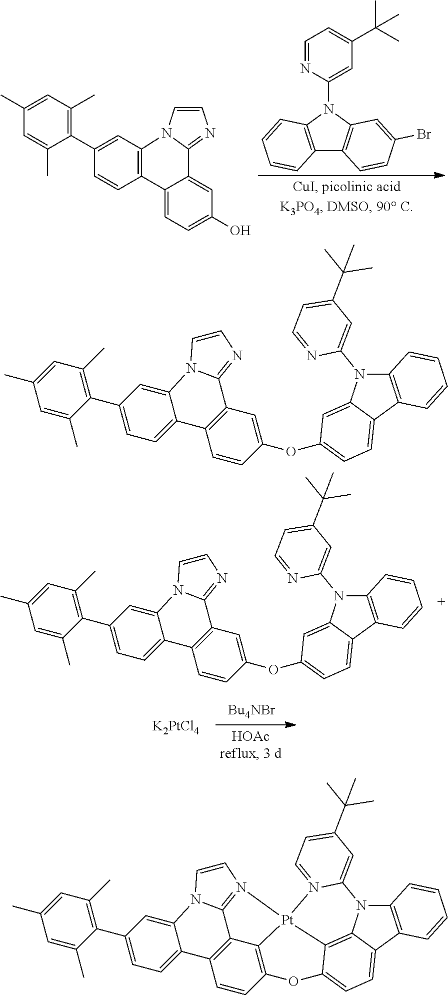

### Example 27

In one embodiment, an exemplary compound may be prepared according to the following scheme:

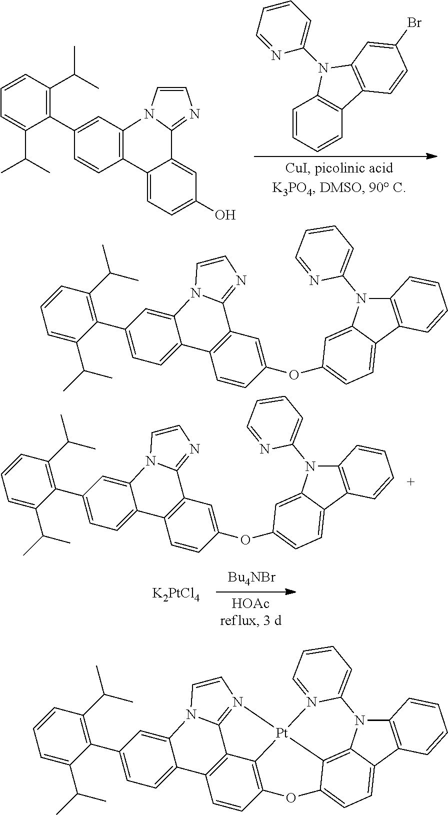

### Example 28

In one embodiment, an exemplary compound may be prepared according to the following scheme:

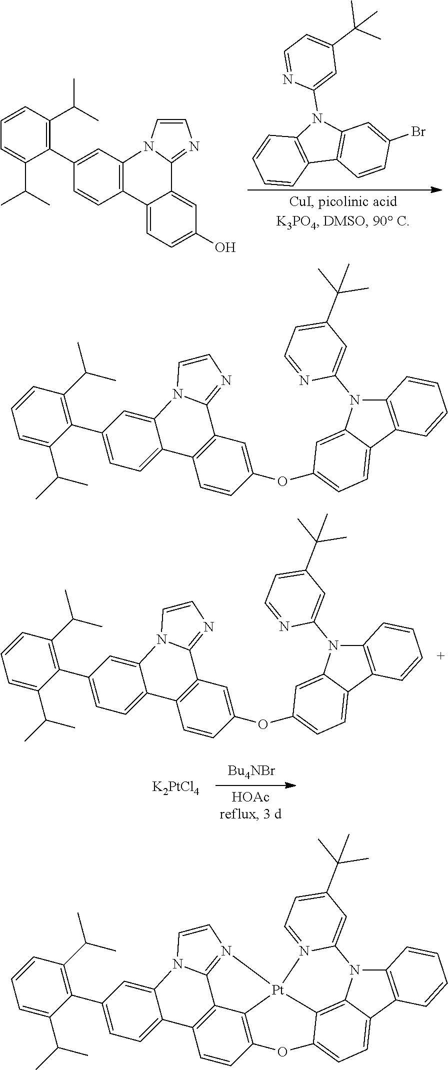

### Example 29

In one embodiment, an exemplary compound may be prepared according to the following scheme:

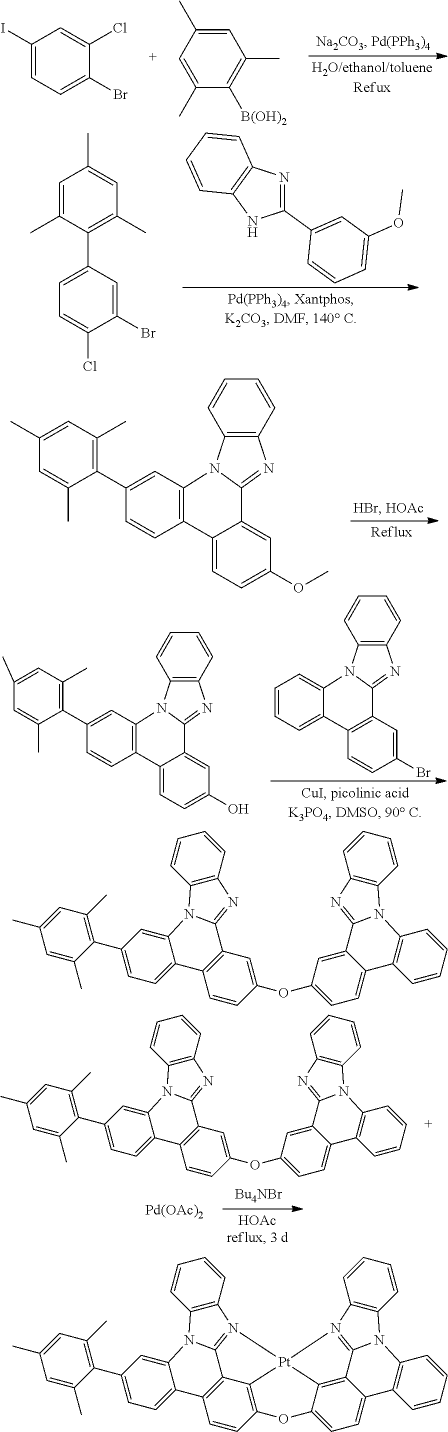

### Example 30

In one embodiment, an exemplary compound may be prepared according to the following scheme:

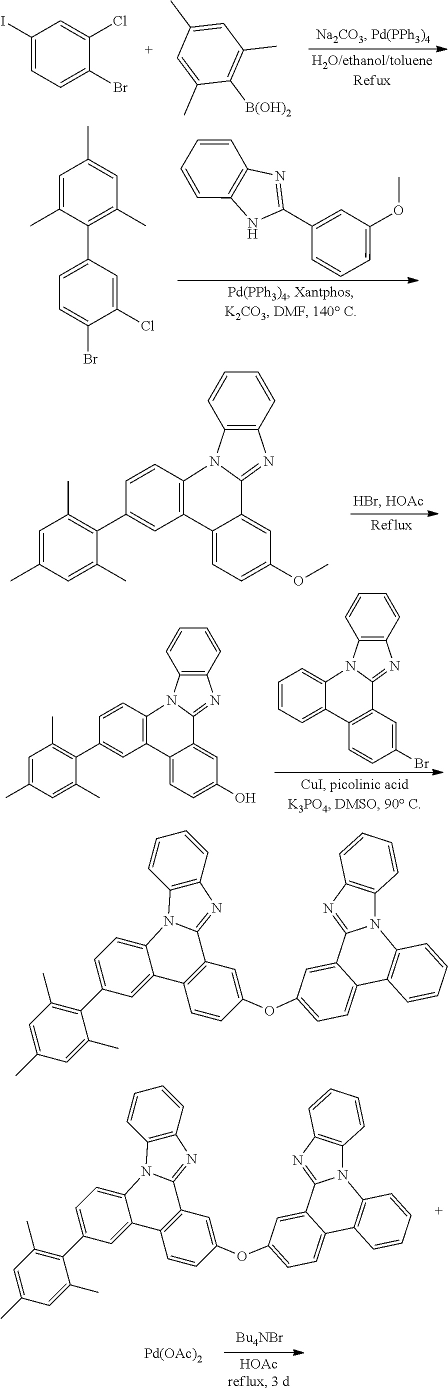

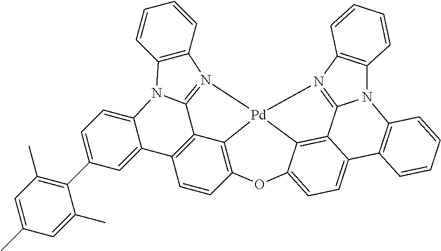

### Example 31

In one embodiment, an exemplary compound may be prepared according to the following scheme:

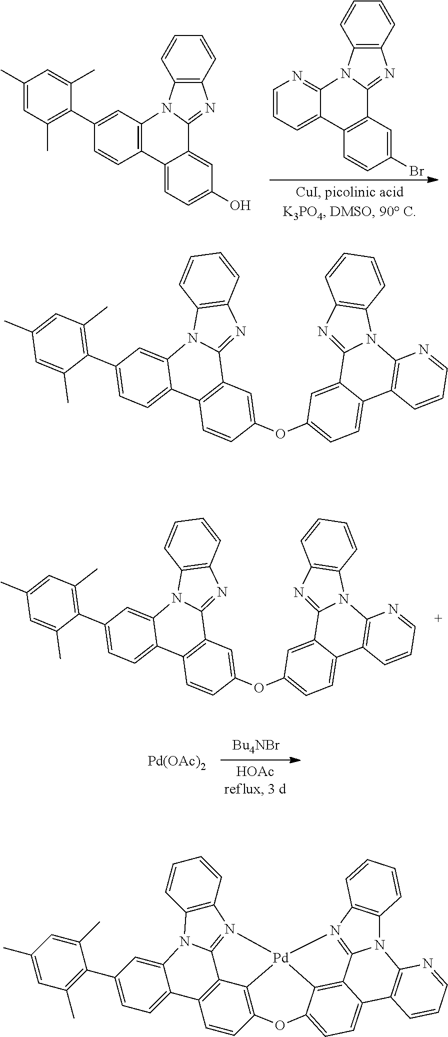

### Example 32

In one embodiment, an exemplary compound may be prepared according to the following scheme:

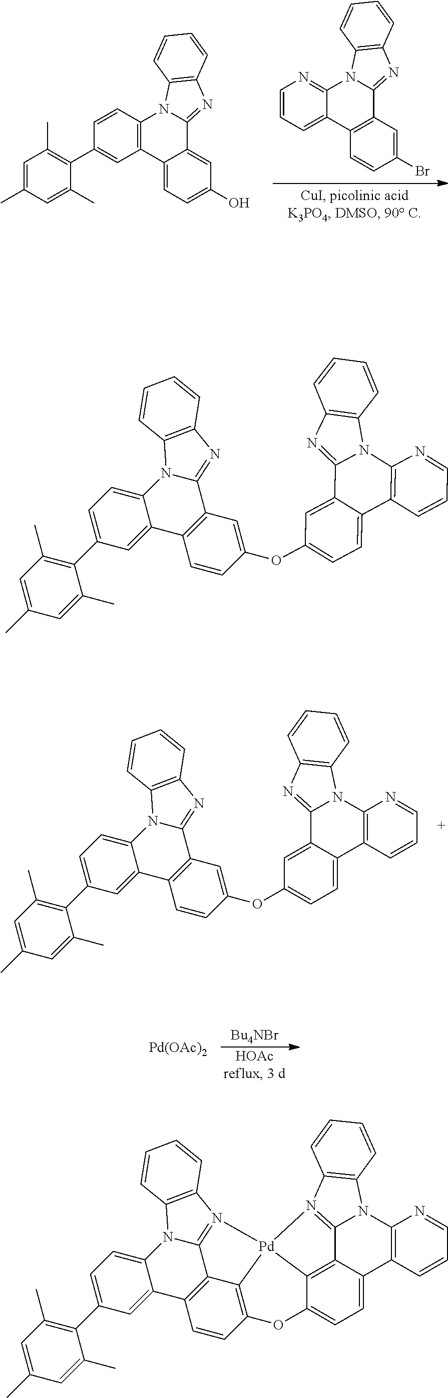

### Example 33

In one embodiment an exemplary compound may be prepared according to the following scheme:

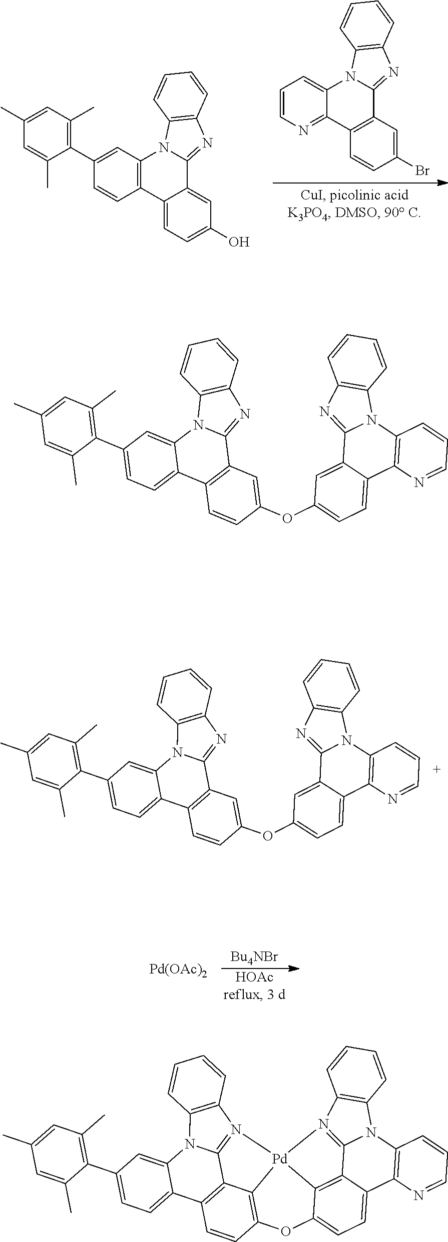

### Example 34

In one embodiment, an exemplary compound may be prepared according to the following scheme:

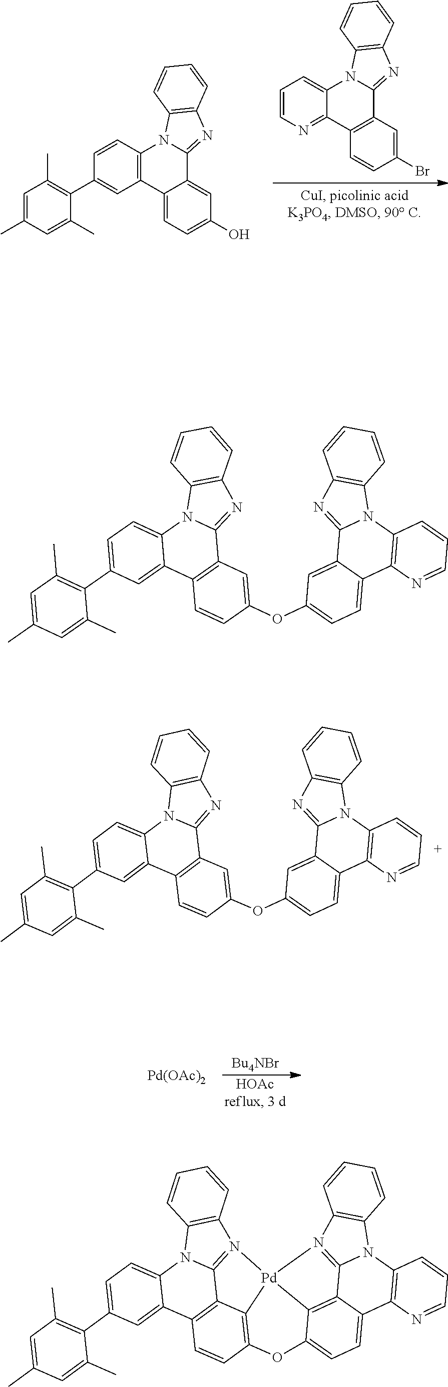

### Example 35

In one embodiment an exemplary compound may be prepared according to the following scheme:

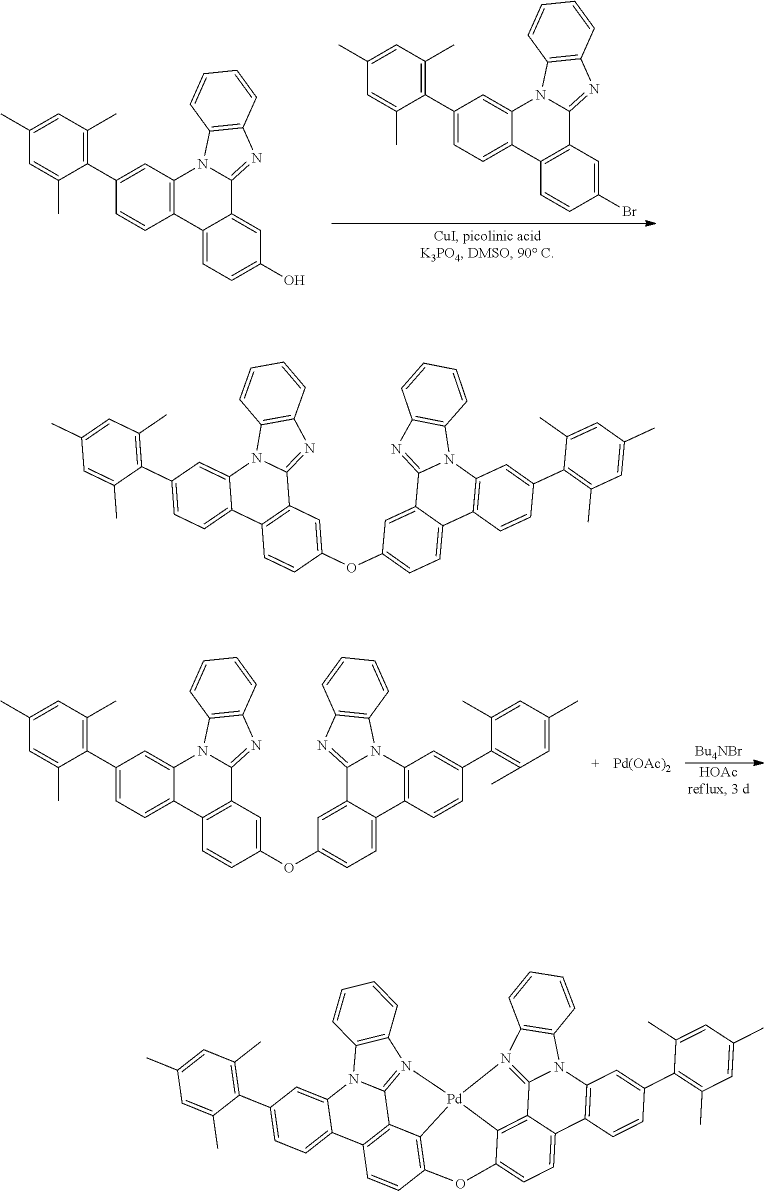

### Example 36

In one embodiment, an exemplary compound may be prepared according to the following scheme:

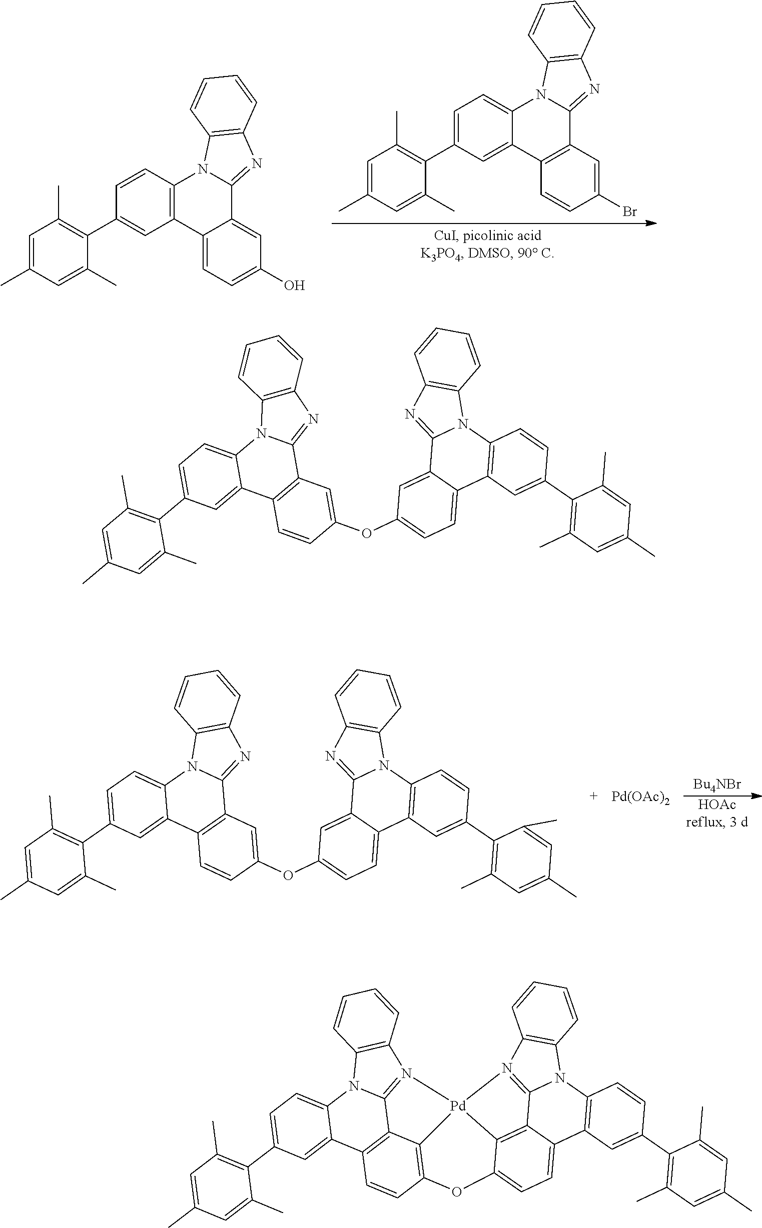

### Example 37

In one embodiment, an exemplary compound may be prepared according to the following scheme:

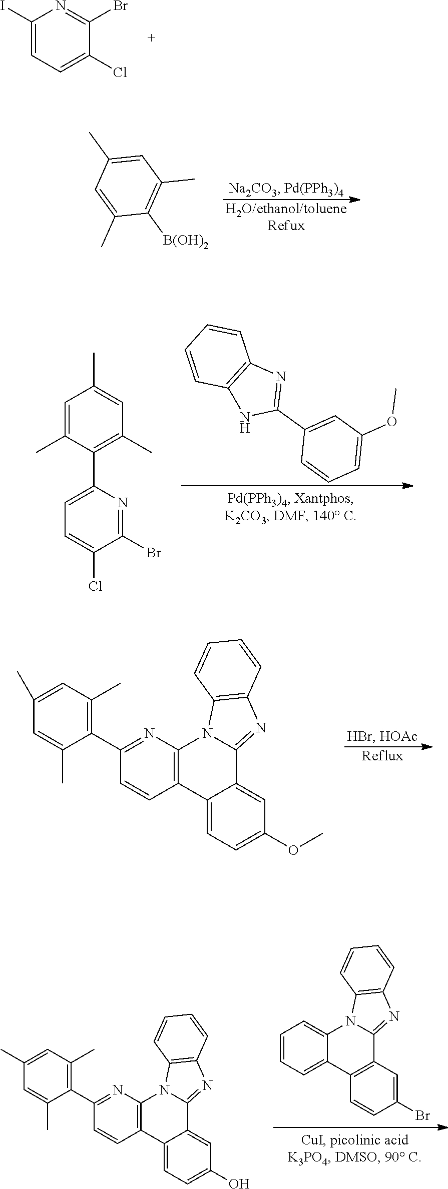

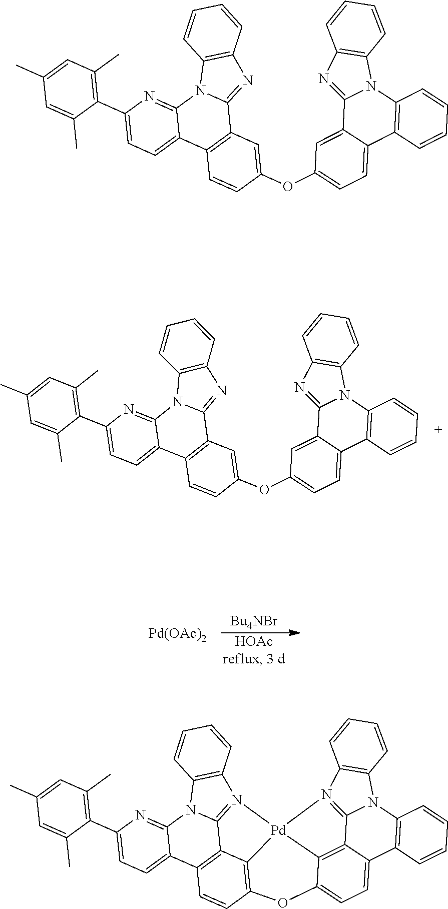

### Example 38

In one embodiment, an exemplary compound may be prepared according to the following scheme:

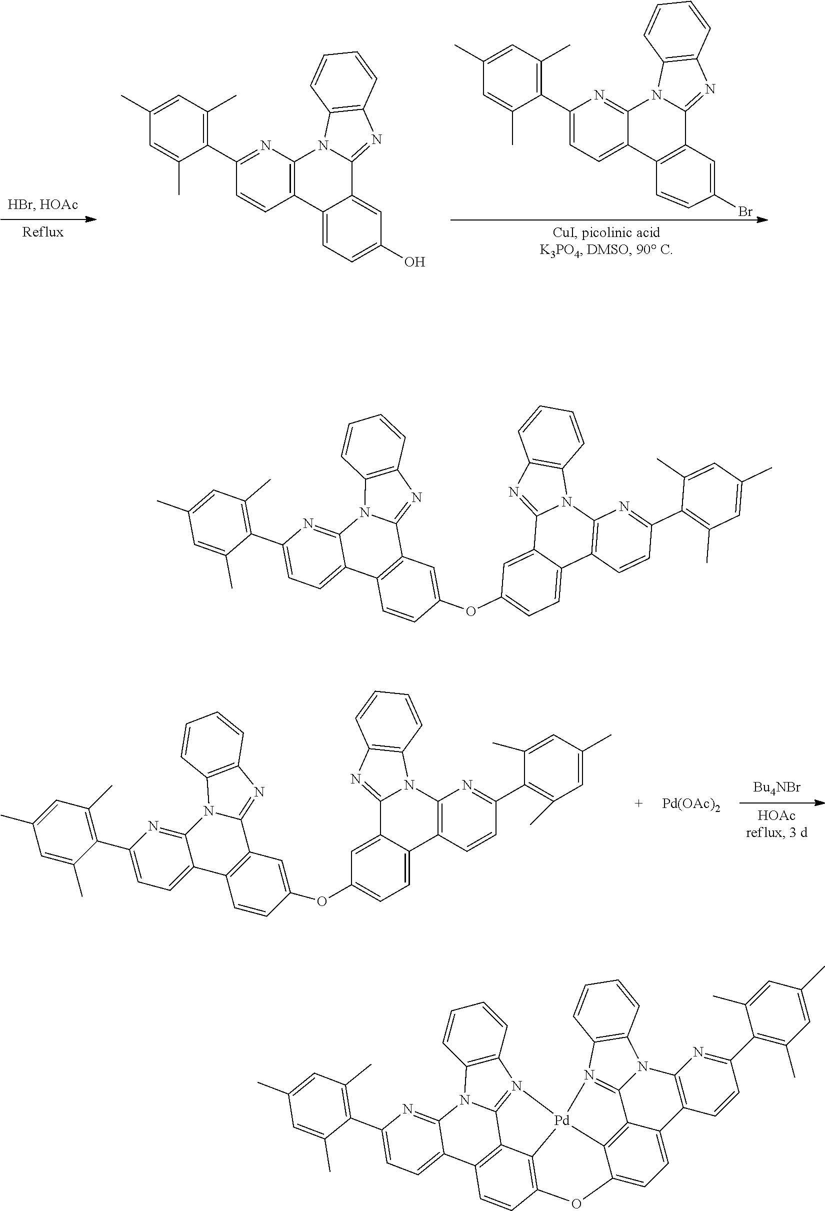

In one embodiment, an exemplary compound may be prepared according to the following scheme:

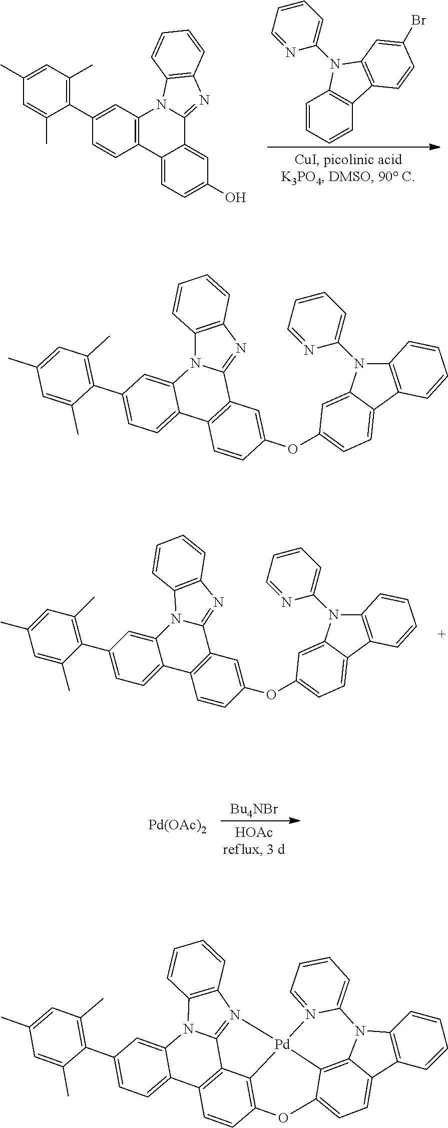

### Example 40

In one embodiment, an exemplary compound may be prepared according to the following scheme:

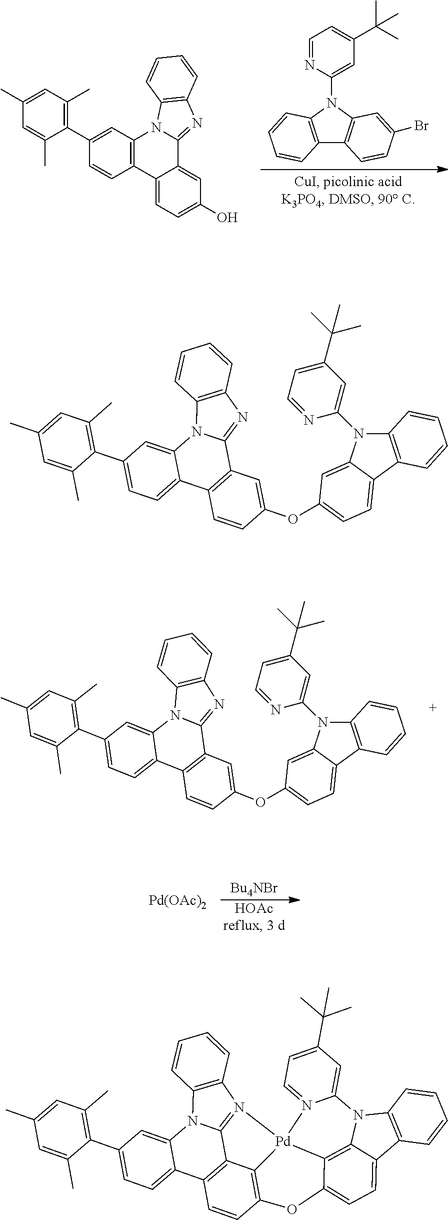

### Example 41

In one embodiment, an exemplary compound may be prepared according to the following scheme:

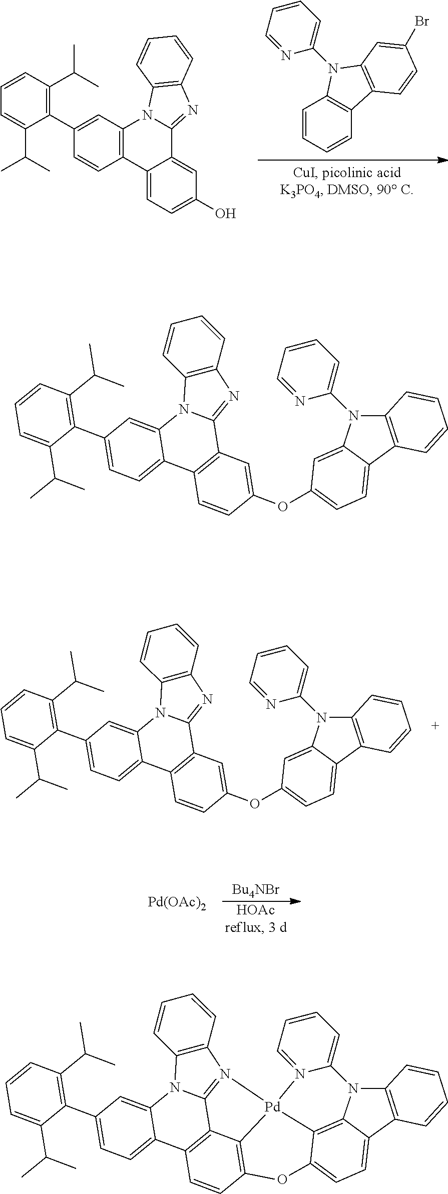

### Example 42

In one embodiment, an exemplary compound may be prepared according to the following scheme:

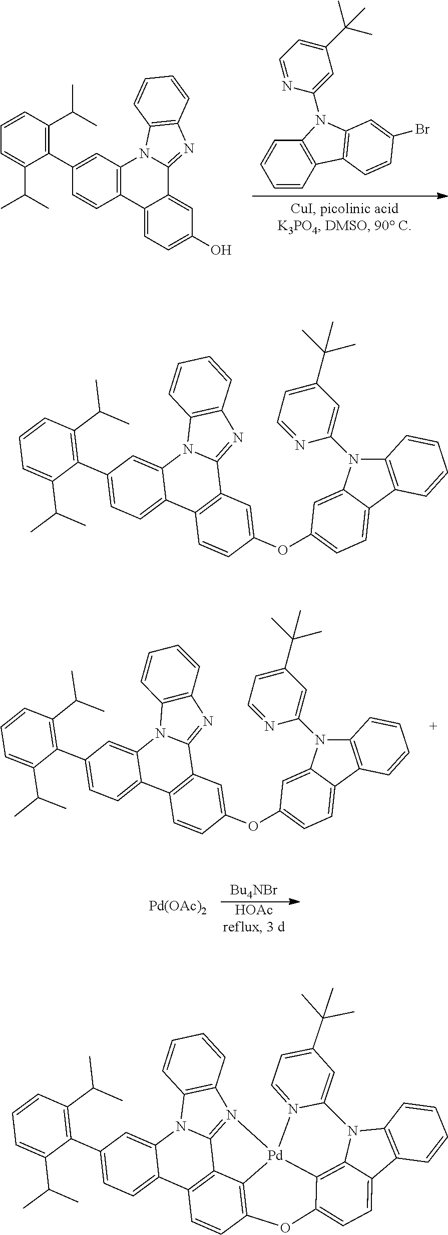

### Example 43

In one embodiment, an exemplary compound may be prepared according to the following scheme:

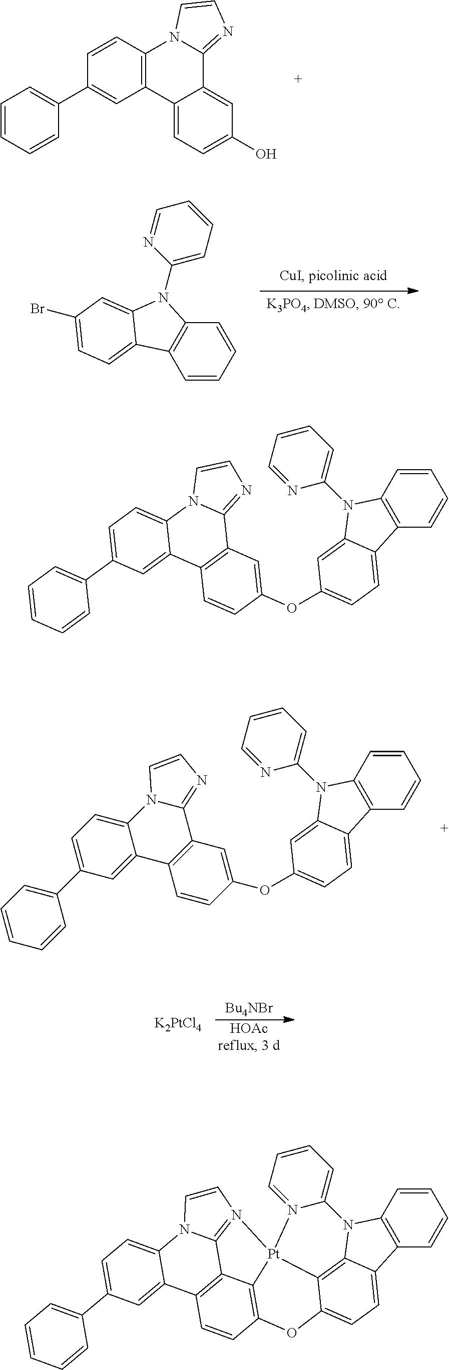

Synthesis of ligand: A mixture of 7-phenylimidazo[1,2-f]phenanthridin-11-ol (0.46 g, 1.48 mmol, 1.0 eq), 2-bromo-9-(pyridin-2-yl)-9H-carbazole (0.57 g, 1.78 mmol, 1.2 eq), Cut (0.057 g, 0.3 mmol, 0.2 eq) 2-picolinic acid (0.0.36 g, 0.3 mmol, 0.2 eq), K₃PO₄ (0.63 g, 2.96 mmol, 2.0 eq), and 15 mL of DMSO was stirred at 90° C. for 2 days under a nitrogen atmosphere, then cooled down to ambient temperature. The mixture was concentrated under reduced pressure. The residue was purified through column chromatography on silica gel using hexane/ethyl acetate as eluent to obtain the desired ligand as white solid (0.54 g, 66%).

Synthesis of Pt (II) complex: A mixture of ligand (0.08 g, 0.14 mmol, 1.0 eq), K₂PtCl₄ (0.066 g, 0.16 mmol, 11 eq), ⁿBu₄Br (0.005 g, 0.014 mmol, 0.1 eq), and 9 mL of acetic acid was stirred under reflux for 3 days via nitrogen atmosphere protection, then cooled down to ambient temperature. The mixture was concentrated under reduced pressure. The residue was purified through column chromatography on silica gel using hexane/methylene chloride as eluent to obtain the desired platinum compound as a white solid (0.4 g, 40%).

### Example 44

In one embodiment, a comparative compound may be prepared according to the following scheme:

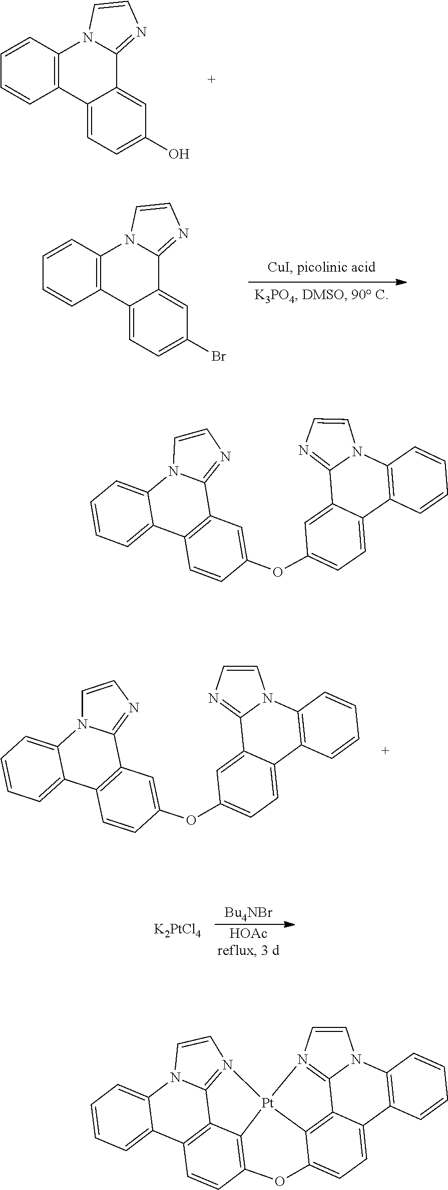

Synthesis of ligand: A mixture of imidazo[1,2-f]phenanthridin-11-ol (0.23 g, 1.0 mmol, 1.0 eq), 11-bromoimidazo[1,2-f]phenanthridine (0.35 g, 1.2 mmol, 1,2 eq) CuI (0.038 g, 0.2 mmol, 0.2 eg), 2-picolinic acid (0.025 g, 0.2 mmol, 0.2 eq), K₃PO₄ (0.42 g, 2.0 mmol, 2.0 eq), and 10 mL of DMSO was stirred at 90° C. or 2 days under a nitrogen atmosphere, then cooled down to ambient temperature. The mixture was concentrated under reduced pressure. The residue was purified through column chromatography on silica gel using hexane/ethyl acetate as eluent to obtain the desired ligand as a white solid (0.31 g, 68%).

Synthesis of Pt (II) complex: A mixture of ligand (0.045 g, 0.1 mmol, 1.0 eq), K₂PtCl₄ (0.046 g, 0.11 mmol, 1.1 eq), ⁿBu₄Br (0.003 g, 0.01 mmol, 0.1 eq), and 9 ml of 2-ethoxyethanol was stirred under reflux for 3 days via nitrogen atmosphere protection, then cooled down to ambient temperature. The mixture was concentrated under reduced pressure. The residue was purified through column chromatography on silica gel using hexane/Methylene chloride as eluent to obtain the desired platinum compound as a white solid (0.01 g, 12%).

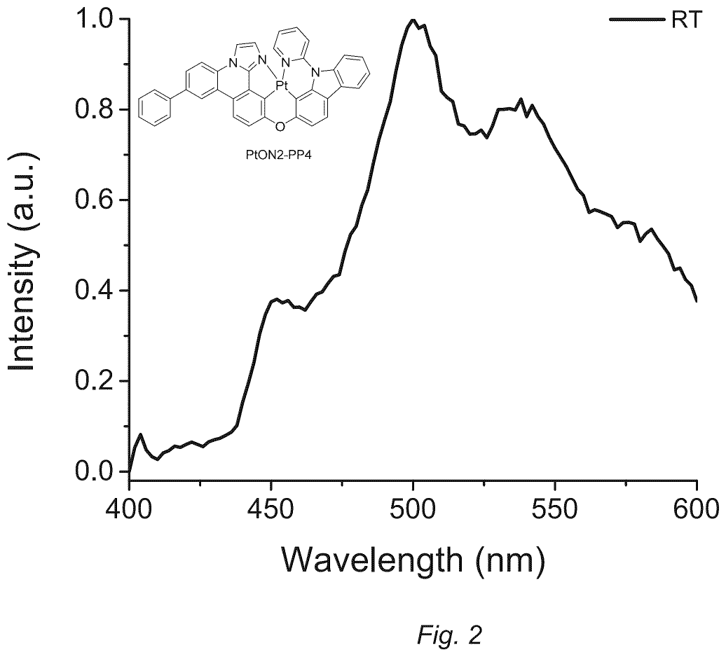

The emission spectrum of an exemplary compound, PtON2-PP4, is presented in FIG. 2.

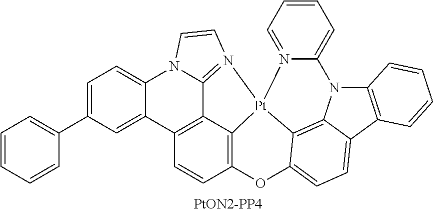

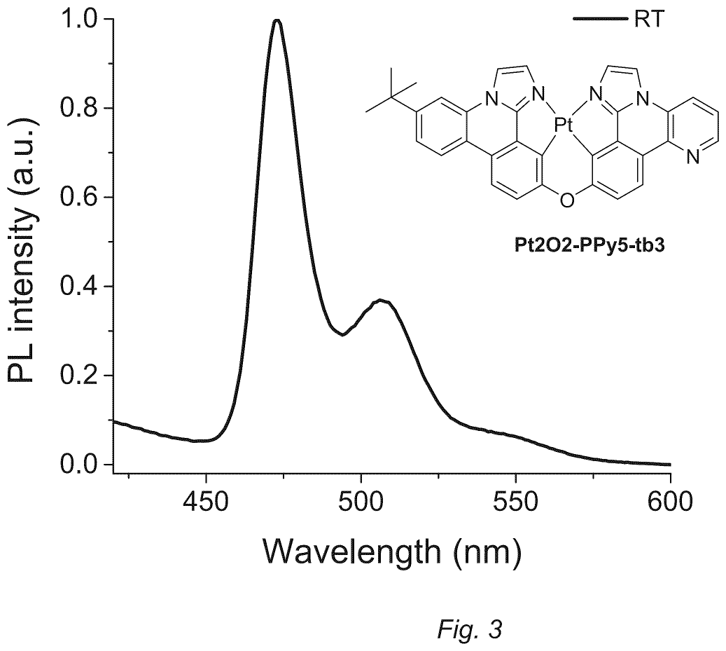

The emission spectrum of a second exemplary compound, Pt2O2-PPy5-tb3, is presented in FIG. 3.

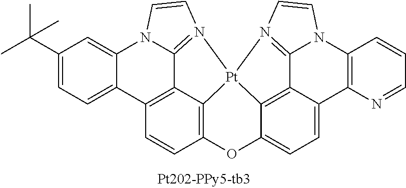

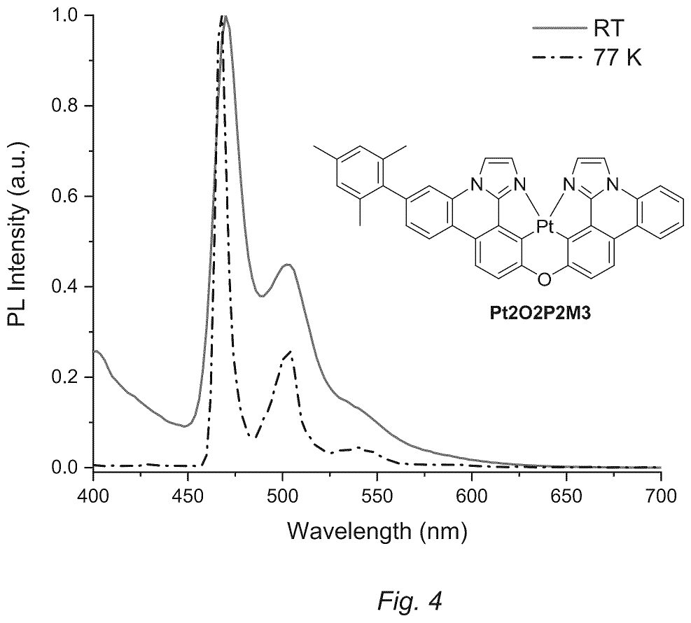

The emission spectrum of a third exemplary compound, Pt2O2-P2-M3, at room temperature and at 77 K, is presented in FIG. 4.

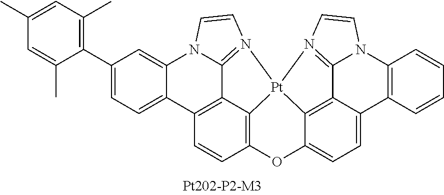

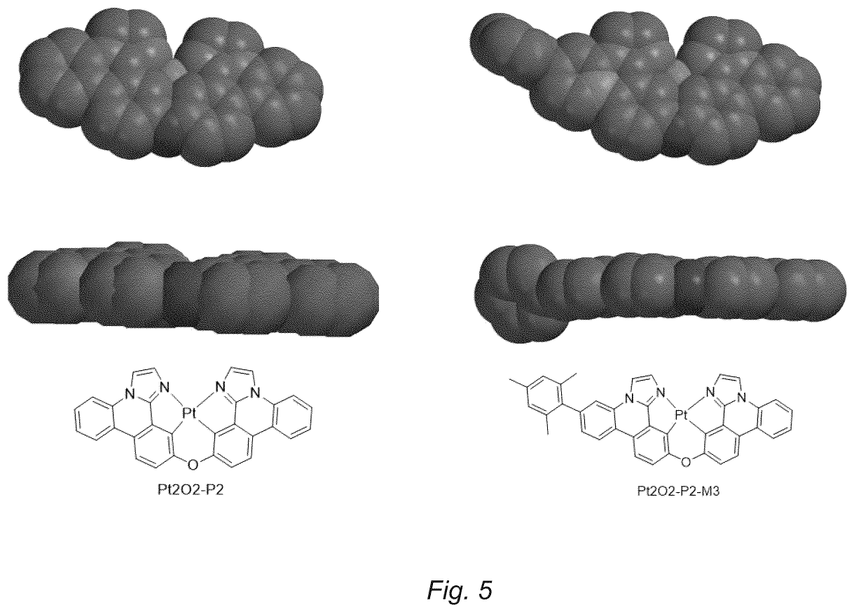

DFT modeling of Pt2O2-P2 and Pt2O2-P2-M3 (FIG. 5) show the departure from planar geometry caused by the mesitylene substituent.

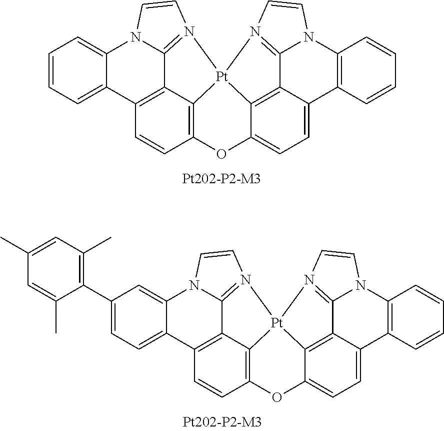

The disclosures of each and every patent, patent application, and publication cited herein are hereby incorporated herein by reference in their entirety. While this disclosure refers to specific embodiments, it is apparent that other embodiments and variations of this disclosure may be devised by others skilled in the art without departing from the true spirit and scope of the disclosure. The appended claims are intended to be construed to include all such embodiments and equivalent variations.

1. A compound of General formula II or General formula IV; 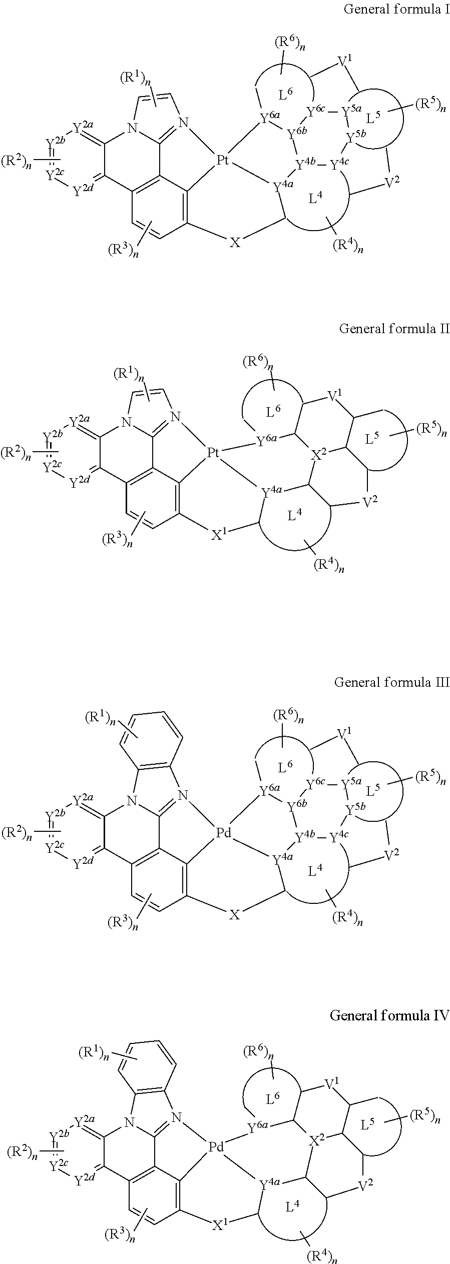
wherein, in General formula II and IV,
Y^{2a}, Y^{2b}, Y^{2c}, Y^{2d}, Y^{4a} Y^{6a}, and X² each independently represent C or N;
X¹, V¹, and V² each independently represent no bond, O, S, Se, NR⁷, PR⁷, AsR⁷, SbR⁷, BiR⁷, R⁷P═O, R⁷As═O, R⁷Bi═O, BR⁷, AlR⁷, CR⁷R⁸, SiR⁷R⁸, GeR⁷R⁸, C═O, SO₂, or SeO₂;
each occurrence of R² independently represents substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
each of R¹, R³, R⁴, R⁵, R⁶, R⁷ and R⁸ is independently absent or present as a single substituent or multiple substituents, valency permitting, and each of R, R¹, R³, R⁴, R⁵, R⁶, R⁷, and R⁸ independently represents deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or
any conjugate or combination thereof;
each n is independently an integer, valency permitting; and
L⁴, L⁵, and L⁶ each independently represents a 5- to 10-membered aryl, heteroaryl, fused aryl, or fused heteroaryl.

2. The compound of claim 1, wherein the compound of General formula II or General formula IV is a compound of General formula VI or General formula VIII; 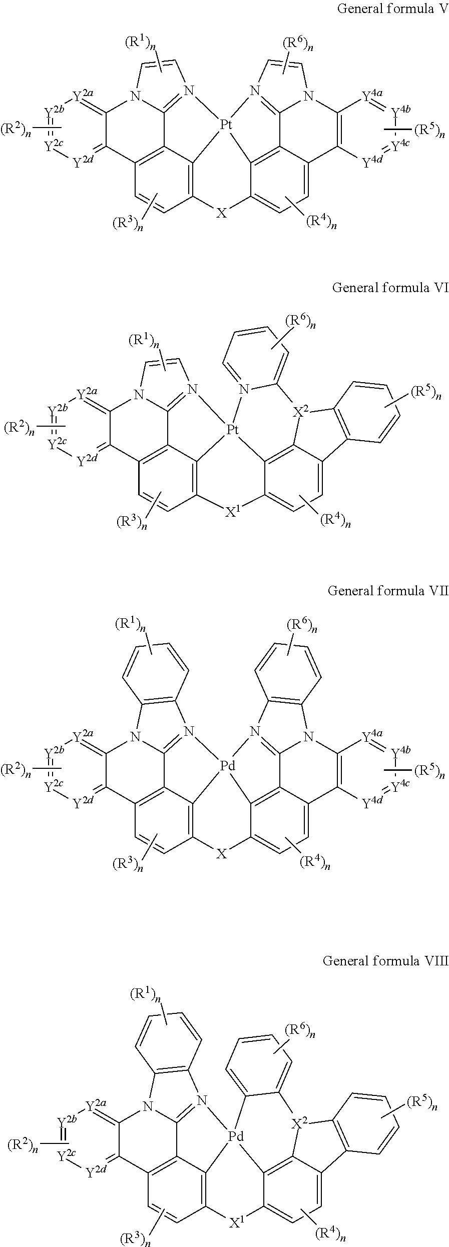
wherein, in General formula VI and VIII;
Y^{2a}, Y^{2b}, Y^{2c}, Y^{2d}, and X² each independently represents C or N;
X¹ represents no bond, O, S, Se, NR⁷, PR⁷, AsR⁷, SbR⁷, BiR⁷, R⁷P═O, R⁷As═O, R⁷Bi═O, BR⁷, AlR⁷, CR⁷R⁸, SiR⁷R⁸, GeR⁷R⁸, C═O, SO₂, or SeO₂;
each occurrence of R² independently represents substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
each of R, R¹, R³, R⁴, R⁵, R⁶, R⁷ and R⁸ is independently absent or present as a single substituent or multiple substituents, valency permitting, and each of R, R¹, R³, R⁴, R⁵, R⁶, R⁷ and R⁸ independently represents deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof; and
each n is independently an integer, valency permitting.

3. The compound of claim 1, wherein the compound has a neutral charge.

4. The compound of claim 1, wherein X¹ is present and each independently represent O, NR⁷, CR⁷R⁸, or SiR⁷R⁸.

5. The compound of claim 1, wherein X² represents N.

6. The compound of claim 2, wherein at least one of Y^{2a}, Y^{2b}, Y^{2c} and Y^{2d} represents N.

7. The compound of claim 2, wherein only one of Y^{2a}, Y^{2b}, Y^{2c}, and Y^{2d} represents N and the remaining of Y^{2a}, Y^{2b}, Y^{2c} and Y^{2d} represent C.

8. The compound of claim 1, wherein L⁶ is 5- to 10-membered heteroaryl or fused heteroaryl.

9. The compound of claim 1, wherein L⁶ is imidazole, benzimidazole, or pyridine.

10. The compound of claim 1, wherein at least one of V¹ and V² represents no bond.

11. The compound of claim 1, wherein each occurrence of R² is independently selected from the group consisting of substituted or unsubstituted alkyl, substituted or unsubstituted aryl, or combinations thereof.

12. The compound of claim 1, wherein at least one occurrence of R⁵ is selected from the group consisting of substituted or unsubstituted alkyl, substituted or unsubstituted aryl, or combinations thereof.

13. The compound of claim 1, wherein each occurrence of R² is independently selected from the group consisting of

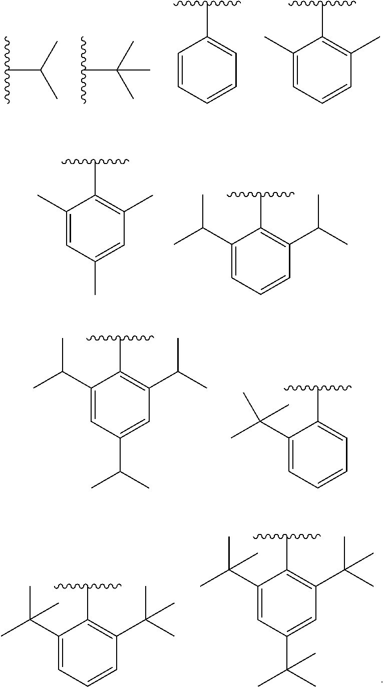

14. The compound of claim 1, wherein each occurrence of R¹, R³, R⁴, R⁵, R⁶, R⁷, and R⁸ is independently selected from the group consisting of: 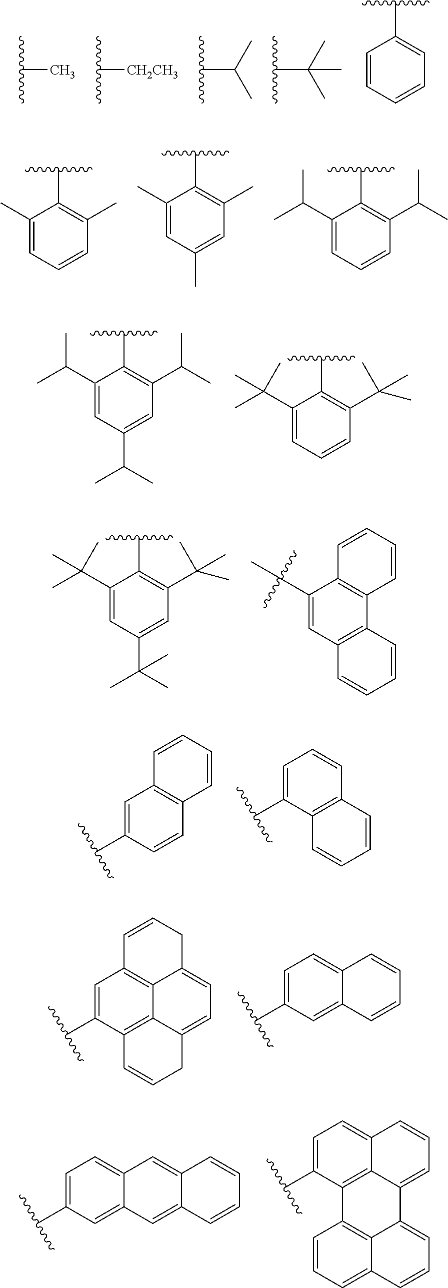 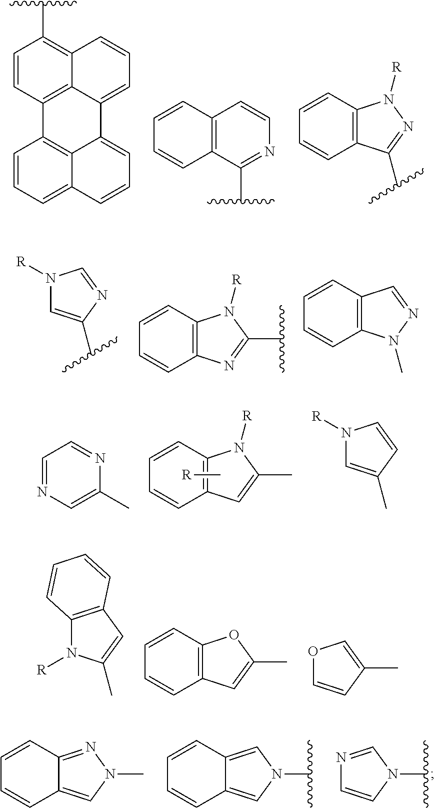
wherein each of R independently represents hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

15. The compound of claim 1, wherein the compound is selected from the group consisting of:

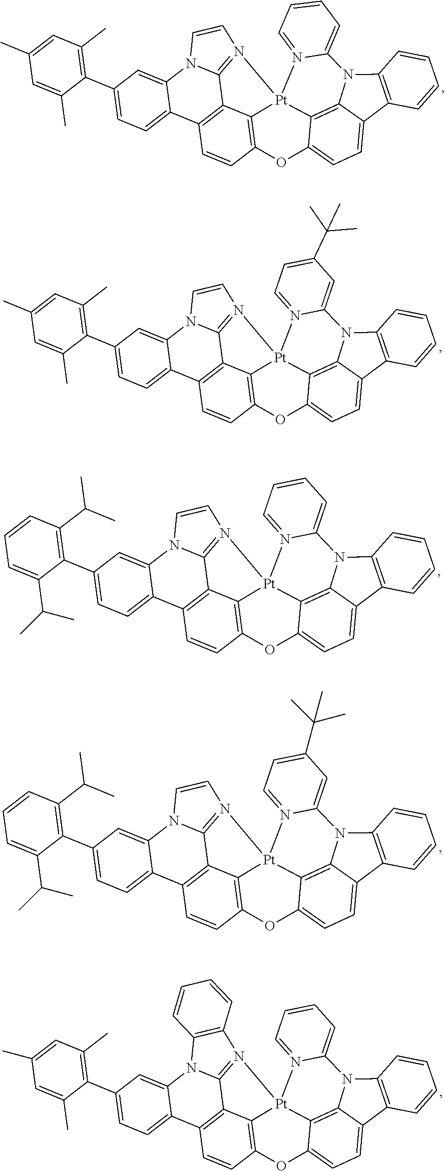

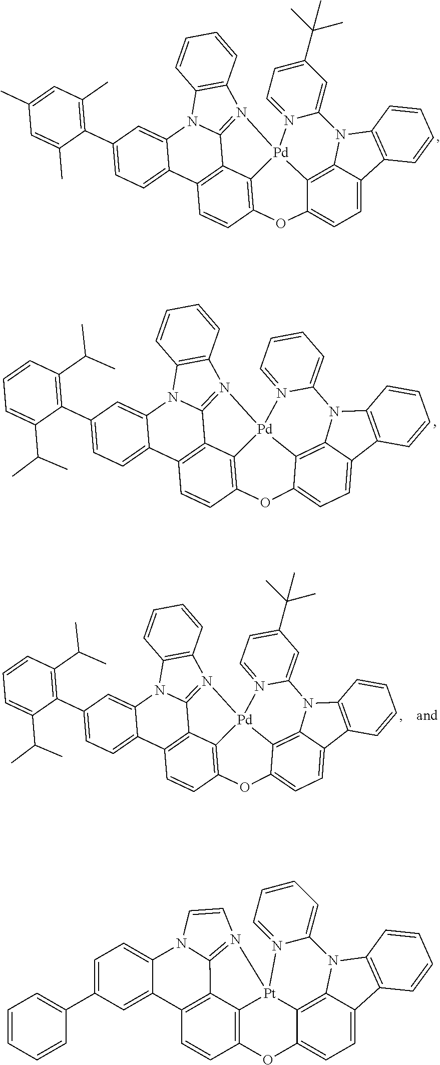

16. An organic light emitting device (OLED) comprising:
an anode;
a cathode; and
an organic layer disposed between the anode and the cathode; wherein the organic layer comprises a compound of General formula II or General formula IV; 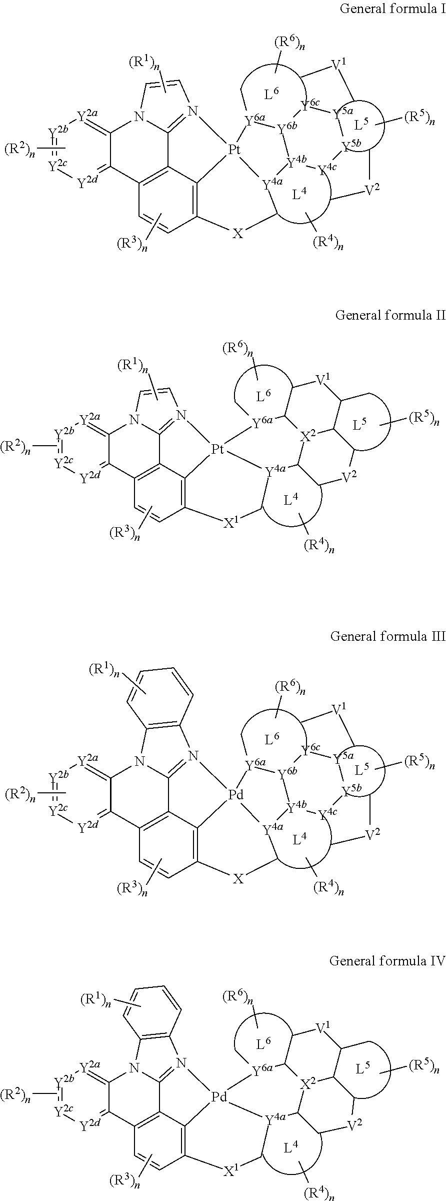
wherein, in General formula II and IV,
Y^{2a}, Y^{2b}, Y^{2c}, Y^{2d}, Y^{4a} Y^{6a}, and X² each independently represent C or N;
X¹, V¹, and V² each independently represent no bond, O, S, Se, NR⁷, PR⁷, AsR⁷, SbR⁷, BiR⁷, R⁷P═O, R⁷As═O, R⁷Bi═O, BR⁷, AlR⁷, CR⁷R⁸, SiR⁷R⁸, GeR⁷R⁸, C═O, SO₂, or SeO₂;
each occurrence of R² independently represents substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
each of R¹, R³, R⁴, R⁵, R⁶, R⁷ and R⁸ is independently absent or present as a single substituent or multiple substituents, valency permitting, and each of R, R¹, R³, R⁴, R⁵, R⁶, R⁷, and R⁸ independently represents deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
each n is independently an integer, valency permitting; and
L⁴, L⁵, and L⁶ each independently represents a 5- to 10-membered aryl, heteroaryl, fused aryl, or fused heteroaryl.

17. The device of claim 16, wherein the organic layer further comprises a host.

18. The device of claim 17, wherein the host comprises at least one selected from the group consisting of a metal complex, triphenylene, carbazole, dibenzothiophene, dibenzofuran, dibenzoselenophene, aza-triphenylene, aza-carbazole, aza-dibenzothiophene, aza-dibenzofuran, and aza-dibenzoselenophene.

19. A consumer product comprising the device of claim 16, wherein the consumer product is selected from the list consisting of a flat panel display, a computer monitor, a medical monitor, a television, a billboard, a light for interior or exterior illumination and/or signaling, a heads-up display, a fully or partially transparent display, a flexible display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video wall comprising multiple displays tiled together, a theater or stadium screen, and a sign.

20. A formulation comprising a compound of General formula II or General formula IV; 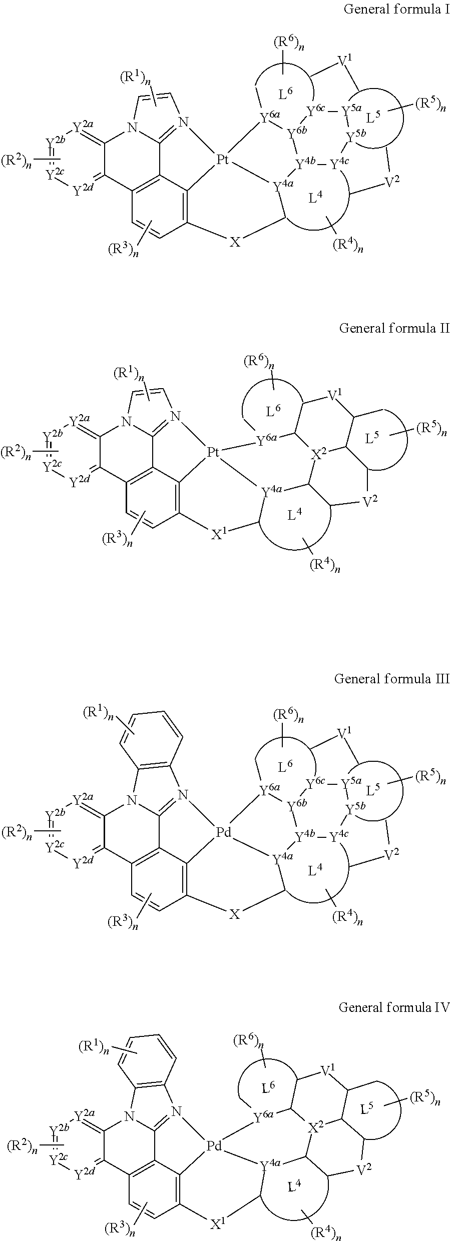
wherein, in General formula II and IV,
Y^{2a}, Y^{2b}, Y^{2c}, Y^{2d}, Y^{4a} Y^{6a}, and X² each independently represent C or N;
X¹, V¹, and V² each independently represent no bond, O, S, Se, NR⁷, PR⁷, AsR⁷, SbR⁷, BiR⁷, R⁷P═O, R⁷As═O, R⁷Bi═O, BR⁷, AlR⁷, CR⁷R⁸, SiR⁷R⁸, GeR⁷R⁸, C═O, SO₂, or SeO₂;
each occurrence of R² independently represents substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
each of R¹, R³, R⁴, R⁵, R⁶, R⁷ and R⁸ is independently absent or present as a single substituent or multiple substituents, valency permitting, and each of R, R¹, R³, R⁴, R⁵, R⁶, R⁷, and R⁸ independently represents deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
each n is independently an integer, valency permitting; and
L⁴, L⁵, and L⁶ each independently represents a 5- to 10-membered aryl, heteroaryl, fused aryl, or fused heteroaryl.
